(19) United States
(12) Patent Application Publication
(10) Pub. No.: US 2023/0259029 A1
(43) Pub. Date: Aug. 17, 2023

(54) ACTINIC RAY-SENSITIVE OR RADIATION-SENSITIVE RESIN COMPOSITION, RESIST FILM, PATTERN FORMING METHOD, AND METHOD FOR MANUFACTURING ELECTRONIC DEVICE

(71) Applicant: FUJIFILM Corporation, Tokyo (JP)

(72) Inventors: Yuta OKUAKI, Haibara-gun (JP); Akihiro KANEKO, Haibara-gun (JP); Masafumi KOJIMA, Haibara-gun (JP); Akiyoshi GOTO, Haibara-gun (JP); Keita KATO, Haibara-gun (JP)

(73) Assignee: FUJIFILM Corporation, Tokyo (JP)

(21) Appl. No.: 18/191,597

(22) Filed: Mar. 28, 2023

Related U.S. Application Data
(63) Continuation of application No. PCT/JP2021/034387, filed on Sep. 17, 2021.

(30) Foreign Application Priority Data
Sep. 29, 2020 (JP) 2020-163058

(51) Int. Cl. G03F 7/039

(52) U.S. Cl. CPC G03F 7/0397

(57) ABSTRACT

An object of the present invention is to provide an actinic ray-sensitive or radiation-sensitive resin composition having an excellent resolution. In addition, another object of the present invention is to provide a resist film, a pattern forming method, and a method for manufacturing an electronic device, each relating to the actinic ray-sensitive or radiation-sensitive resin composition.

The actinic ray-sensitive or radiation-sensitive resin composition of the embodiment of the present invention includes:
a resin of which polarity increases through decomposition by the action of an acid; and
a compound that generates an acid upon irradiation with actinic rays or radiation,
in which the resin includes a resin including a repeating unit X1 having two or more groups of which polarity increases through decomposition by the action of an acid and a repeating unit X2 having a phenolic hydroxyl group.

### CROSS-REFERENCE TO RELATED APPLICATIONS

This application is a Continuation of PCT International Application No. PCT/JP2021/034387 filed on Sep. 17, 2021, which claims priority under 35 U.S.C. § 119(a) to Japanese Patent Application No. 2020-163058 filed on Sep. 29, 2020. The above applications are hereby expressly incorporated by reference, in their entirety, into the present application.

### BACKGROUND OF THE INVENTION

### 1. Field of the Invention

The present invention relates to an actinic ray-sensitive or radiation-sensitive resin composition, a resist film, a pattern forming method, and a method for manufacturing an electronic device.

### 2. Description of the Related Art

Since the advent of a resist for KrF excimer laser (248 nm), a pattern forming method utilizing chemical amplification has been used in order to compensate for a decrease in sensitivity due to light absorption. For example, in a positive tone chemical amplification method, first, a photoacid generator included in the exposed portion decomposes upon irradiation with light to generate an acid. Then, in a post-exposure baking (PEB) step and the like, a solubility in a developer changes by, for example, changing an alkali-insoluble group contained in a resin included in an actinic ray-sensitive or radiation-sensitive resin composition to an alkali-soluble group by the catalytic action of an acid thus generated. Thereafter, development is performed using a basic aqueous solution, for example. As a result, the exposed portion is removed to obtain a desired pattern.

For miniaturization of semiconductor elements, the wavelength of an exposure light source has been shortened and a projection lens with a high numerical aperture (high NA) has been advanced, and currently, an exposure machine using an ArF excimer laser having a wavelength of 193 nm as a light source is under development. In addition, in recent years, a pattern forming method using extreme ultraviolet rays (EUV light) and an electron beam (EB) as a light source has also been studied.

Under these circumstances, various configurations have been proposed as actinic ray-sensitive or radiation-sensitive resin compositions.

For example, JP2015-577667A discloses an actinic ray-sensitive or radiation-sensitive resin composition including a resin including a hydroxystyrene-based repeating unit and a repeating unit having an acid-decomposable group.

### SUMMARY OF THE INVENTION

The present inventors have conducted studies on the resist composition described in JP2015-577667A, and have thus clarified that there is room for further improvement of resolution.

Therefore, an object of the present invention is to provide an actinic ray-sensitive or radiation-sensitive resin composition having an excellent resolution.

In addition, another object of the present invention is to provide a resist film, a pattern forming method, and a method for manufacturing an electronic device, each relating to the actinic ray-sensitive or radiation-sensitive resin composition.

The present inventors have found that the objects can be accomplished by the following configurations.

[1] An actinic ray-sensitive or radiation-sensitive resin composition comprising:

a resin of which polarity increases through decomposition by an action of an acid; and

a compound that generates an acid upon irradiation with actinic rays or radiation,

in which the resin includes a resin containing a repeating unit X1 having two or more groups of which polarity increases through decomposition by an action of an acid and a repeating unit X2 having a phenolic hydroxyl group.

[2] The actinic ray-sensitive or radiation-sensitive resin composition as described in [1],

in which the repeating unit X1 is a repeating unit represented by Formula (A) which will be described later.

[3] The actinic ray-sensitive or radiation-sensitive resin composition as described in [2],

in which M¹¹ has 7 or less carbon atoms.

[4] The actinic ray-sensitive or radiation-sensitive resin composition as described in any one of [1] to [3],

in which a content of the repeating unit X1 is 30% by mass or more with respect to all repeating units in the resin.

[5] The actinic ray-sensitive or radiation-sensitive resin composition as described in any one of [1] to [4],

in which the repeating unit X2 is a repeating unit represented by Formula (I) which will be described later.

[6] The actinic ray-sensitive or radiation-sensitive resin composition as described in any one of [1] to [5],

in which the compound that generates an acid upon irradiation with actinic rays or radiation includes any one or more of a compound (I) or a compound (II) which will be described later.

[7] A resist film formed of the actinic ray-sensitive or radiation-sensitive resin composition as described in any one of [1] to [6].

[8] A pattern forming method comprising:

a step of forming a resist film on a substrate, using the actinic ray-sensitive or radiation-sensitive resin composition as described in any one of [1] to [6];

a step of exposing the resist film; and

a step of developing the exposed resist film, using a developer, to form a pattern.

[9] The pattern forming method as described in [8],

in which the developer includes an organic solvent.

[10] A method for manufacturing an electronic device, comprising the pattern forming method as described in [8] or [9].

According to the present invention, it is possible to provide an actinic ray-sensitive or radiation-sensitive resin composition having an excellent resolution.

In addition, according to the present invention, it is possible to provide a resist film, a pattern forming method, and a method for manufacturing an electronic device, each relating to the actinic ray-sensitive or radiation-sensitive resin composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

In notations for a group (atomic group) in the present specification, in a case where the group is noted without specifying whether it is substituted or unsubstituted, the group includes both a group having no substituent and a group having a substituent as long as this does not impair the spirit of the present invention. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

The substituent is preferably a monovalent substituent unless otherwise specified.

“Actinic rays” or “radiation” in the present specification means, for example, a bright line spectrum of a mercury lamp, far ultraviolet rays typified by an excimer laser, extreme ultraviolet rays (EUV light), X-rays, an electron beam (EB), or the like. “Light” in the present specification means actinic rays or radiation.

Unless otherwise specified, “exposure” in the present specification encompasses not only exposure by a bright line spectrum of a mercury lamp, far ultraviolet rays typified by an excimer laser, extreme ultraviolet rays (EUV light), X-rays, or the like, but also lithography by particle beams such as electron beams and ion beams.

In the present specification, a numerical range expressed using “to” is used in a meaning of a range that includes the preceding and succeeding numerical values of “to” as the lower limit value and the upper limit value, respectively.

The bonding direction of divalent groups noted in the present specification is not limited unless otherwise specified. For example, in a case where Y in a compound represented by Formula “X—Y—Z” is —COO—, Y may be —CO—O— or —O—CO—. In addition, the compound may be “X—CO—O—Z” or “X—O—CO—Z”.

In the present specification, (meth)acrylate represents acrylate and methacrylate, and (meth)acryl represents acryl and methacryl.

In the present specification, a weight-average molecular weight (Mw), a number-average molecular weight (Mn), and a dispersity (also referred to as a molecular weight distribution) (Mw/Mn) of a resin are defined as values expressed in terms of polystyrene by means of gel permeation chromatography (GPC) measurement (solvent: tetrahydrofuran, flow amount (amount of a sample injected): 10 μL, columns: TSK gel Multipore HXL-M manufactured by Tosoh Corporation, column temperature: 40° C., flow rate: 1.0 mL/min, and detector: differential refractive index detector) using a GPC apparatus (HLC-8120GPC manufactured by Tosoh Corporation).

In the present specification, an acid dissociation constant (pKa) represents a pKa in an aqueous solution, and is specifically a value determined by computation from a value based on a Hammett's substituent constant and database of publicly known literature values, using the following software package 1. Any of the pKa values described in the present specification indicate values determined by computation using the software package.

Software Package 1: Advanced Chemistry Development (ACD/Labs) Software V 8.14 for Solaris (1994-2007 ACD/Labs).

On the other hand, the pKa can also be determined by a molecular orbital computation method. Examples of a specific method therefor include a method for performing calculation by computing H⁺ dissociation free energy in an aqueous solution based on a thermodynamic cycle. With regard to a computation method for H⁺ dissociation free energy, the H⁺ dissociation free energy can be computed by, for example, density functional theory (DFT), but various other methods have been reported in literature and the like, and are not limited thereto. Furthermore, there are a plurality of software applications capable of performing DFT, and examples thereof include Gaussian 16.

As described above, the pKa in the present specification refers to a value determined by computation from a value based on a Hammett's substituent constant and database of publicly known literature values, using the software package 1, but in a case where the pKa cannot be calculated by the method, a value obtained by Gaussian 16 based on density functional theory (DFT) shall be adopted.

In addition, the pKa in the present specification refers to a “pKa in an aqueous solution” as described above, but in a case where the pKa in an aqueous solution cannot be calculated, a “pKa in a dimethyl sulfoxide (DMSO) solution” shall be adopted.

In the present specification, examples of the halogen atom include a fluorine atom, a chlorine atom, a bromine atom, and an iodine atom.

In the present specification, the solid content means all components other than the solvent. Furthermore, even in a case where the properties of a solid content are liquid, the solid content is used for the calculation.

[Actinic Ray-Sensitive or Radiation-Sensitive Resin Composition]

The actinic ray-sensitive or radiation-sensitive resin composition of an embodiment of the present invention (hereinafter also referred to as a “resist composition”) includes:

a resin of which polarity increases through decomposition by the action of an acid (hereinafter also referred to as an “acid-decomposable resin” or a “resin (A)”, and

a compound that generates an acid upon irradiation with actinic rays or radiation (hereinafter also referred to as a “photoacid generator”),

in which the resin includes a resin (hereinafter also referred to as a “specific acid-decomposable resin”) containing a repeating unit X1 having two or more groups of which polarity increases through decomposition by the action of an acid (hereinafter also referred to as “acid-decomposable groups”) and a repeating unit X2 having a phenolic hydroxyl group (hereinafter also referred to as an “acid-decomposable group”).

The resist composition of the embodiment of the present invention having the configuration exhibits an excellent resolution.

Mechanism of the action of the resist composition of the embodiment of the present invention is not clear, but is presumed to be as follows by the present inventors.

The repeating unit X1 included in the specific acid-decomposable resin has two or more acid-decomposable groups. Therefore, the specific acid-decomposable resin can significantly improve a polarity thereof in a case where it is deprotected by exposure. That is, it is presumed that a resist film formed of the resist composition has an excellent dissolution contrast between the exposed portion and the unexposed portion, and as a result, it exhibits an excellent resolution even with any development treatment of development with an alkali developer or development with an organic solvent-based developer.

In addition, the present inventors have clarified that in a case where the specific acid-decomposable resin has a structure including a repeating unit represented by Formula (A) which will be described later and a repeating unit represented by Formula (C) which will be described later, a dissolution contrast between the exposed portion and the unexposed portion of the resist film is more excellent, and as a result, the resolution property is further excellent.

Furthermore, hereinbelow, the resist composition having a more excellent resolution is also expressed as follows: “the effects of the present invention are more excellent”.

Hereinafter, the resist composition of the embodiment of the present invention will be described in detail.

The resist composition may be either a positive tone resist composition or a negative tone resist composition. In addition, the resist composition may be either a resist composition for alkali development or a resist composition for organic solvent development.

The resist composition is typically a chemically amplified resist composition.

Hereinbelow, various components of the resist composition will first be described in detail.

[Acid-Decomposable Resin (Resin (A))]

The resist composition includes a resin (also referred to as an “acid-decomposable resin” or a “resin (A)” as described above) of which polarity increases through decomposition by the action of an acid.

That is, in the pattern forming method of an embodiment of the present invention, typically, in a case where an alkali developer is adopted as the developer, a positive tone pattern is suitably formed, and in a case where an organic solvent-based developer is adopted as the developer, a negative tone pattern is suitably formed.

The resin (A) usually includes a group of which polarity increases through decomposition by the action of an acid (also referred to as an acid-decomposable group as described above), and the acid-decomposable group usually has a structure in which a polar group is protected by a leaving group that leaves by the action of an acid. In other words, the resin (A) usually has a group that decomposes by the action of an acid to generate a polar group. The resin (A) preferably includes a repeating unit having an acid-decomposable group among those.

The polarity of the resin (A) usually increases by the action of an acid, and thus, the solubility in an alkali developer increases and the solubility in an organic solvent decreases.

The resist composition includes, as the resin (A), a resin (specific acid-decomposable resin) including a repeating unit X1 having two or more acid-decomposable groups and a repeating unit X2 having a phenolic hydroxyl group.

In the resist composition, the content of the specific acid-decomposable resin is preferably 20.0% by mass or more, more preferably 30.0% by mass or more, still more preferably 40.0% by mass or more, particularly preferably 50.0% by mass or more, and most preferably 60.0% by mass or more with respect to the total solid content of the composition. Furthermore, the upper limit value is not particularly limited, but is preferably 90.0% by mass or less, more preferably 85.0% by mass or less, and still more preferably 80.0% by mass or less.

In addition, the specific acid-decomposable resin may be used alone or in combination of a plurality thereof.

In addition, the resist composition may include an acid-decomposable resin (hereinafter also referred to as “another acid-decomposable resin”) other than the specific acid-decomposable resin. Examples of such another acid-decomposable resin include an acid-decomposable resin that does not include a repeating unit having two or more acid-decomposable groups but includes a repeating unit having only one acid-decomposable group, and an acid-decomposable resin that does not include a repeating unit having a phenolic hydroxyl group.

In the resist composition, the content of the resin (A) (the total content of the specific acid-decomposable resin and other acid-decomposable resins) is preferably 40.0% to 90.0% by mass, more preferably 50.0% to 90.0% by mass, and still more preferably 60.0% to 90.0% by mass with respect to the total solid content of the composition.

In addition, the content of the specific acid-decomposable resin in the resist composition is preferably 10% to 100% by mass, more preferably 25% to 100% by mass, still more preferably 45% to 100% by mass, and particularly preferably 55% to 100% by mass with respect to the content of the resin (A) (the total content of the specific acid-decomposable resin and other acid-decomposable resins).

Hereinafter, the specific acid-decomposable resin will first be described.

<<<Specific Acid-Decomposable Resin>>>

The specific acid-decomposable resin includes a repeating unit X1 having two or more acid-decomposable groups (hereinafter also referred to as a “repeating unit X1”) and a repeating unit X2 having a phenolic hydroxyl group (hereinafter also referred to as a “repeating unit X2”).

<<Repeating Unit X1>>

The repeating unit X1 is a repeating unit having two or more acid-decomposable groups. The number of acid-decomposable groups in the repeating unit X1 is not particularly limited, but is, for example, 2 to 4, preferably 2 or 3, and more preferably 2.

<Acid-Decomposable Group>

The acid-decomposable group refers to a group that decomposes by the action of an acid to generate a polar group. The acid-decomposable group preferably has a structure in which the polar group is protected by a leaving group that leaves by the action of an acid. The acid-decomposable group can decompose by the action of an acid to generate a polar group.

As the polar group, an alkali-soluble group is preferable, and examples thereof include an acidic group such as a carboxyl group, a phenolic hydroxyl group, a fluorinated alcohol group, a sulfonic acid group, a phosphoric acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group, and an alcoholic hydroxyl group.

Among those, as the polar group, the carboxyl group, the phenolic hydroxyl group, the fluorinated alcohol group (preferably a hexafluoroisopropanol group), or the sulfonic acid group is preferable, and the carboxyl group is more preferable.

Examples of an aspect of the leaving group that leaves by the action of an acid include groups represented by Formulae (Y1) to (Y4).

—C(Rx₁)(Rx₂)(Rx₃) Formula (Y1):

—C(═O)OC(Rx₁)(Rx₂)(Rx₃) Formula (Y2):

—C(R₃₆)(R₃₇)(OR₃₈) Formula (Y3):

—C(Rn)(H)(Ar) Formula (Y4):

In Formulae (Y1) and (Y2), Rx₁ to Rx₃ each independently represent an (linear or branched) alkyl group, a (monocyclic or polycyclic) cycloalkyl group, an (linear or branched) alkenyl group, or an (monocyclic or polycyclic) aryl group. Furthermore, in a case where all of Rx₁ to Rx₃ are (linear or branched) alkyl groups, it is preferable that at least two of Rx₁, Rx₂, or Rx₃ are methyl groups.

Above all, it is preferable that Rx₁ to Rx₃ each independently represent a linear or branched alkyl group, and it is more preferable that Rx₁ to Rx₃ each independently represent a linear alkyl group.

Two of Rx₁ to Rx₃ may be bonded to each other to form a monocycle or a polycycle.

As the alkyl group of each of Rx₁ to Rx₃, an alkyl group having 1 to 5 carbon atoms, such as a methyl group, an ethyl group, an n-propyl group, an isopropyl group, an n-butyl group, an isobutyl group, and a t-butyl group, is preferable.

Examples of the cycloalkyl group of each of Rx₁ to Rx₃ include monocyclic cycloalkyl groups such as a cyclopentyl group and a cyclohexyl group, and polycyclic cycloalkyl groups such as a norbornyl group, a tetracyclodecanyl group, a tetracyclododecanyl group, and an adamantyl group.

As the alkenyl group of each of Rx₁ to Rx₃, a vinyl group is preferable.

As the aryl group as each of Rx₁ to Rx₃, an aryl group having 6 to 10 carbon atoms is preferable, and examples thereof include a phenyl group, a naphthyl group, and an anthryl group.

As a ring formed by the bonding of two of Rx₁ to Rx₃, a cycloalkyl group is preferable. As the cycloalkyl group formed by the bonding of two of Rx₁ to Rx₃, a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group is preferable, and a monocyclic cycloalkyl group having 5 or 6 carbon atoms is more preferable.

In the cycloalkyl group formed by the bonding of two of Rx₁ to Rx₃, for example, one of the methylene groups constituting the ring may be substituted with a heteroatom such as an oxygen atom, a group having a heteroatom, such as a carbonyl group, or a vinylidene group. In addition, in such the cycloalkyl group, one or more of the ethylene groups constituting the cycloalkane ring may be substituted with a vinylene group.

Examples of a suitable aspect of the group represented by Formula (Y1) or Formula (Y2) include an aspect in which Rx₁ is a methyl group or an ethyl group, and Rx₂ and Rx₃ are bonded to each other to form a cycloalkyl group.

In a case where the resist composition is, for example, a resist composition for EUV exposure or EB exposure, it is preferable that the alkyl group, the cycloalkyl group, the alkenyl group, or the aryl group represented by each of Rx₁ to Rx₃, and a ring formed by the bonding of two of Rx₁ to Rx₃ further has a fluorine atom or an iodine atom as a substituent.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is the hydrogen atom.

Furthermore, the alkyl group, the cycloalkyl group, the aryl group, and the aralkyl group may include a heteroatom such as an oxygen atom, and/or a group having a heteroatom, such as a carbonyl group. For example, in the alkyl group, the cycloalkyl group, the aryl group, and the aralkyl group, one or more of the methylene groups may be substituted with a heteroatom such as an oxygen atom, and/or a group having a heteroatom, such as a carbonyl group.

In a case where the resist composition is, for example, a resist composition for EUV exposure or EB exposure, it is preferable that the monovalent organic group represented by each of R₃₆ to R₃₈ and the ring formed by the mutual bonding of R₃₇ and R₃₈ further have a fluorine atom or an iodine atom as a substituent.

As Formula (Y3), a group represented by Formula (Y3-1) is preferable.

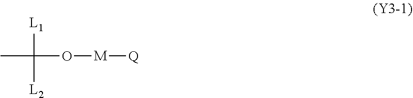

Here, L₁ and L₂ each independently represent a hydrogen atom, an alkyl group, a cycloalkyl group, an aryl group, or a group formed by combination thereof (for example, a group formed by combination of an alkyl group and an aryl group).

M represents a single bond or a divalent linking group.

Q represents an alkyl group which may include a heteroatom, a cycloalkyl group which may include a heteroatom, an aryl group which may include a heteroatom, an amino group, an ammonium group, a mercapto group, a cyano group, an aldehyde group, or a group formed by combination of these groups (for example, a group formed by combination of an alkyl group and a cycloalkyl group).

In the alkyl group and the cycloalkyl group, for example, one of the methylene groups may be substituted with a heteroatom such as an oxygen atom or a group having a heteroatom, such as a carbonyl group.

In addition, it is preferable that one of L₁ or L₂ is a hydrogen atom, and the other is an alkyl group, a cycloalkyl group, an aryl group, or a group formed by combination of an alkylene group and an aryl group.

At least two of Q, M, or L₁ may be bonded to each other to form a ring (preferably a 5- or 6-membered ring).

From the viewpoint of pattern miniaturization, L₂ is preferably a secondary or tertiary alkyl group, and more preferably the tertiary alkyl group. Examples of the secondary alkyl group include an isopropyl group, a cyclohexyl group, and a norbornyl group, and examples of the tertiary alkyl group include a tert-butyl group and an adamantane group. In a case of using these aspects, since the glass transition temperature (Tg) and the activation energy of the resin (A) are increased, it is possible to suppress fogging in addition to ensuring film hardness.

In a case where the resist composition is, for example, a resist composition for EUV exposure or EB exposure, it is also preferable that the alkyl group, the cycloalkyl group, an aryl group, or the group formed by combination of these groups, represented by each of L₁ and L₂, further has a fluorine atom or an iodine atom as a substituent. In addition, it is also preferable that the alkyl group, the cycloalkyl group, the aryl group, and the aralkyl group include a heteroatom such as an oxygen atom, in addition to the fluorine atom and the iodine atom (that is, in the alkyl group, the cycloalkyl group, the aryl group, and the aralkyl group, for example, one of the methylene groups is substituted with a heteroatom such as an oxygen atom or a group having a heteroatom, such as a carbonyl group).

In addition, in a case where the resist composition is, for example, a resist composition for EUV exposure or EB exposure, it is also preferable that in an alkyl group which may include a heteroatom, a cycloalkyl group which may include a heteroatom, an aryl group which may include a heteroatom, an amino group, an ammonium group, a mercapto group, a cyano group, an aldehyde group, or a group formed by combination of these groups, represented by Q, the heteroatom is a heteroatom selected from the group consisting of a fluorine atom, an iodine atom, and an oxygen atom.

In Formula (Y4), Ar represents an aromatic ring group. Rn represents an alkyl group, a cycloalkyl group, or an aryl group. Rn and Ar may be bonded to each other to form a non-aromatic ring. Ar is more preferably the aryl group.

In a case where the resist composition is, for example, a resist composition for EUV exposure or EB exposure, it is also preferable that the aromatic ring group represented by Ar, and the alkyl group, the cycloalkyl group, and the aryl group, represented by Rn, have a fluorine atom and an iodine atom as a substituent.

From the viewpoint that the acid decomposability is further improved, in a case where a non-aromatic ring is directly bonded to a polar group (or a residue thereof) in a leaving group that protects the polar group, it is also preferable that a ring member atom adjacent to the ring member atom directly bonded to the polar group (or a residue thereof) in the non-aromatic ring has no halogen atom such as a fluorine atom as a substituent.

In addition, one aspect of the leaving group that leaves by the action of an acid may be an aspect in which the leaving group is a 2-cyclopentenyl group having a substituent (an alkyl group and the like), such as a 3-methyl-2-cyclopentenyl group, and a cyclohexyl group having a substituent (an alkyl group and the like), such as a 1,1,4,4-tetramethylcyclohexyl group.

In addition, one aspect of the leaving group that leaves by the action of an acid also include a group represented by Formula (Y5).

—C(Ry₁)(Ry₂)(Ry₃) (Y5):

Ry₁ to Ry₃ each independently represent a hydrogen atom, a linear or branched alkyl group, a monocyclic or polycyclic cycloalkyl group, an alkenyl group, an alkynyl group, or a monocyclic or polycyclic aryl group. In addition, any two of Ry₁, Ry₂, or Ry₃ may be bonded to each other to form a monocycle or polycycle (for example, a monocyclic or polycyclic cycloalkyl group, and a cycloalkenyl group).

It should be noted that at least one of Ry₁, Ry₂, or Ry₃ represents an alkenyl group, an alkynyl group, a monocyclic or polycyclic cycloalkenyl group, or a monocyclic or polycyclic aryl group, or any two of Ry₁, Ry₂, or Ry₃ are bonded to each other to form a monocyclic or polycyclic alicyclic ring (for example, a monocyclic or polycyclic cycloalkyl group or a cycloalkenyl group). In addition, there is no case where two or more of Ry₁ to Ry₃ are hydrogen atoms, and in a case where any one of Ry₁, Ry₂, or Ry₃ represents a hydrogen atom, the other two of Ry₁ to Ry₃ are bonded to each other to form a ring having one or more vinylene groups in the ring structure, and at least one of the vinylene groups is present adjacent to a carbon atom to which a hydrogen atom represented by any one of Ry 1, Ry₂, or Ry₃ is bonded.

As the alkyl group of each of Ry₁ to Ry₃, an alkyl group having 1 to 4 carbon atoms, such as a methyl group, an ethyl group, an n-propyl group, an isopropyl group, an n-butyl group, an isobutyl group, and a t-butyl group, is preferable.

Examples of the cycloalkyl group represented by each of Ry₁ to Ry₃ include monocyclic cycloalkyl groups such as a cyclopentyl group and a cyclohexyl group, and polycyclic cycloalkyl groups such as a norbornyl group, a tetracyclodecanyl group, a tetracyclododecanyl group, and an adamantyl group.

As the alkenyl group of each of Ry₁ to Ry₃, a vinyl group is preferable.

As the alkynyl group of each of Ry₁ to Ry₃, an ethynyl group is preferable.

As the aryl group of each of Ry₁ to Ry₃, an aryl group having 6 to 15 carbon atoms is preferable, an aryl group having 6 to 10 carbon atoms is more preferable, and examples thereof include a phenyl group, a naphthyl group, and an anthryl group.

As the cycloalkenyl group of each of Ry₁ to Ry₃, a structure including a double bond in a part of a monocyclic cycloalkyl group such as a cyclopentyl group and a cyclohexyl group is preferable.

As the cycloalkyl group formed by the bonding of two of Ry₁ to Ry₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is also preferable. Among those, a monocyclic cycloalkyl group having 5 or 6 carbon atoms is preferable.

In the cycloalkyl group and cycloalkenyl group formed by the bonding of two of Ry₁ to Ry₃, for example, one of the methylene groups constituting the ring may be substituted with a heteroatom such as an oxygen atom, a group having a heteroatom, such as a carbonyl group, an —SO₂— group, and an —SO₃— group, a vinylidene group, or a combination thereof. In addition, in such the cycloalkyl group and cycloalkenyl group, one or more of the ethylene groups constituting the cycloalkane ring and the cycloalkene ring may be substituted with a vinylene group.

Examples of a suitable aspect of the group represented by Formula (Y5) include an aspect in which Ry₁ is a methyl group, an ethyl group, a vinyl group, an allyl group, or an aryl group, and Ry₂ and Rx₃ are bonded to each other to form a cycloalkyl group or a cycloalkenyl group, and an aspect in which Ry₁ is a hydrogen atom, Ry₂ and Ry₃ are bonded to each other to form a ring having one or more vinylene groups in the ring structure, and at least one of the vinylene groups is present adjacent to a carbon atom to which a hydrogen atom represented by Ry₁ is bonded.

In a case where the group represented by Formula (Y5) has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

From the viewpoint that the effects of the present invention are more excellent, it is preferable that the number of carbon atoms of the leaving group that leaves by the action of an acid in the acid-decomposable group is 7 or less. Among those, it is more preferable that the leaving group that leaves by the action of an acid in the acid-decomposable group is a group represented by any one of Formula (Y1), . . . , or (Y5) mentioned above, and has 7 or less carbon atoms.

<Repeating Unit X1>

The repeating unit X1 is not particularly limited as long as it is a repeating unit having two or more acid-decomposable groups as described above, but from the viewpoint that the effects of the present invention are more excellent, it is preferable that the repeating unit X1 is a repeating unit represented by Formula (A).

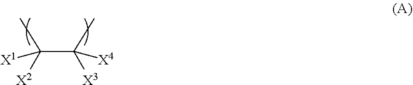

In the formula, X¹ to X⁴ each independently represent a hydrogen atom, an alkyl group, or a group represented by Formula (AP). It should be noted that two or more of X¹ to X⁴ represent a group represented by Formula (AP). * represents a bonding position.

*-L¹-M¹ Formula (AP):

In the formula, L¹ represents a single bond or a divalent organic group. M¹ represents an acid-decomposable group.

Furthermore, in the group represented by Formula (AP), the acid-decomposable group represented by M¹ may decompose by the action of an acid to generate a polar group.

Hereinafter, Formula (A) will be described.

In Formula (A), the alkyl group represented by each of X¹ to X⁴ may be linear, branched, or cyclic. The alkyl group preferably has 1 to 12 carbon atoms, more preferably has 1 to 10 carbon atoms, and still more preferably has 1 to 6 carbon atoms.

In Formula (AP), the divalent organic group represented by L¹ is not particularly limited, and examples thereof include a divalent organic group in which one or more or two or more kinds selected from the group consisting of —CO—, —O—, —S—, —SO—, —SO₂—, and a hydrocarbon group (for example, an alkylene group, an alkenylene group, and an arylene group) are linked. Furthermore, the alkylene group and the alkenylene group may be linear, branched, or cyclic. In addition, the number of carbon atoms in the hydrocarbon group is not particularly limited, but is preferably 1 to 12, more preferably 1 to 8, still more preferably 1 to 6, and particularly preferably 1 to 3.

As the divalent organic group represented by L¹, among those, a divalent organic group in which one or more or two or more selected from the group consisting of —CO—, —O—, —S—, —SO—, —SO₂—, an alkylene group, and an alkenylene group are linked is preferable, an alkylene group having 1 to 6 carbon atoms is more preferable, and an alkylene group having 1 to 3 carbon atoms is still more preferable.

As L¹, from the viewpoint that the effects of the present invention are more excellent, a single bond or an alkylene group having 1 to 3 carbon atoms is preferable.

Specific examples of the acid-decomposable group represented by M¹ in Formula (AP) include the above-mentioned acid-decomposable groups.

From the viewpoint that the effects of the present invention are more excellent, it is preferable that the leaving group that leaves by the action of an acid in the acid-decomposable group represented by M¹ has 7 or less carbon atoms. In addition, among those, it is more preferable that the leaving group that leaves by the action of the above-mentioned acid is a group represented by any one of Formula (Y1), . . . , or (Y5) mentioned above, and has 7 or less carbon atoms.

From the viewpoint that the effects of the present invention are more excellent, it is preferable that the group represented by Formula (AP) is a group represented by Formula (AP′).

*-L¹-COOM¹¹ Expression (AP′):

In the formula, L¹ and * have the same definitions as L¹ and * in Formula (AP) mentioned above, respectively, and preferred aspects thereof are also the same.

M¹¹ represents a leaving group that leaves by the action of an acid. Specific examples of the leaving group that leaves by the action of an acid, represented by M¹¹, include the leaving group contained in the above-mentioned acid-decomposable group. With regard to the leaving group that leaves by the action of an acid, represented by M¹¹, from the viewpoint that the effects of the present invention are more excellent, it is preferable that the leaving group that leaves by the action of an acid has 7 or less carbon atoms, and it is more preferable that the leaving group that leaves by the action of an acid is a group represented by any one of Formula (Y1), . . . , or (Y5) mentioned above, and has 7 or less carbon atoms.

Furthermore, the group represented by Formula (AP′) decomposes by the action of an acid (in other words, M¹¹ leaves) to generate a carboxyl group.

In one aspect of the repeating unit represented by Formula (A), among those, the repeating unit is preferably a repeating unit in which any two of X¹ to X⁴ represent a hydrogen atom, and the other two of X¹ to X⁴ represent a group represented by Formula (AP).

The repeating unit represented by Formula (A) can be synthesized, for example, using an itaconic acid derivative, a methylene malonate derivative, or the like as a raw material monomer.

A content of the repeating unit X¹ is preferably 15% by mass or more, more preferably 20% by mass or more, and still more preferably 30% by mass or more with respect to all the repeating units in the specific acid-decomposable resin. In addition, the upper limit value is preferably 85% by mass or less, more preferably 70% by mass or less, and particularly preferably 65% by mass or less.

In the specific acid-decomposable resin, the repeating unit X1 may be included alone or in combination of two or more kinds thereof.

Hereinafter, specific examples of the repeating unit X1 are shown, but the repeating unit X1 is not limited thereto.

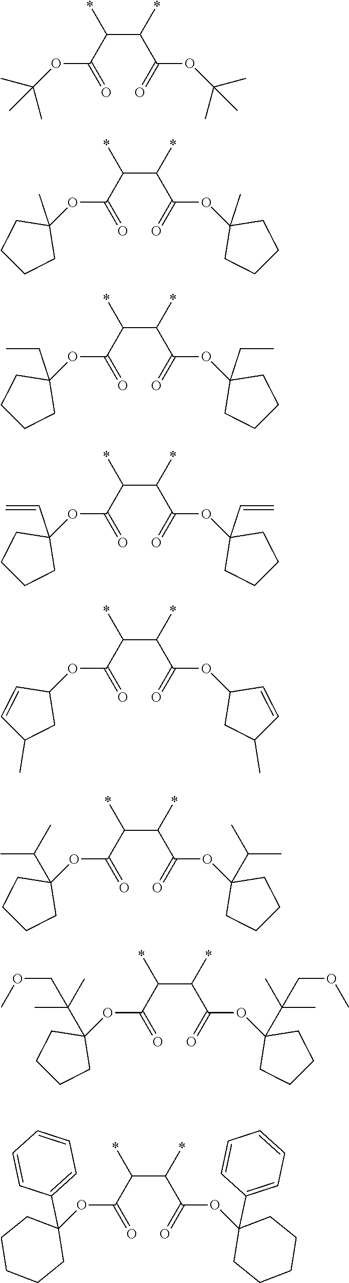

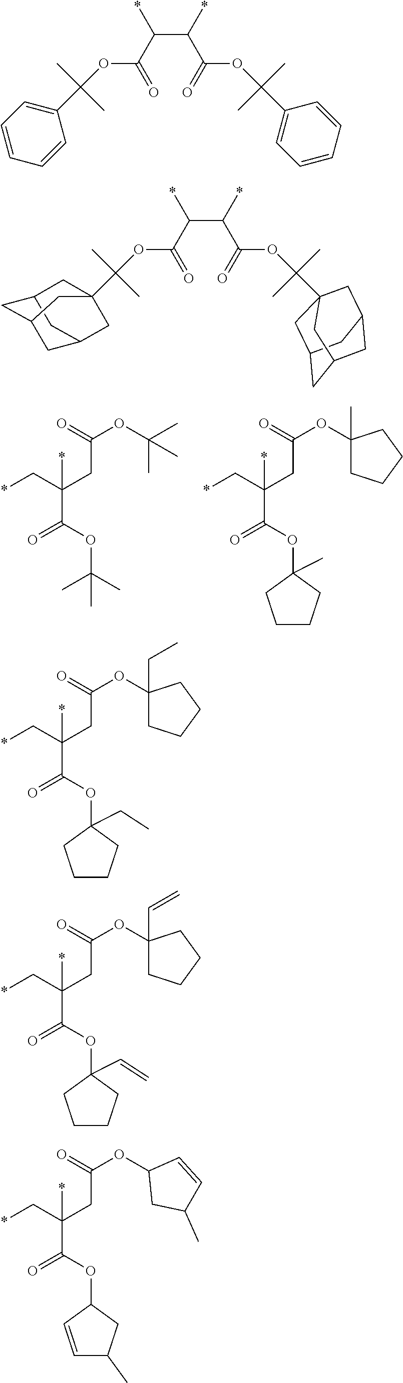

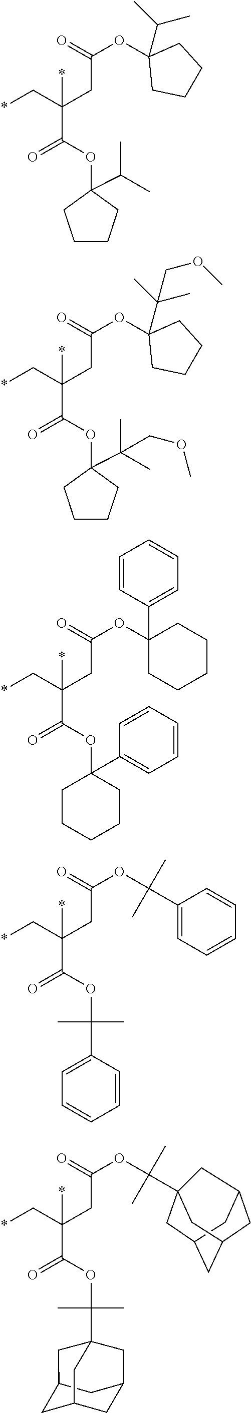

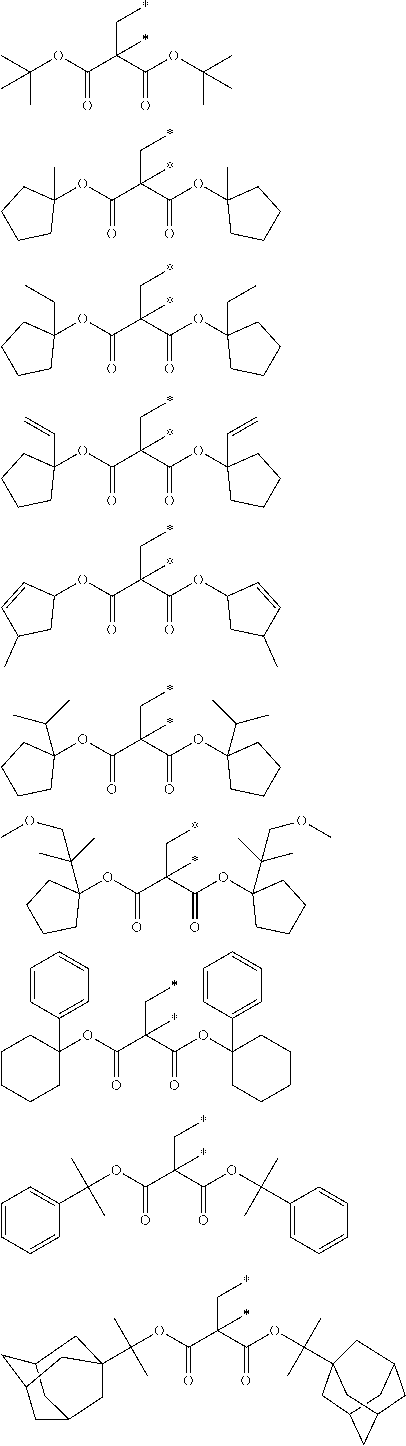

<<Repeating Unit X2>>

The repeating unit X2 is a repeating unit having a phenolic hydroxyl group. The number of the phenolic hydroxyl groups in the repeating unit X2 is not particularly limited, but is, for example, 1 to 5, and preferably 1 to 3. Furthermore, the phenolic hydroxyl group is intended to be a hydroxyl group directly bonded to the aromatic ring. The aromatic ring as mentioned herein includes both an aromatic hydrocarbon ring and an aromatic heterocyclic ring.

One aspect of the repeating unit X2 may be a repeating unit represented by Formula (I).

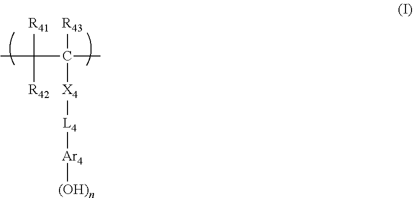

In Formula (I),

R₄₁, R₄₂, and R₄₃ each independently represent a hydrogen atom or a substituent. It should be noted that R₄₂ may be bonded to Ar₄ to form a ring, where in such a case R₄₂ represents a single bond or an alkylene group.

X⁴ represents a single bond, —COO—, or —CONR₆₄—.

R₆₄ represents a hydrogen atom or an alkyl group.

L₄ represents a single bond or an alkylene group.

Ar₄ represents an (n+1)-valent aromatic ring group, and in a case where Ar₄ is bonded to R₄₂ to form a ring, Ar₄ represents an (n+2)-valent aromatic ring group.

n represents an integer of 1 to 5.

Specifically, the substituent represented by each of R₄₁, R₄₂, and R₄₃ preferably represents an alkyl group, a cycloalkyl group, a halogen atom, a cyano group, or an alkoxycarbonyl group.

As the alkyl group represented by each of R₄₁, R₄₂, and R₄₃ in Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group is preferable, an alkyl group having 8 or less carbon atoms is more preferable, and an alkyl group having 3 or less carbon atoms is still more preferable.

The cycloalkyl group of each of R₄₁, R₄₂, and R₄₃ in Formula (I) may be monocyclic or polycyclic. Among those, a monocyclic cycloalkyl group having 3 to 8 carbon atoms, such as a cyclopropyl group, a cyclopentyl group, and a cyclohexyl group, is preferable.

Examples of the halogen atom of each of R₄₁, R₄₂, and R₄₃ in Formula (I) include a fluorine atom, a chlorine atom, a bromine atom, and an iodine atom, and the fluorine atom is preferable.

As the alkyl group included in the alkoxycarbonyl group of each of R₄₁, R₄₂, and R₄₃ in Formula (I), the same ones as the alkyl group in each of R₄₁, R₄₂, and R₄₃ are preferable.

As the alkylene group in L₄, an alkylene group having 1 to 8 carbon atoms, such as a methylene group, an ethylene group, a propylene group, a butylene group, a hexylene group, and an octylene group, is preferable.

Ar₄ represents an (n+1)-valent aromatic ring group. The divalent aromatic ring group in a case where n is 1 is preferably for example, an arylene group having 6 to 18 carbon atoms, such as a phenylene group, a tolylene group, a naphthylene group, and an anthracenylene group, or a divalent aromatic ring group including a heterocyclic ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Furthermore, the aromatic ring group may have a substituent.

Specific examples of the (n+1)-valent aromatic ring group in a case where n is an integer of 2 or more include groups formed by removing any (n−1) hydrogen atoms from the above-mentioned specific examples of the divalent aromatic ring group.

The (n+1)-valent aromatic ring group may further have a substituent.

As Ar₄, an aromatic ring group having 6 to 18 carbon atoms is preferable, and a benzene ring group, a naphthalene ring group, and a biphenylene ring group are more preferable.

The repeating unit represented by Formula (I) is preferably equipped with a hydroxystyrene structure. That is, Ar₄ is preferably the benzene ring group.

Examples of the alkyl group of R₆₄ in —CONR₆₄— represented by X⁴ (R₆₄ represents a hydrogen atom or an alkyl group) include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and an alkyl group having 8 or less carbon atoms, is preferable.

As X⁴, a single bond, —COO—, or —CONH— is preferable, and the single bond or —COO— is more preferable.

Examples of the substituent the can be contained in the above-mentioned alkyl group, cycloalkyl group, alkoxycarbonyl group, alkylene group, and (n+1)-valent aromatic ring group include an alkyl group, a cycloalkyl group, an aryl group, an amino group, an amide group, a ureide group, a urethane group, a hydroxyl group, a carboxyl group, a halogen atom, an alkoxy group, a thioether group, an acyl group, an acyloxy group, an alkoxycarbonyl group, an alkenyl group, an aralkyl group, an alkylcarbonyloxy group, an alkylsulfonyloxy group, an alkyloxycarbonyl group, an aryloxycarbonyl group, a cyano group, and a nitro group. The substituent preferably has 8 or less carbon atoms.

The repeating unit represented by Formula (I) is preferably a repeating unit represented by Formula (1), and more preferably a repeating unit represented by Formula (C).

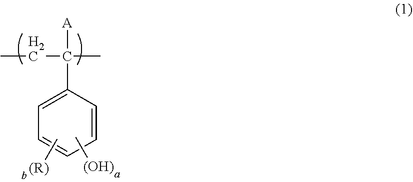

In Formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group, and in a case where a plurality of R's are present, R's may be the same as or different from each other. In a case where there are a plurality of R's, R's may be bonded to each other to form a ring.

a represents an integer of 1 to 5, and preferably represents an integer of 1 to 3.

b represents an integer of 0 to (5-a).

The alkyl group, the cycloalkyl group, and the halogen atom represented by A are the same as in the preferred embodiments of the alkyl group, the cycloalkyl group, and the halogen atom represented by each of R₄₁, R₄₂, and R₄₃ in Formula (I), respectively.

The alkyl group, the cycloalkyl group, and the halogen atom represented by R are the same as in the preferred embodiments of the alkyl group, the cycloalkyl group, and the halogen atom represented by each of R₄₁, R₄₂, and R₄₃ in Formula (I), respectively.

As the aryl group represented by R, an aryl group having 6 to 15 carbon atoms is preferable, an aryl group having 6 to 10 carbon atoms is more preferable, and examples thereof include a phenyl group, a naphthyl group, and an anthryl group.

As the alkenyl group represented by R, a vinyl group is preferable.

The number of carbon atoms of the alkyl group moiety in each of the aralkyl group, the alkoxy group, the alkylcarbonyloxy group, the alkylsulfonyloxy group, and the alkyloxycarbonyl group represented by R is not particularly limited, but is preferably 1 to 12, and more preferably 1 to 6.

Examples of the aryl group moiety in each of the aryloxycarbonyl group and the aralkyl group represented by R include the same as the aryl group represented by R.

Among those, R is preferably a hydrogen atom.

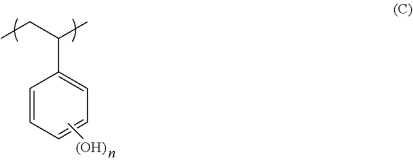

In the formula, n represents an integer of 1 to 5.

The content of the repeating unit X2 is preferably 5% by mass or more, and more preferably 10% by mass or more with respect to all the repeating units in the specific acid-decomposable resin. In addition, the upper limit value is preferably 60% by mass or less, more preferably 50% by mass or less, still more preferably 45% by mass or less, and particularly preferably 40% by mass or less.

In the specific acid-decomposable resin, the repeating unit X2 may be included alone or in combination of two or more kinds thereof.

The repeating unit X2 will be exemplified below. In the formulae, a represents 1 or 2.

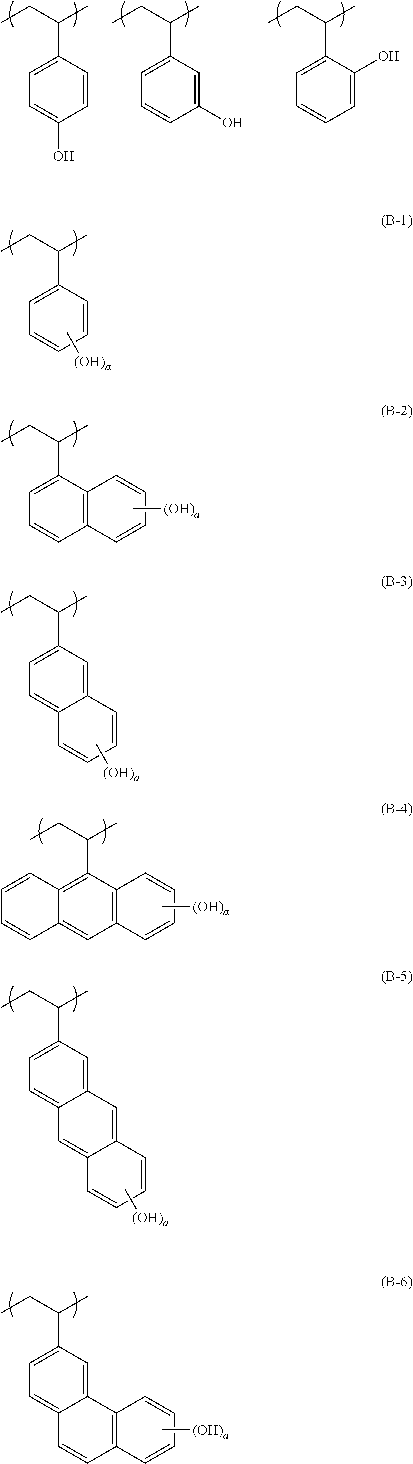

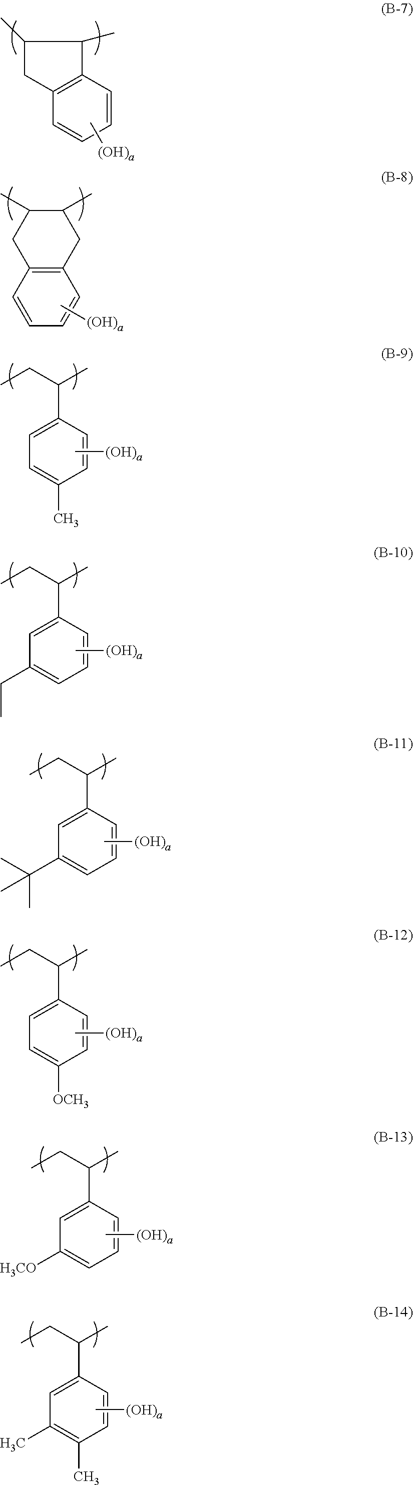

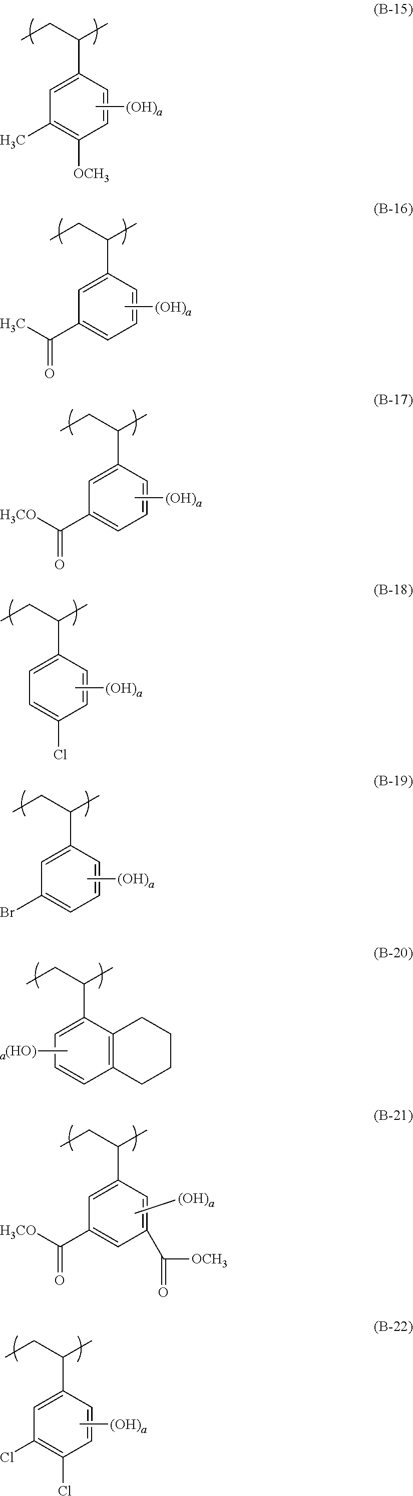

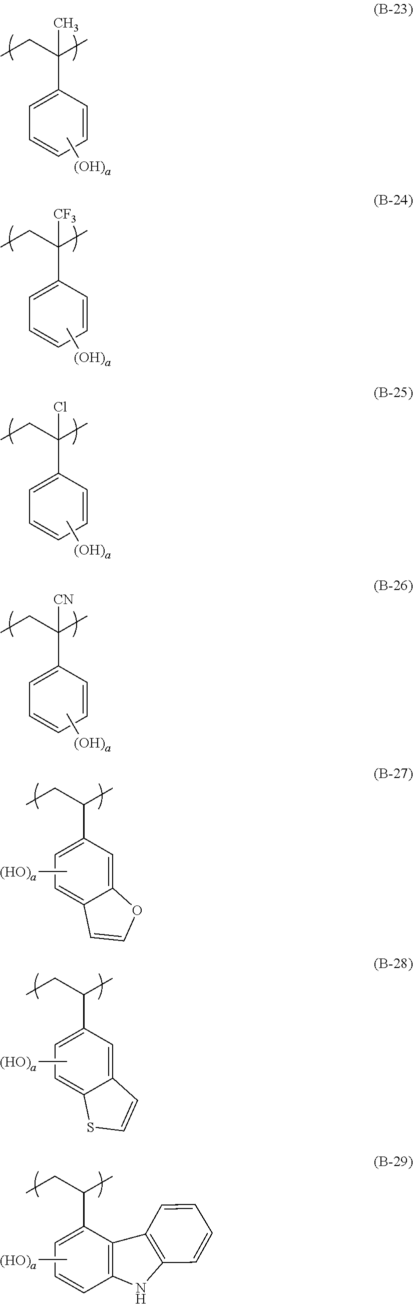

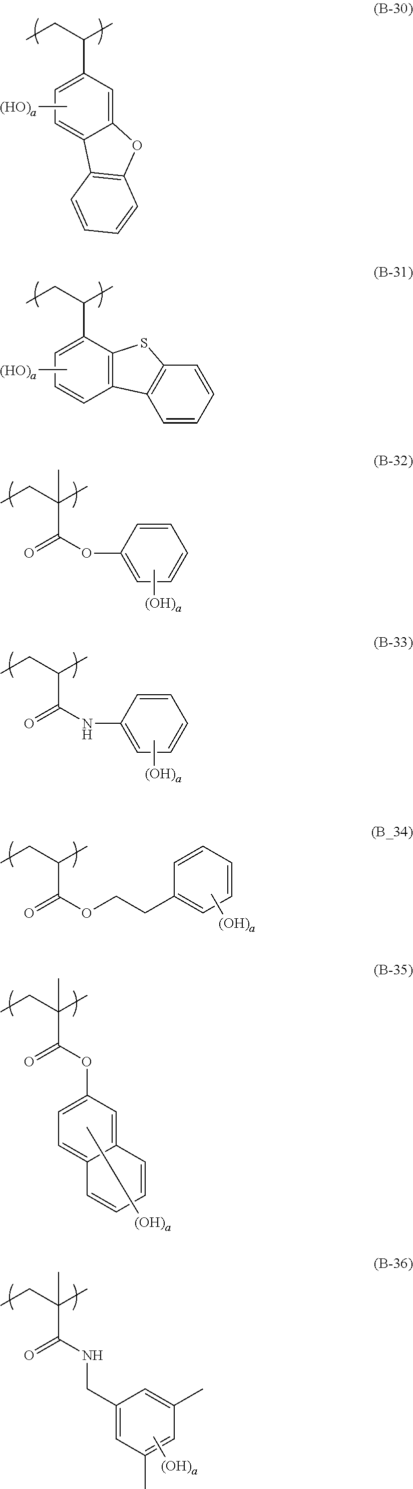

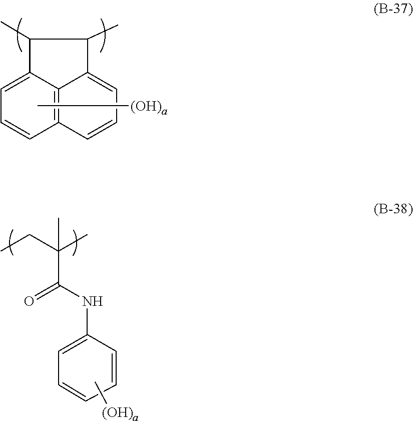

Hereinafter, in the formula, R represents a hydrogen atom or a methyl group, and a represents 2 or 3.

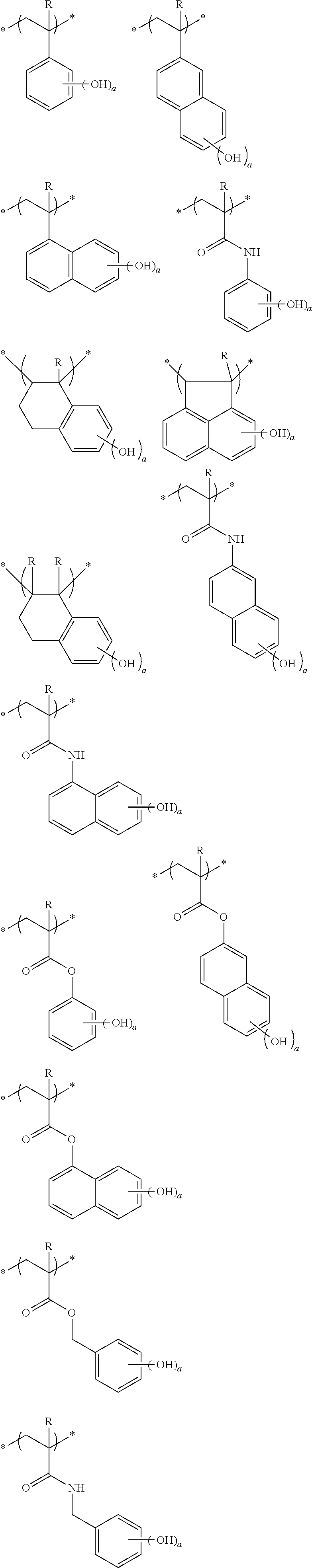

<<Other Repeating Units>>

The specific acid-decomposable resin may include another repeating unit other than the above-mentioned repeating units.

Examples of such another repeating unit include a repeating unit having an acid-decomposable group other than the above-mentioned repeating unit X1.

<Another Repeating Unit Having Acid-Decomposable Group Other than Repeating Unit X1>

The specific acid-decomposable group may include another repeating unit having an acid-decomposable group other than the above-mentioned repeating unit X1 (hereinafter also referred to as “another repeating unit having an acid-decomposable group”).

Such another repeating unit having an acid-decomposable group is intended to be a repeating unit that does not correspond to the above-mentioned repeating unit X1 (in other words, a repeating unit having only one acid-decomposable group).

One aspect of such another repeating unit having an acid-decomposable group may be a repeating unit represented by Formula (A) can be mentioned.

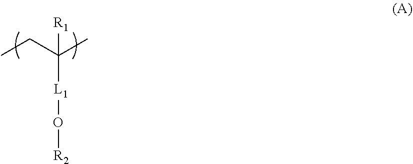

L₁ represents a divalent linking group which may have a fluorine atom or an iodine atom, R₁ represents a hydrogen atom, a fluorine atom, an iodine atom, a fluorine atom, an alkyl group which may have an iodine atom, or an aryl group which may have a fluorine atom or an iodine atom, and R₂ represents a leaving group that leaves by the action of an acid and may have a fluorine atom or an iodine atom. It is preferable that at least one of L₁, R₁, or R₂ has a fluorine atom or an iodine atom.

L₁ represents a divalent linking group which may have a fluorine atom or an iodine atom. Examples of the divalent linking group which may have a fluorine atom or an iodine atom include —CO—, —O—, —S—, —SO—, —SO₂—, a hydrocarbon group which may have a fluorine atom or an iodine atom (for example, an alkylene group, a cycloalkylene group, an alkenylene group, and an arylene group), and a linking group formed by the linking of a plurality of these groups. Among those, as L₁, —CO—, an arylene group, or -arylene group-alkylene group having a fluorine atom or an iodine atom—is preferable, and from the viewpoint that the pKa of an acid group that can be generated by elimination of R₂ by the action of an acid, —CO— or -arylene group-alkylene group having a fluorine atom or an iodine atom—is more preferable.

As the arylene group, a phenylene group is preferable.

The alkylene group may be linear or branched. The number of carbon atoms of the alkylene group is not particularly limited, but is preferably 1 to 10, and more preferably 1 to 3.

The total number of fluorine atoms and iodine atoms included in the alkylene group having a fluorine atom or an iodine atom is not particularly limited, but is preferably 2 or more, more preferably 2 to 10, and still more preferably 3 to 6.

R₁ represents a hydrogen atom, a fluorine atom, an iodine atom, an alkyl group which may have a fluorine atom or an iodine atom, or an aryl group which may have a fluorine atom or an iodine atom.

The alkyl group may be linear or branched. The number of carbon atoms of the alkyl group is not particularly limited, but is preferably 1 to 10, and more preferably 1 to 3.

The total number of fluorine atoms and iodine atoms included in the alkyl group having a fluorine atom or an iodine atom is not particularly limited, but is preferably 1 or more, more preferably 1 to 5, and still more preferably 1 to 3.

The alkyl group may include a heteroatom such as an oxygen atom, other than a halogen atom.

R₂ represents a leaving group that leaves by the action of an acid and may have a fluorine atom or an iodine atom. Examples of the leaving group which may have a fluorine atom or an iodine atom include a leaving group represented by each of Formulae (Y1) to (Y4) which may be contained in the above-mentioned repeating unit X1, and suitable aspects thereof are also the same.

In addition, as such another repeating unit having an acid-decomposable group, a repeating unit represented by Formula (AI) is also preferable.

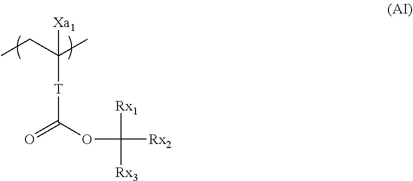

In Formula (AI),

Xa₁ represents a hydrogen atom, or an alkyl group which may have a substituent.

T represents a single bond or a divalent linking group.

Rx₁ to Rx₃ each independently represent an (linear or branched) alkyl group, a (monocyclic or polycyclic) cycloalkyl group, an (linear or branched) alkenyl group, or an (monocyclic or polycyclic) aryl group. It should be noted that in a case where all of Rx₁ to Rx₃ are (linear or branched) alkyl groups, it is preferable that at least two of Rx₁, Rx₂, or Rx₃ are methyl groups.

Two of Rx₁ to Rx₃ may be bonded to each other to form a monocycle or polycycle (a monocyclic or polycyclic cycloalkyl group and the like).

Examples of the alkyl group which may have a substituent, represented by Xa₁, include a methyl group and a group represented by —CH₂—R₁₁. R₁₁ represents a halogen atom (a fluorine atom or the like), a hydroxyl group, or a monovalent organic group, examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. As Xa₁, a hydrogen atom, a methyl group, a trifluoromethyl group, or a hydroxymethyl group is preferable.

Examples of the divalent linking group of T include an alkylene group, an aromatic ring group, a —COO-Rt- group, and an —O-Rt- group. In the formulae, Rt represents an alkylene group or a cycloalkylene group.

T is preferably the single bond or the —COO-Rt- group. In a case where T represents the —COO-Rt-group, Rt is preferably an alkylene group having 1 to 5 carbon atoms, and more preferably a —CH₂— group, a —(CH₂)₂— group, or a —(CH₂)₃— group.

As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group of each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the aryl group as each of Rx₁ to Rx₃, an aryl group having 6 to 10 carbon atoms is preferable, and examples thereof include a phenyl group, a naphthyl group, and an anthryl group.

As the alkenyl group of each of Rx₁ to Rx₃, a vinyl group is preferable.

As the cycloalkyl group formed by the bonding of two of Rx₁ to Rx₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is also preferable. Among those, a monocyclic cycloalkyl group having 5 or 6 carbon atoms is preferable.

In the cycloalkyl group formed by the bonding of two of Rx₁ to Rx₃, for example, one of the methylene groups constituting the ring may be substituted with a heteroatom such as an oxygen atom, a group having a heteroatom, such as a carbonyl group, or a vinylidene group. In addition, in such the cycloalkyl group, one or more of the ethylene groups constituting the cycloalkane ring may be substituted with a vinylene group.

With regard to the repeating unit represented by Formula (AI), for example, an aspect in which Rx₁ is a methyl group or an ethyl group, and Rx₂ and Rx₃ are bonded to each other to form the above-mentioned cycloalkyl group is preferable.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

The repeating unit represented by Formula (AI) is preferably an acid-decomposable tertiary alkyl (meth)acrylate ester-based repeating unit (the repeating unit in which Xa₁ represents a hydrogen atom or a methyl group, and T represents a single bond).

Specific examples of such another repeating unit having an acid-decomposable group are shown below, but the present invention is not limited thereto. Furthermore, in the formulae, Xa₁ represents H, CH₃, CF₃, or CH₂OH, and Rxa and Rxb each represent a linear or branched alkyl group having 1 to 5 carbon atoms.

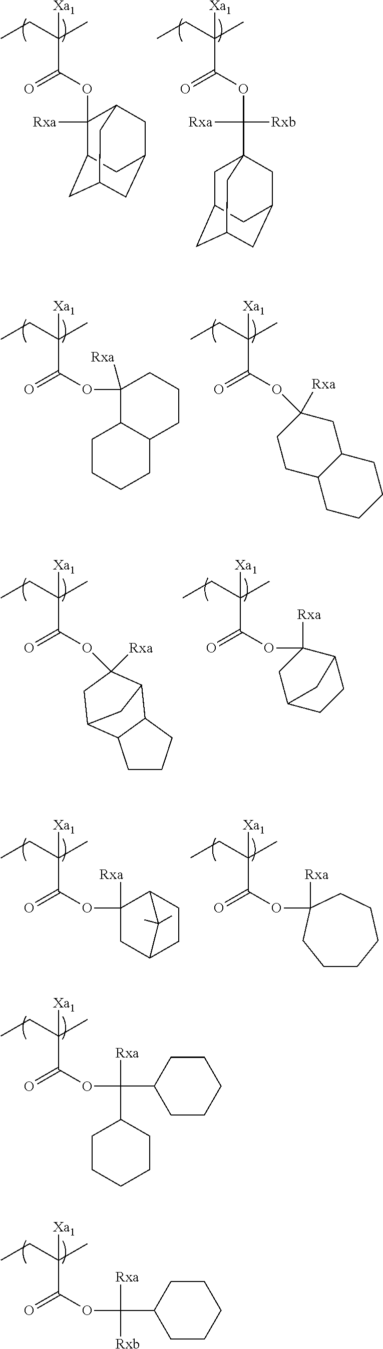

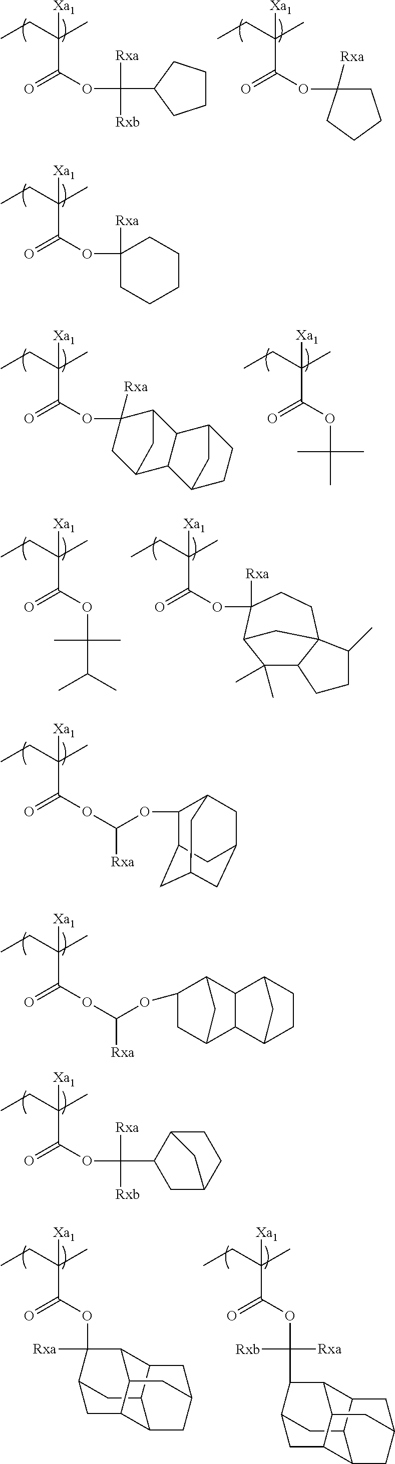

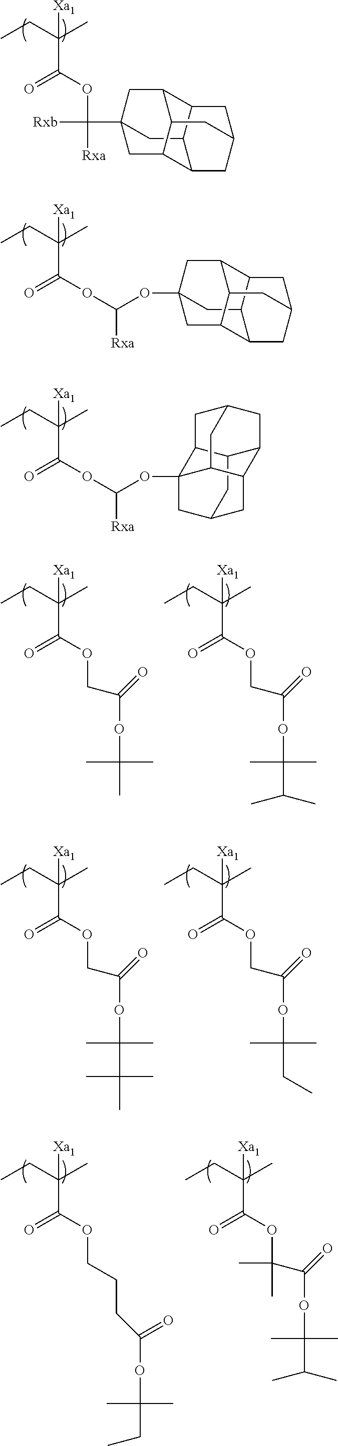

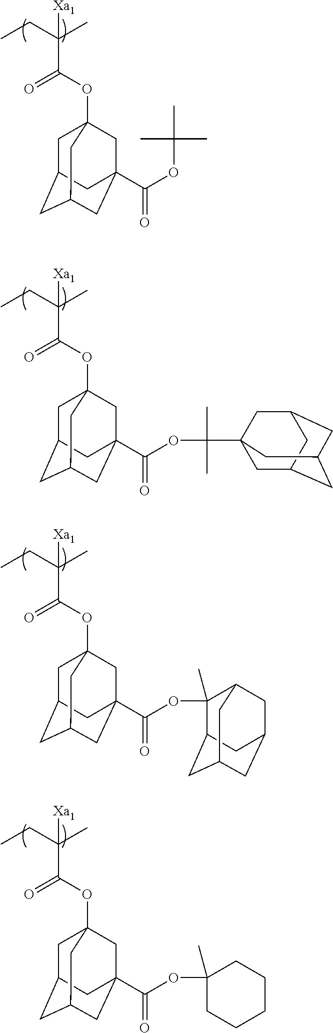

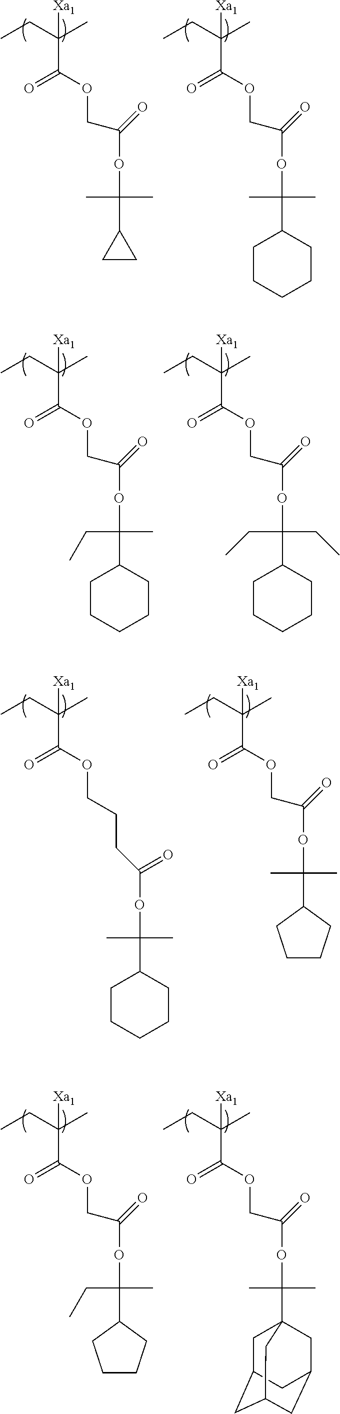

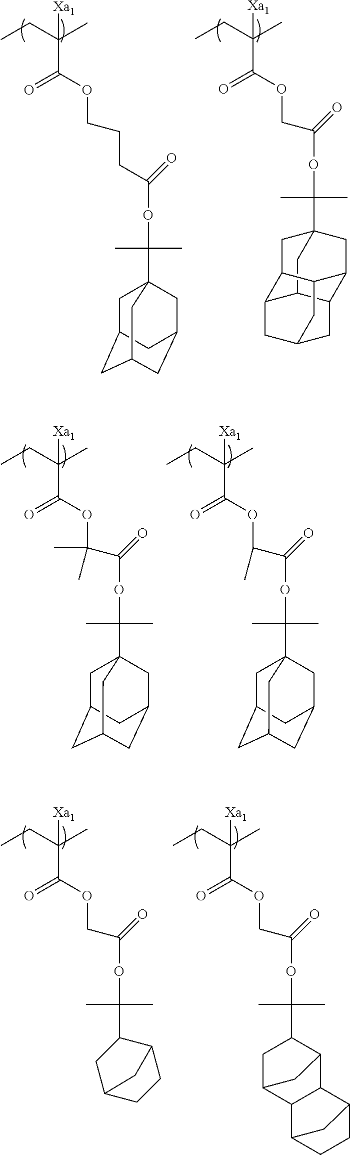

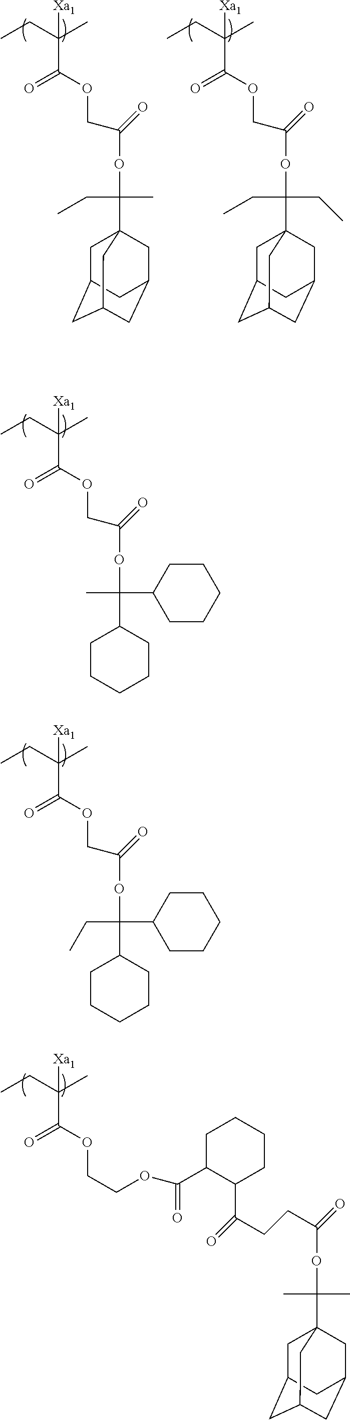

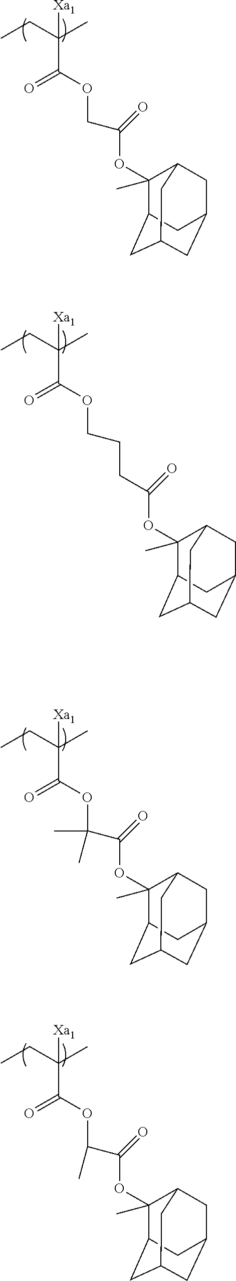

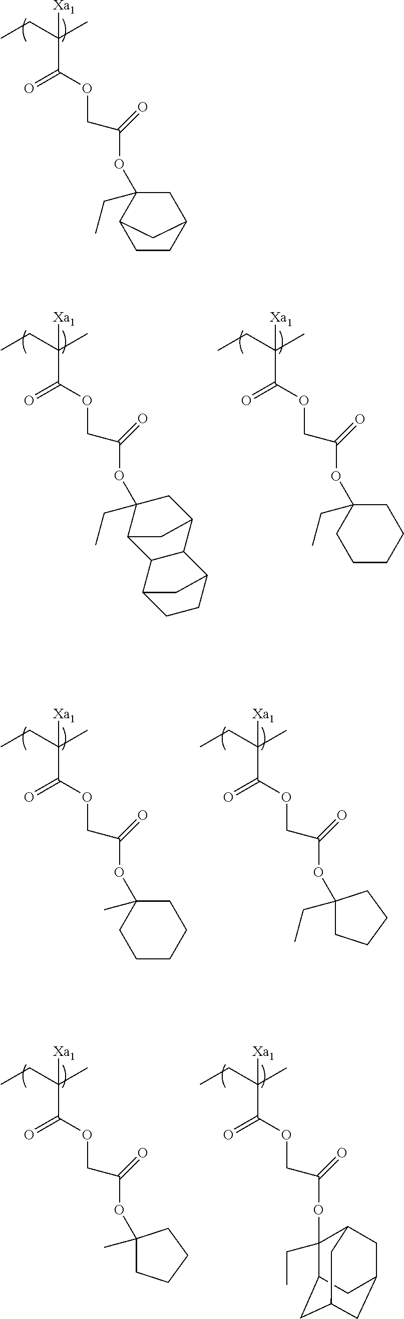

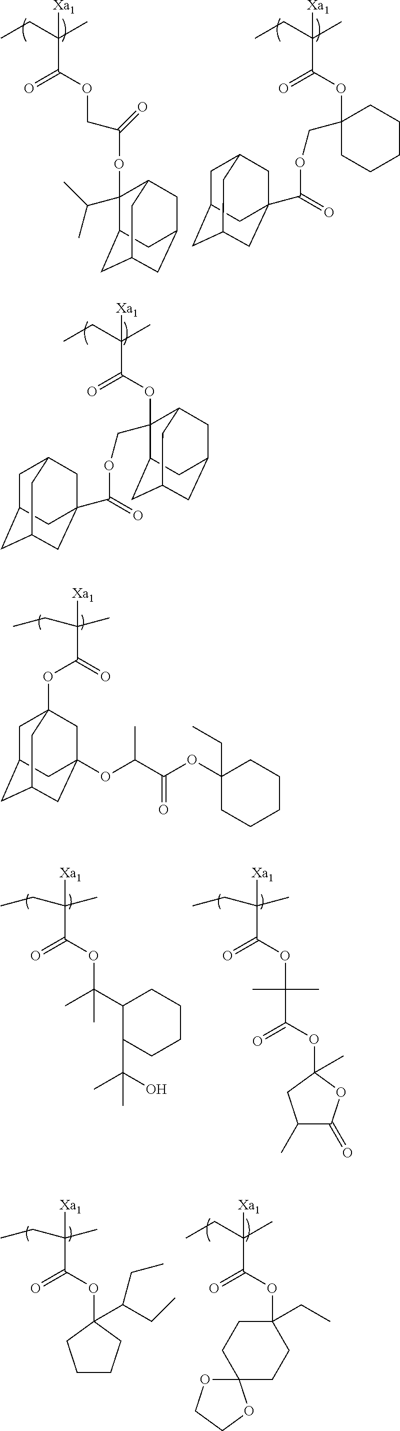

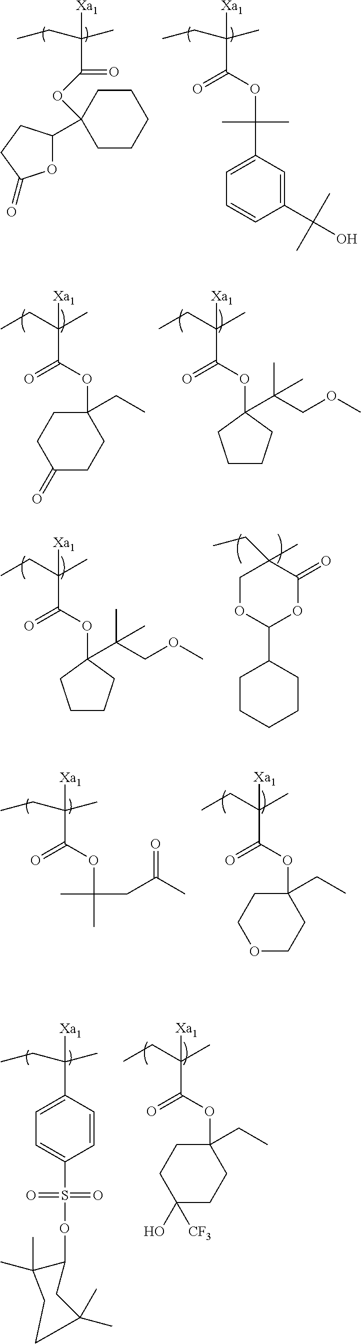

In addition, as such another repeating unit having an acid-decomposable group, a repeating unit represented by Formula (B) is also preferable.

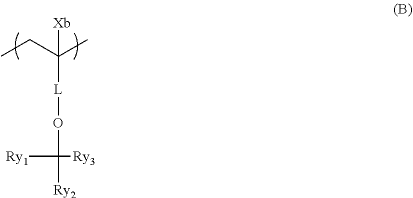

In Formula (B),

Xb represents a hydrogen atom, a halogen atom, or an alkyl group which may have a substituent.

L represents a single bond, or a divalent linking group which may have a substituent.

Ry₁, Ry₂, and Ry₃ have the same definitions as Ry₁, Ry₂, and Ry₃ in the leaving group represented by Formula (Y5) which may be contained in the repeating unit X1, respectively, and preferred aspects thereof are also the same.

Examples of the alkyl group which may have a substituent, represented by Xb, include a methyl group and a group represented by —CH₂—R₁₁. R₁₁ represents a halogen atom (a fluorine atom or the like), a hydroxyl group, or a monovalent organic group, examples thereof include an alkyl group having 5 or less carbon atoms, which may be substituted with a halogen atom, an acyl group having 5 or less carbon atoms, which may be substituted with a halogen atom, and an alkoxy group having 5 or less carbon atoms, which may be substituted with a halogen atom; and an alkyl group having 3 or less carbon atoms is preferable, and a methyl group is more preferable. As Xb, a hydrogen atom, a fluorine atom, a methyl group, a trifluoromethyl group, or a hydroxymethyl group is preferable.

Examples of the divalent linking group of L include an —Rt- group, a —CO— group, a —COO-Rt- group, a —COO-Rt-CO— group, an —Rt-CO— group, and an —O-Rt- group. In the formulae, Rt represents an alkylene group, a cycloalkylene group, or an aromatic ring group, and is preferably the aromatic ring group.

As L, the —Rt- group, the —CO— group, the —COO-Rt-CO— group, or the —Rt-CO— group is preferable. Rt may have a substituent such as, for example, a halogen atom, a hydroxyl group, and an alkoxy group.

Furthermore, in a case where each of the groups in Formula (B) has a substituent, examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms). The substituent preferably has 8 or less carbon atoms.

As the repeating unit represented by Formula (B), an acid-decomposable (meth)acrylic acid tertiary ester-based repeating unit (a repeating unit in which Xb represents a hydrogen atom or a methyl group, and L represents a —CO— group), an acid-decomposable hydroxystyrene tertiary alkyl ether-based repeating unit (a repeating unit in which Xb represents a hydrogen atom or a methyl group and L represents a phenyl group), or an acid-decomposable styrenecarboxylic acid tertiary ester-based repeating unit (a repeating unit in which Xb represents a hydrogen atom or a methyl group, and L represents a —Rt-CO— group (Rt is an aromatic ring group)) is preferable.

Specific examples of the repeating unit having an acid-decomposable group represented by Formula (B) are shown below.

Furthermore, in the formula, Xb and L₁ have the same definitions as Xb and L in Formula (B), respectively. In addition, Ar represents an aromatic ring group. R represents a substituent such as a hydrogen atom, an alkyl group, a cycloalkyl group, an aryl group, an aralkyl group, an alkenyl group, a hydroxyl group, an alkoxy group, an acyloxy group, a cyano group, a nitro group, an amino group, a halogen atom, an ester group (—OCOR′″ or —COOR′″: R′″ is an alkyl group or fluorinated alkyl group having 1 to 20 carbon atoms), or a carboxyl group. R′ represents a linear or branched alkyl group, a monocyclic or polycyclic cycloalkyl group, an alkenyl group, an alkynyl group, or a monocyclic or polycyclic aryl group. Q represents a heteroatom such as an oxygen atom, a group having a heteroatom, such as a carbonyl group, a —SO₂— group, and a —SO₃— group, a vinylidene group, or a combination thereof 1, n, and m each represent an integer of 0 or more. The upper limit value is not limited, and is, for example, 6 or less, and preferably 4 or less.

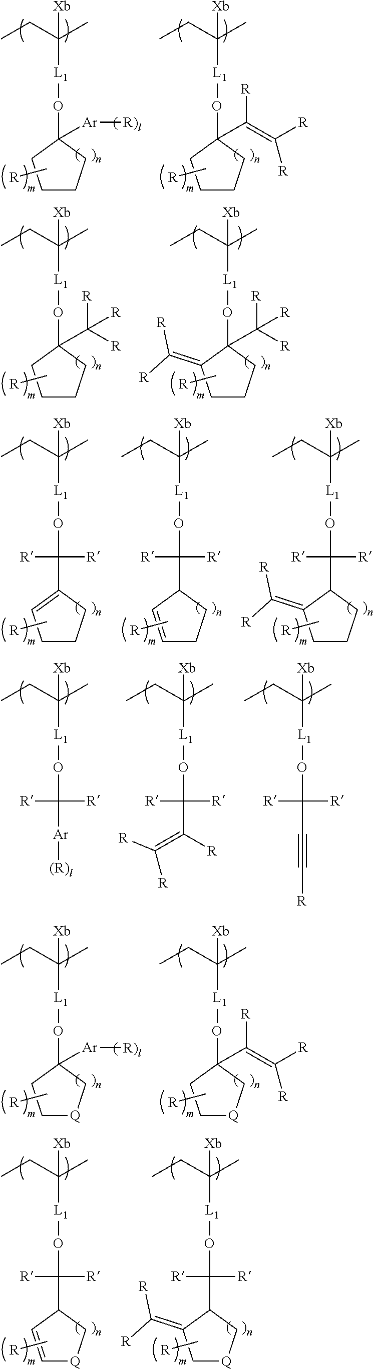

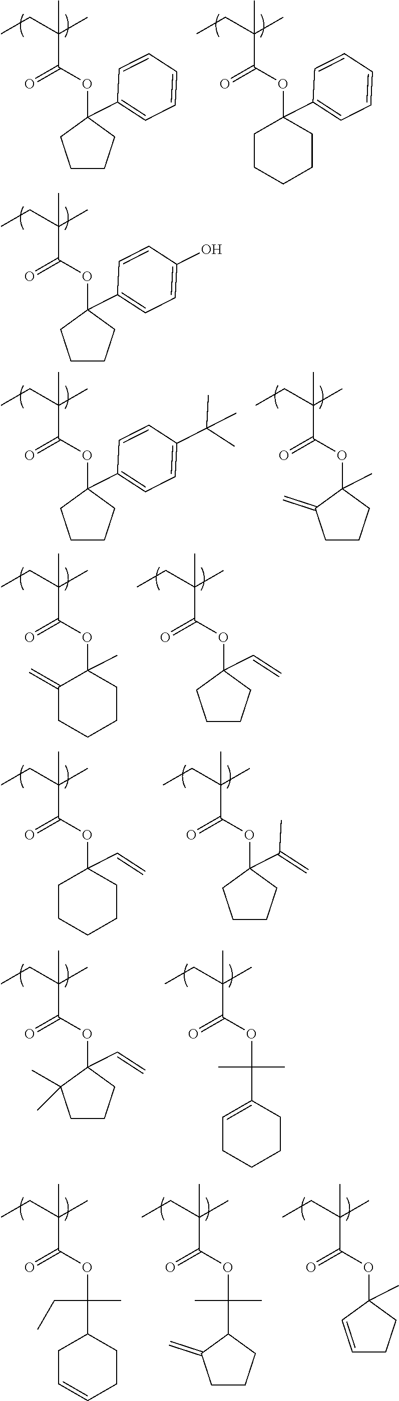

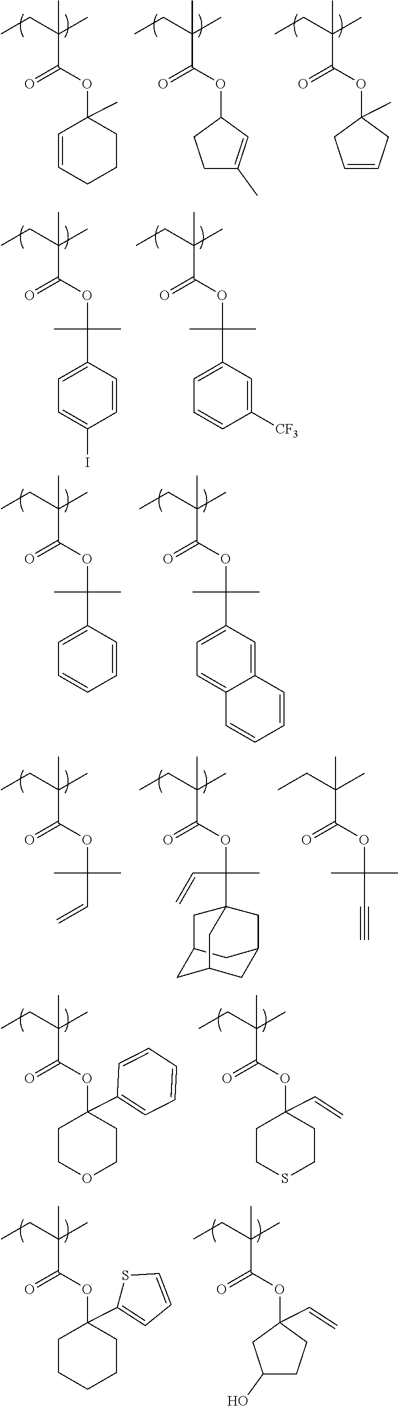

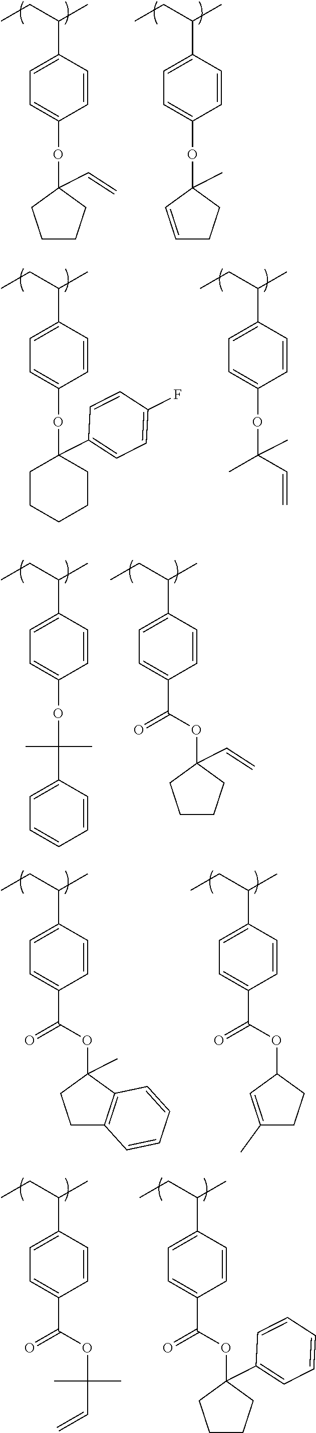

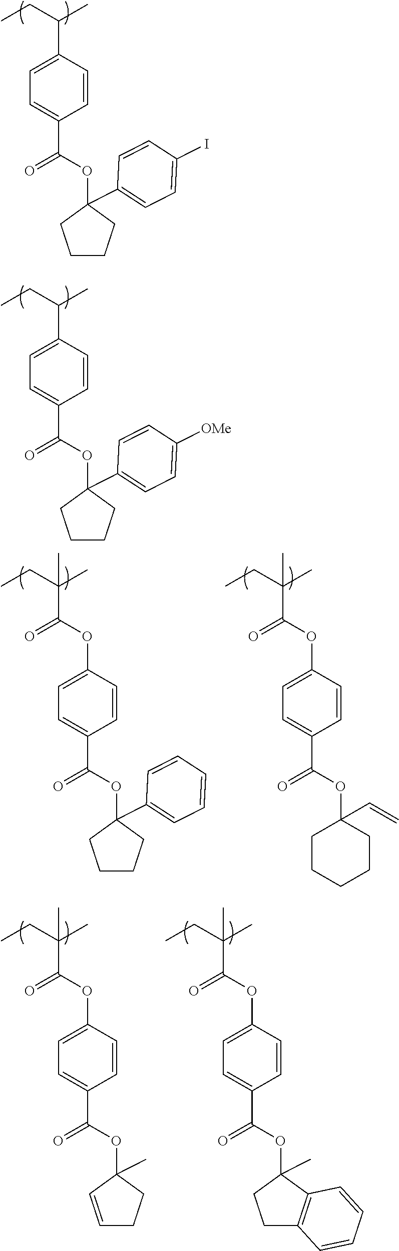

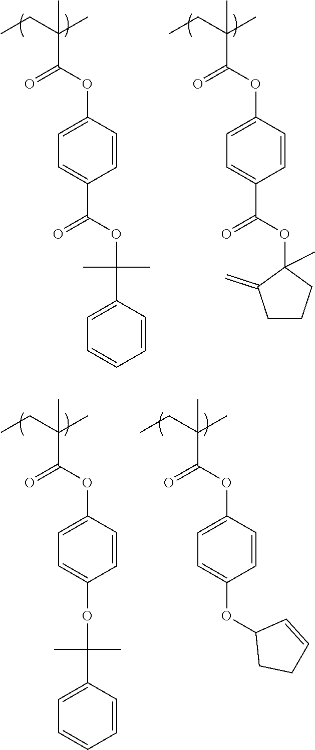

In a case where the specific acid-decomposable resin includes another repeating unit having an acid-decomposable group, the content is preferably 5% by mass or more, more preferably 10% by mass or more, and still more preferably 15% by mass or more with respect to all the repeating units in the specific acid-decomposable resin. In addition, an upper limit value thereof is preferably 40% by mass or less, and more preferably 30% by mass or less.

In addition, the specific acid-decomposable resin may include at least one repeating unit selected from the group consisting of the following group A and/or at least one repeating unit selected from the group consisting of the following group B.

Group A: A group consisting of the following repeating units (20) to (29).

(20) A repeating unit having an acid group, which will be described later

(21) A repeating unit having a fluorine atom or an iodine atom, which will be described later

(22) A repeating unit having a lactone group, a sultone group, or a carbonate group, which will be described later

(23) A repeating unit having a photoacid generating group, which will be described later

(24) A repeating Unit represented by Formula (V-1) or Formula (V-2), which will be described later

(25) A repeating unit represented by Formula (A), which will be described later

(26) A repeating unit represented by Formula (B), which will be described later

(27) A repeating unit represented by Formula (C), which will be described later

(28) A repeating unit represented by Formula (D), which will be described later

(29) A repeating unit represented by Formula (E), which will be described later

Group B: A group consisting of the following repeating units (30) to (32).

(30) A repeating unit having at least one group selected from a lactone group, a sultone group, a carbonate group, a hydroxyl group, a cyano group, or an alkali-soluble group, which will be described later

(31) A repeating unit having an alicyclic hydrocarbon structure and not exhibiting acid decomposability described later

(32) A repeating unit represented by Formula (III) having neither a hydroxyl group nor a cyano group, which will be described later

In a case where the resist composition is used as an actinic ray-sensitive or radiation-sensitive resin composition for EUV exposure or EB exposure, it is preferable that the specific acid-decomposable resin has at least one repeating unit selected from the group consisting of the group A.

In addition, in a case where the resist composition is used as the actinic ray-sensitive or radiation-sensitive resin composition for EUV exposure or EB exposure, it is preferable that the specific acid-decomposable resin includes at least one of a fluorine atom or an iodine atom. In a case where the specific acid-decomposable resin includes both a fluorine atom and an iodine atom, the specific acid-decomposable resin may have one repeating unit including both a fluorine atom and an iodine atom, and the specific acid-decomposable resin may include two kinds of repeating units, that is, a repeating unit having a fluorine atom and a repeating unit having an iodine atom.

In addition, in a case where the resist composition is used as an actinic ray-sensitive or radiation-sensitive resin composition for EUV exposure or EB exposure, it is also preferable that the specific acid-decomposable resin has a repeating unit having an aromatic group.

In a case where the resist composition is used as an actinic ray-sensitive or radiation-sensitive resin composition for ArF, it is preferable that the specific acid-decomposable resin has at least one repeating unit selected from the group consisting of the group B.

<Repeating Unit Having Acid Group>

The specific acid-decomposable resin preferably has a repeating unit having an acid group.

As the acid group, an acid group having a pKa of 13 or less is preferable. The acid dissociation constant of the acid group is preferably 13 or less, more preferably 3 to 13, and still more preferably 5 to 10, as described above.

In a case where the specific acid-decomposable resin has an acid group having a pKa of 13 or less, the content of the acid group in the specific acid-decomposable resin is not particularly limited, but is 0.2 to 6.0 mmol/g in many cases. Among those, the content of the acid group is preferably 0.8 to 6.0 mmol/g, more preferably 1.2 to 5.0 mmol/g, and still more preferably 1.6 to 4.0 mmol/g. In a case where the content of the acid group is within the range, the progress of development is improved, and thus, the shape of a pattern thus formed is excellent and the resolution is also excellent.

As the acid group, for example, a carboxyl group, a hydroxyl group, a phenolic hydroxyl group, a fluorinated alcohol group (preferably a hexafluoroisopropanol group), a sulfonic acid group, or a sulfonamide group is preferable.

In addition, the hexafluoroisopropanol group, in which one or more (preferably one or two) fluorine atoms are substituted with a group other than a fluorine atom, is also preferable as the acid group. Examples of such a group include a group including —C(CF₃)(OH)—CF₂—. Furthermore, the group including —C(CF₃)(OH)—CF₂— may be a ring group including —C(CF₃)(OH)—CF₂—.

The repeating unit having an acid group is preferably another repeating unit which is different from the above-mentioned repeating unit X1, the above-mentioned repeating unit X2, or a repeating unit having a lactone group, a sultone group, or a carbonate group which will be described later.

A repeating unit having an acid group may have a fluorine atom or an iodine atom.

As the repeating unit having an acid group, a repeating unit represented by Formula (B) is preferable.

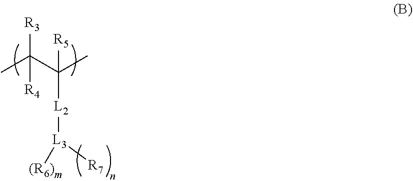

R₃ represents a hydrogen atom or a monovalent organic group which may have a fluorine atom or an iodine atom.

The monovalent organic group which may have a fluorine atom or an iodine atom is preferably a group represented by -L₄-R₈. L₄ represents a single bond or an ester group. R₈ is an alkyl group which may have a fluorine atom or an iodine atom, a cycloalkyl group which may have a fluorine atom or an iodine atom, an aryl group which may have a fluorine atom or an iodine atom, or a group formed by combination thereof.

R₄ and R₅ each independently represent a hydrogen atom, a fluorine atom, an iodine atom, or an alkyl group which may have a fluorine atom or an iodine atom.

L₂ represents a single bond, an ester group, or a divalent group formed by combination of —CO—, —O—, and an alkylene group (which preferably has 1 to 6 carbon atoms, and may be linear or branched; —CH₂— may be substituted with a halogen atom).

L₃ represents an (n+m+1)-valent aromatic hydrocarbon ring group or an (n+m+1)-valent alicyclic hydrocarbon ring group. Examples of the aromatic hydrocarbon ring group include a benzene ring group and a naphthalene ring group. The alicyclic hydrocarbon ring group may be a monocycle or a polycycle, and examples thereof include a cycloalkyl ring group, a norbornene ring group, and an adamantane ring group.

R₆ represents a hydroxyl group, a carboxyl group, or a fluorinated alcohol group.

Furthermore, in a case where R₆ is a hydroxyl group, L₃ preferably represents an (n+m+1)-valent alicyclic hydrocarbon ring group. In addition, in a case where R₆ represents a carboxyl group, it is preferable that L₃ represents a (n+m+1)-valent aromatic hydrocarbon ring group.

The fluorinated alcohol group is preferably a monovalent group represented by Formula (3L).

*-L_{6X}-R_{6X} (3L)

L_{6X} represents a single bond or a divalent linking group. The divalent linking group is not particularly limited, but examples thereof include-CO—, —O—, —SO—, —SO₂—, —NR^{A}—, an alkylene group (which preferably has 1 to 6 carbon atoms, and may be linear or branched) which may have a substituent, and a divalent linking group formed by combination of a plurality of these groups. Examples of R^{A} include a hydrogen atom or an alkyl group having 1 to 6 carbon atoms. In addition, the alkylene group may have a substituent. Examples of the substituent include a halogen atom (preferably a fluorine atom) and a hydroxyl group. R_{6X} represents a hexafluoroisopropanol group.

R₇ represents a halogen atom. Examples of the halogen atom include a fluorine atom, a chlorine atom, a bromine atom, or an iodine atom.

m represents an integer of 1 or more. m is preferably an integer of 1 to 3, and more preferably an integer of 1 or 2.

n represents 0 or an integer of 1 or more. n is preferably an integer of 1 to 4.

Furthermore, (n+m+1) is preferably an integer of 1 to 5.

Examples of the repeating unit having an acid group include the following repeating units.

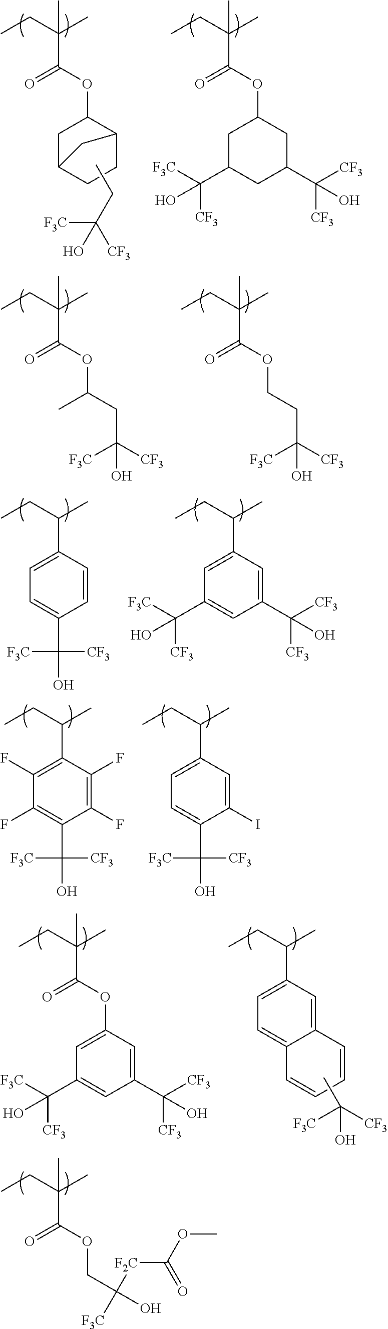

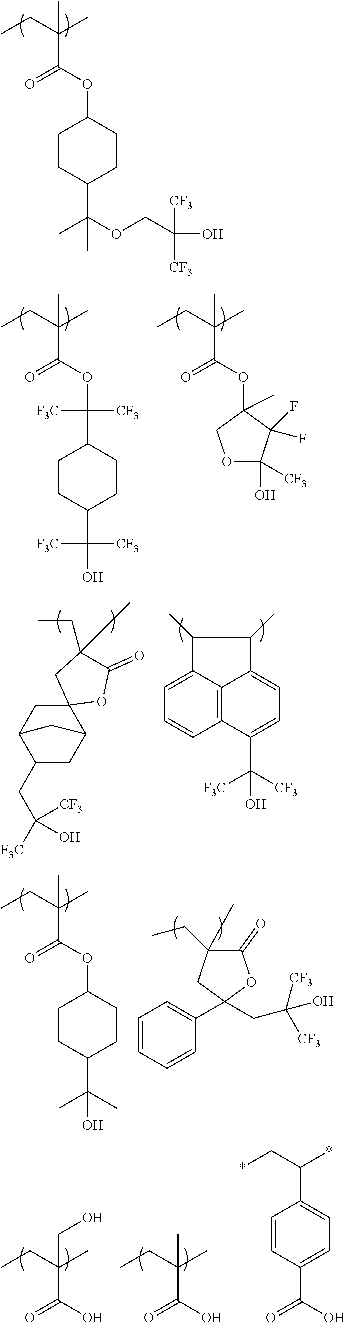

In a case where the specific acid-decomposable resin includes a repeating unit having an acid group, the content is preferably 5% by mass or more, and more preferably 10% by mass or more with respect to all the repeating units in the specific acid-decomposable resin. In addition, the upper limit value is preferably 50% by mass or less, more preferably 40% by mass or less, and still more preferably 30% by mass or less.

<Repeating Unit Having Fluorine Atom or Iodine Atom>

The specific acid-decomposable resin may have a repeating unit having a fluorine atom or an iodine atom, in addition to <Repeating Unit X1>, <Repeating Unit X2>, <Another Repeating Unit Having Acid-Decomposable Group Other than Repeating Unit X1>, and <Repeating Unit Having Acid Group> mentioned above. In addition, <Repeating Unit Having Fluorine Atom or Iodine Atom> mentioned herein is preferably different from other kinds of repeating units belonging to the group A, such as <Repeating Unit Having Lactone Group, Sultone Group, or Carbonate Group> which will be described later.

As the repeating unit having a fluorine atom or an iodine atom, a repeating unit represented by Formula (C) is preferable.

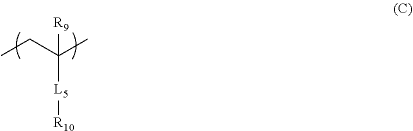

L₅ represents a single bond or an ester group.

R₉ represents a hydrogen atom, or an alkyl group which may have a fluorine atom or an iodine atom.

R₁₀ represents a hydrogen atom, an alkyl group which may have a fluorine atom or an iodine atom, a cycloalkyl group which may have a fluorine atom or an iodine atom, an aryl group which may have a fluorine atom or an iodine atom, or a group formed by combination thereof.

The repeating unit having a fluorine atom or an iodine atom will be exemplified below.

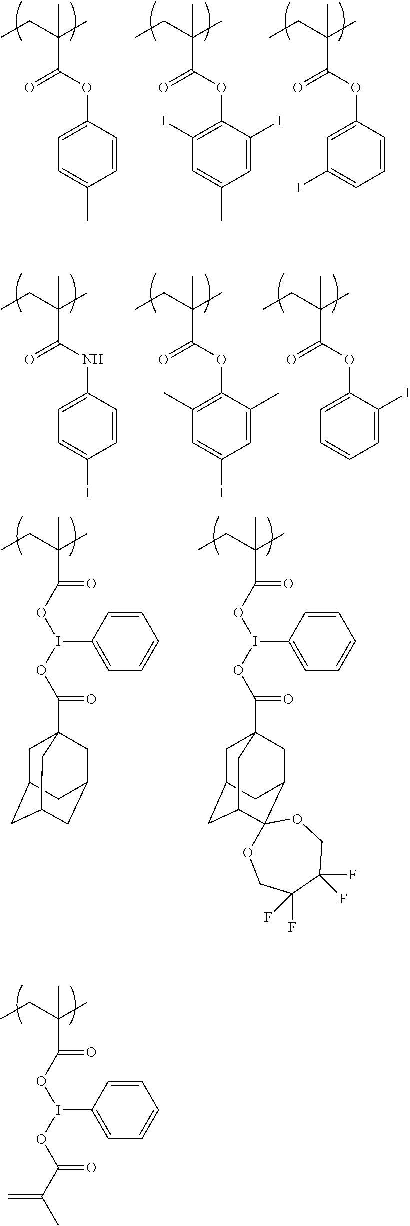

In a case where the specific acid-decomposable resin includes a repeating unit having a fluorine atom or an iodine atom, the content is preferably 1% by mass or more, more preferably 5% by mass or more, and still more preferably 10% by mass or more with respect to all the repeating units in the specific acid-decomposable resin. In addition, the upper limit value is preferably 50% by mass or less, more preferably 45% by mass or less, and still more preferably 40% by mass or less.

Furthermore, since <Repeating Unit X1>, <Repeating Unit X2>, <Another Repeating Unit Having Acid-Decomposable Group Other than Repeating Unit X1>, and <Repeating Unit Having Acid Group> as described above are not included in the repeating unit having a fluorine atom or an iodine atom as mentioned above, the content of the repeating unit having a fluorine atom or an iodine atom is also intended to be a content of the repeating unit having a fluorine atom or an iodine atom excluding <Repeating Unit X1>, <Repeating Unit X2>, <Another Repeating Unit Having Acid-Decomposable Group Other than Repeating Unit X1>, and <Repeating Unit Having Acid Group>.

<Repeating Unit Having Lactone Group, Sultone Group, or Carbonate Group>

The specific acid-decomposable resin may have a repeating unit having at least one selected from the group consisting of a lactone group, a sultone group, and a carbonate group (hereinafter also collectively referred to as a “repeating unit having a lactone group, a sultone group, or a carbonate group”).

It is also preferable that the repeating unit having a lactone group, a sultone group, or a carbonate group does not have a hydroxyl group and an acid group such as a hexafluoropropanol group.

The lactone group or the sultone group may have a lactone structure or a sultone structure. The lactone structure or the sultone structure is preferably a 5- to 7-membered ring lactone structure or a 5- to 7-membered ring sultone structure. Among those, the structure is more preferably a 5- to 7-membered ring lactone structure with which another ring structure is fused so as to form a bicyclo structure or a spiro structure, or a 5- to 7-membered ring sultone structure with which another ring structure is fused so as to form a bicyclo structure or a spiro structure.

The specific acid-decomposable resin preferably has a repeating unit having a lactone group or a sultone group, formed by extracting one or more hydrogen atoms from a ring member atom of a lactone structure represented by any one of Formula (LC1-1), . . . , or (LC1-21) or a sultone structure represented by any one of Formula (SL1-1), (SL1-2), or (SL1-3).

In addition, the lactone group or the sultone group may be bonded directly to the main chain. For example, a ring member atom of the lactone group or the sultone group may constitute the main chain of the specific acid-decomposable resin.

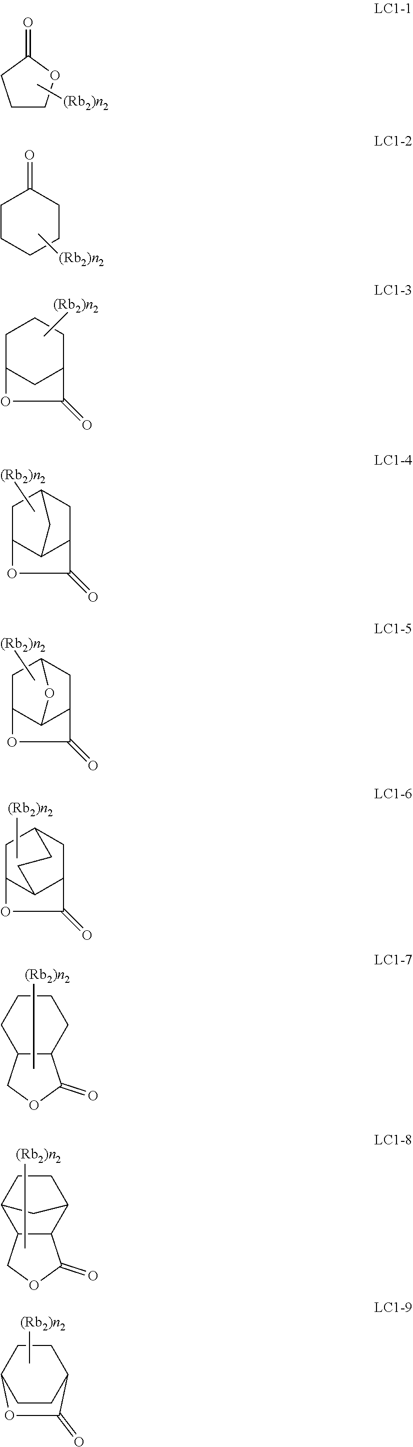

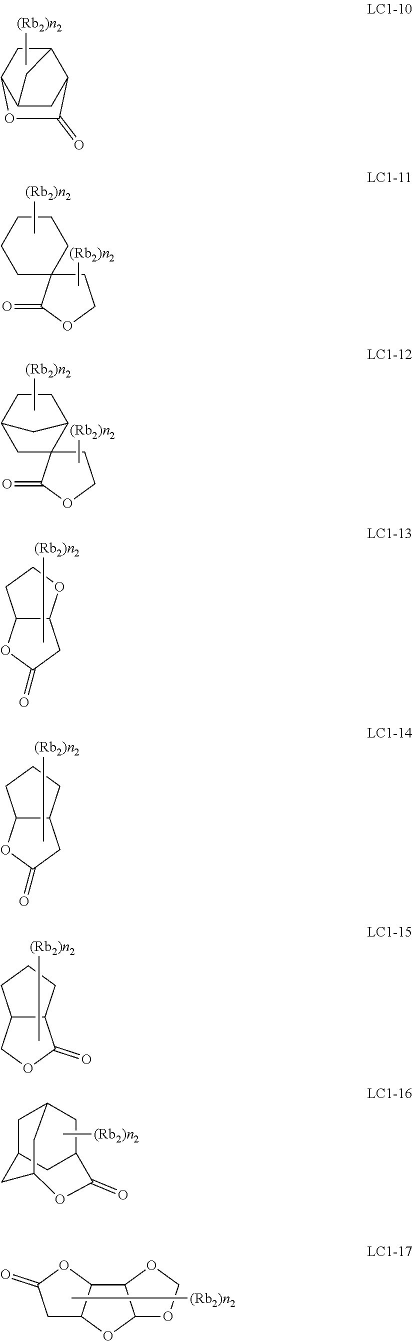

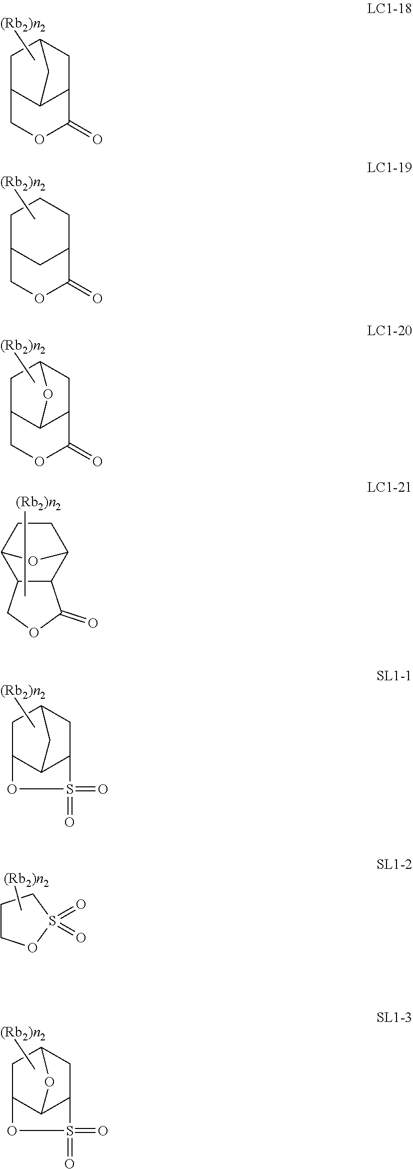

The moiety of the lactone structure or the sultone structure may have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a cyano group, and an acid-decomposable group. n2 represents an integer of 0 to 4. In a case where n2 is 2 or more, Rb₂'s which are present in plurality may be different from each other, and Rb₂'s which are present in plurality may be bonded to each other to form a ring.

Examples of the repeating unit having a group having the lactone structure represented by any one of Formula (LC1-1), . . . , or (LC1-21) or the sultone structure represented by any one of Formula (SL1-1), (SL1-2), or (SL1-3) include a repeating unit represented by Formula (AI).

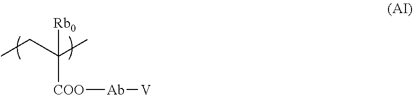

In Formula (AI), Rb₀ represents a hydrogen atom, a halogen atom, or an alkyl group having 1 to 4 carbon atoms.

Preferred examples of the substituent which may be contained in the alkyl group of Rb₀ include a hydroxyl group and a halogen atom.

Examples of the halogen atom of Rb₀ include a fluorine atom, a chlorine atom, a bromine atom, and an iodine atom. Rb₀ is preferably the hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by combination of these groups. Among those, the single bond or a linking group represented by -Ab₁-CO₂— is preferable. Ab₁ is a linear or branched alkylene group, or a monocyclic or polycyclic cycloalkylene group, and is preferably a methylene group, an ethylene group, a cyclohexylene group, an adamantylene group, or a norbornylene group.

V represents a group formed by extracting one hydrogen atom from a ring member atom of the lactone structure represented by any one of Formula (LC1-1), . . . , or (LC1-21) or a group formed by extracting one hydrogen atom from a ring member atom of the sultone structure represented by any one of Formula (SL1-1), (SL1-2), or (SL1-3).

In a case where an optical isomer is present in the repeating unit having a lactone group or a sultone group, any of the optical isomers may be used. In addition, one kind of optical isomers may be used alone or a plurality of kinds of optical isomers may be mixed and used. In a case where one kind of optical isomers is mainly used, an optical purity (ee) thereof is preferably 90 or more, and more preferably 95 or more.

As the carbonate group, a cyclic carbonic acid ester group is preferable.

As the repeating unit having a cyclic carbonic acid ester group, a repeating unit represented by Formula (A-1) is preferable.

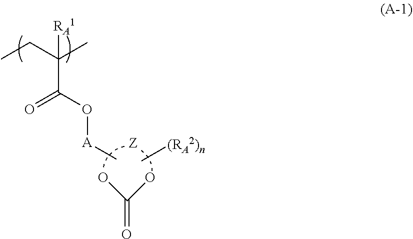

In Formula (A-1), R_{A}¹ represents a hydrogen atom, a halogen atom, or a monovalent organic group (preferably a methyl group).

n represents an integer of 0 or more.

R_{A}² represents a substituent. In a case where n is 2 or more, R_{A}² which are present in plurality may be the same as or different from each other.

A represents a single bond or a divalent linking group. As the divalent linking group, an alkylene group, a divalent linking group having a monocyclic or polycyclic alicyclic hydrocarbon structure, an ether group, an ester group, a carbonyl group, a carboxyl group, or a divalent group formed by combination of these groups is preferable.

Z represents an atomic group that forms a monocycle or polycycle with a group represented by —O—CO—O— in the formula.

The repeating unit having a lactone group, a sultone group, or a carbonate group will be exemplified below.

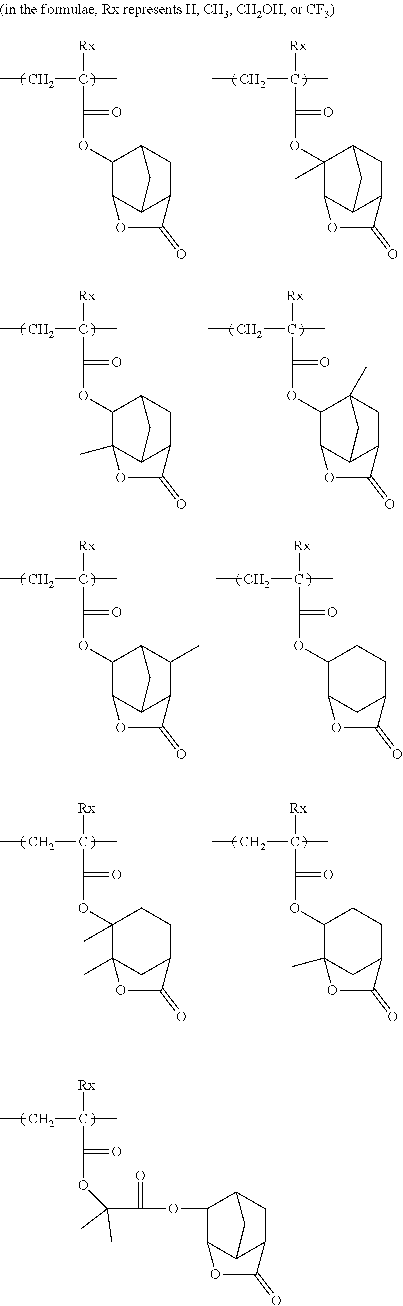

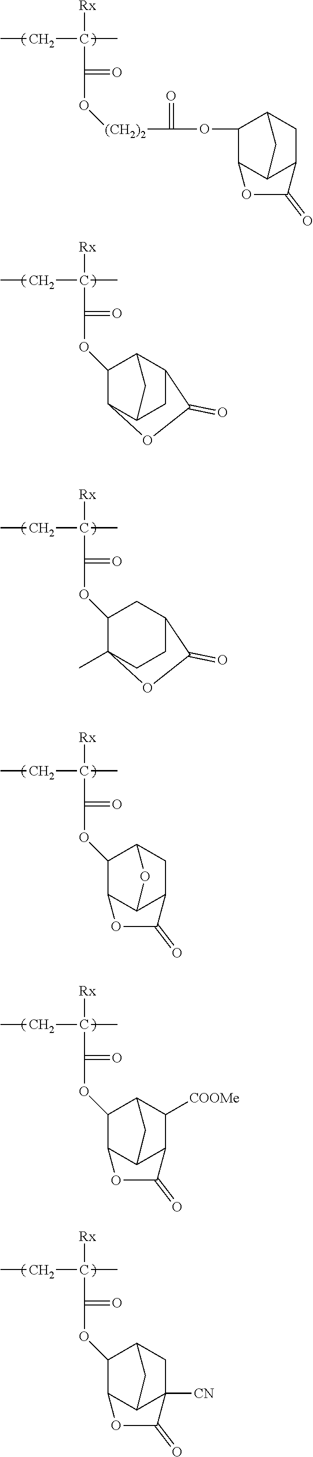

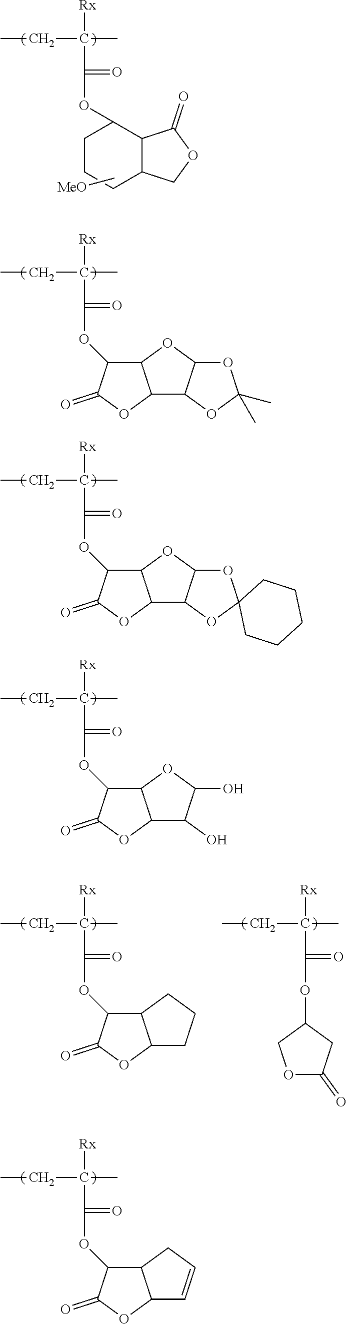

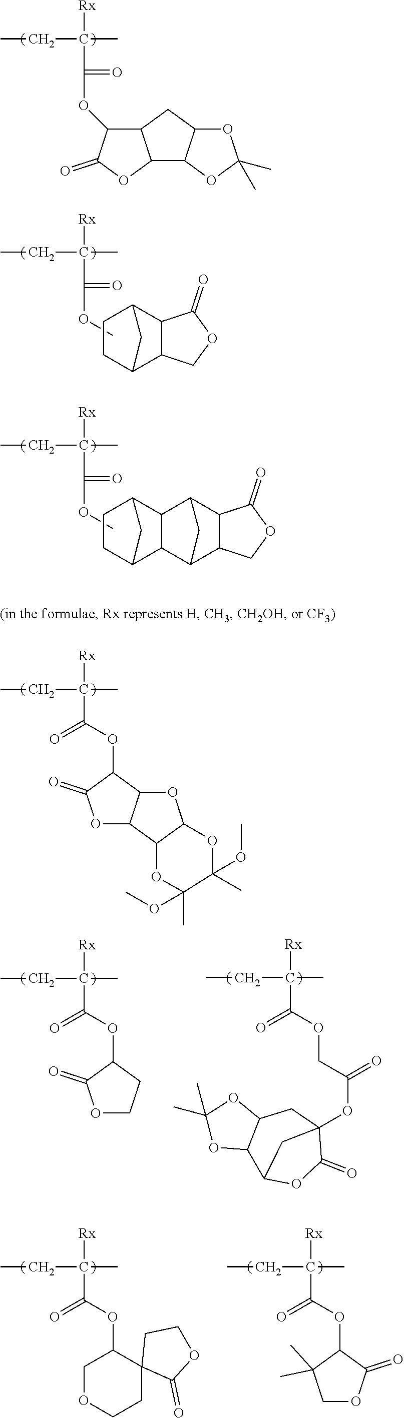

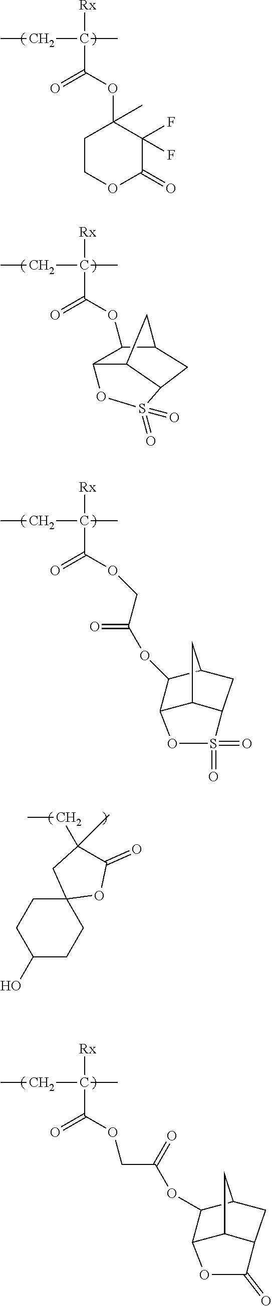

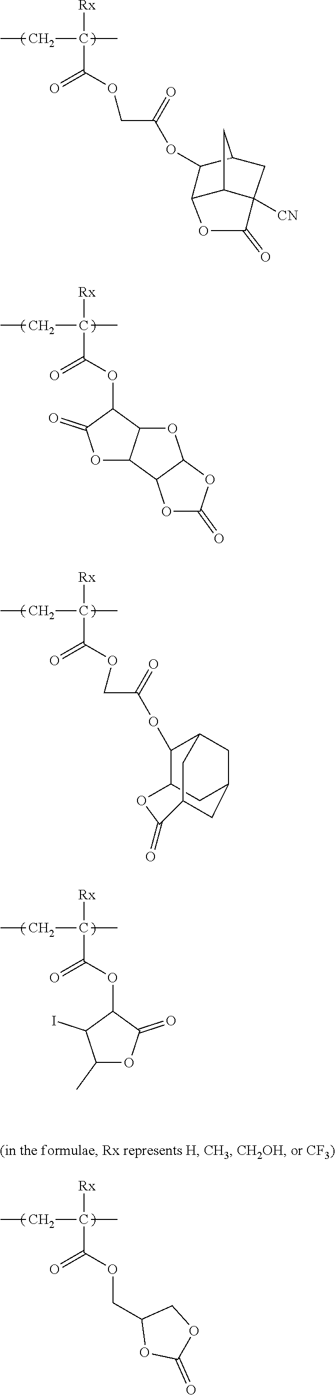

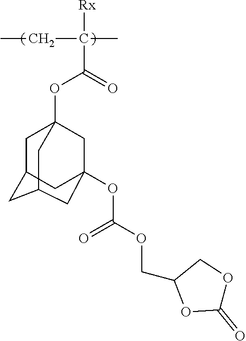

In a case where the specific acid-decomposable resin includes a repeating unit having a lactone group, a sultone group, or a carbonate group, the content is preferably 5% by mass or more, and more preferably 10% by mass or more with respect to all the repeating units in the specific acid-decomposable resin. In addition, the upper limit value is preferably 50% by mass or less, more preferably 40% by mass or less, and still more preferably 30% by mass or less.

<Repeating Unit Having Photoacid Generating Group>

The specific acid-decomposable resin may have, as a repeating unit other than those above, a repeating unit having a group that generates an acid upon irradiation with actinic rays or radiation (hereinafter also referred to as a “photoacid generating group”).

In this case, it can be considered that the repeating unit having the photoacid generating group corresponds to the above-mentioned photoacid generator.

Examples of such the repeating unit include a repeating unit represented by Formula (4).

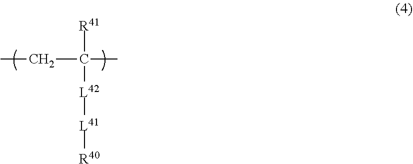

R⁴¹ represents a hydrogen atom or a methyl group. L⁴¹ represents a single bond or a divalent linking group. L⁴² represents a divalent linking group. R⁴⁰ represents a structural site that decomposes upon irradiation with actinic rays or radiation to generate an acid in a side chain.

The repeating unit having a photoacid generating group is exemplified below.

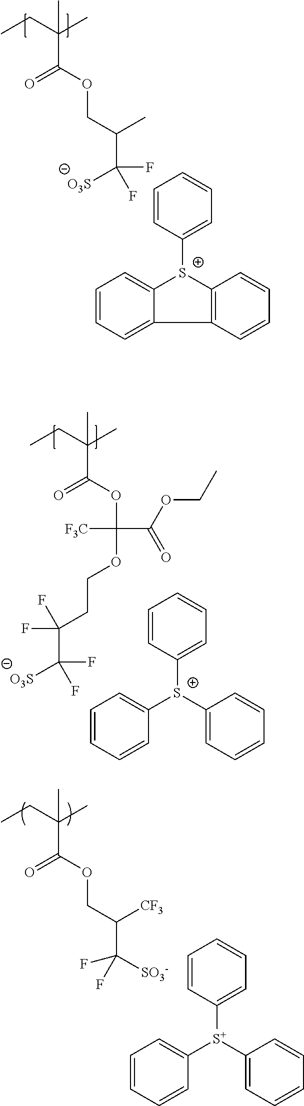

In addition, examples of the repeating unit represented by Formula (4) include the repeating units described in paragraphs [0094] to [0105] of JP2014-041327A and the repeating units described in paragraph [0094] of WO2018/193954A.

In a case where the specific acid-decomposable resin includes a repeating unit having a photoacid generating group, the content is preferably 1% by mass or more, and more preferably 2% by mass or more with respect to all the repeating units in the specific acid-decomposable resin. In addition, the upper limit value is preferably 20% by mass or less, more preferably 10% by mass or less, and still more preferably 5% by mass or less.

<Repeating Unit Represented by Formula (V-1) or Formula (V-2)>

The specific acid-decomposable resin may have a repeating unit represented by Formula (V-1) or Formula (V-2).

The repeating unit represented by Formulae (V-1) and (V-2) is preferably a repeating unit different from the above-mentioned repeating units.

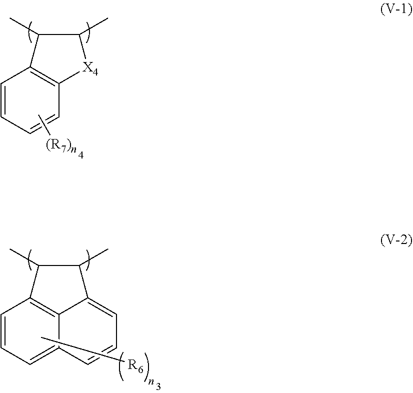

In the formulae,

R₆ and R₇ each independently represent a hydrogen atom, a hydroxyl group, an alkyl group, an alkoxy group, an acyloxy group, a cyano group, a nitro group, an amino group, a halogen atom, an ester group (—OCOR or —COOR: R is an alkyl group or fluorinated alkyl group having 1 to 6 carbon atoms), or a carboxyl group. As the alkyl group, a linear, branched, or cyclic alkyl group having 1 to 10 carbon atoms is preferable.

n₃ represents an integer of 0 to 6.

n₄ represents an integer of 0 to 4.

X₄ is a methylene group, an oxygen atom, or a sulfur atom.

Examples of the repeating unit represented by Formula (V-1) or (V-2) include the repeating unit described in paragraph [0100] of WO2018/193954A.

<Repeating Unit for Reducing Motility of Main Chain>

The specific acid-decomposable resin preferably has a high glass transition temperature (Tg) from the viewpoint that excessive diffusion of an acid generated or pattern collapse during development can be suppressed. Tg is preferably higher than 90° C., more preferably higher than 100° C., still more preferably higher than 110° C., and particularly preferably higher than 125° C. Furthermore, since an excessive increase in Tg causes a decrease in the dissolution rate in a developer, Tg is preferably 400° C. or lower, and more preferably 350° C. or lower.

Furthermore, in the present specification, the glass transition temperature (Tg) of a polymer such as the specific acid-decomposable resin is calculated by the following method. First, the Tg of a homopolymer consisting only of each repeating unit included in the polymer is calculated by a Bicerano method. Hereinafter, the calculated Tg is referred to as the “Tg of the repeating unit”. Next, the mass proportion (%) of each repeating unit to all the repeating units in the polymer is calculated. Then, the Tg at each mass proportion is calculated using a Fox's equation (described in Materials Letters 62 (2008) 3152, and the like), and these are summed to obtain the Tg (° C.) of the polymer.

The Bicerano method is described in Prediction of polymer properties, Marcel Dekker Inc., New York (1993), and the like. In addition, the calculation of a Tg by the Bicerano method can be carried out using MDL Polymer (MDL Information Systems, Inc.), which is software for estimating physical properties of a polymer.

In order to raise the Tg of the specific acid-decomposable resin (preferably to raise the Tg to higher than 90° C.), it is preferable to reduce the motility of the main chain of the specific acid-decomposable resin. Examples of a method for reducing the motility of the main chain of the specific acid-decomposable resin include the following (a) to (e) methods.

(a) Introduction of a bulky substituent into the main chain

(b) Introduction of a plurality of substituents into the main chain

(c) Introduction of a substituent that induces an interaction between the specific acid-decomposable resins near the main chain

(d) Formation of the main chain in a cyclic structure

(e) Linking of a cyclic structure to the main chain

Furthermore, the specific acid-decomposable resin preferably has a repeating unit having a Tg of a homopolymer exhibiting 130° C. or higher.

In addition, the type of the repeating unit having a Tg of the homopolymer exhibiting 130° C. or higher is not particularly limited, and may be any of repeating units having a Tg of a homopolymer of 130° C. or higher calculated by the Bicerano method. Moreover, it corresponds to a repeating unit having a Tg of a homopolymer exhibiting 130° C. or higher, depending on the type of a functional group in the repeating units represented by Formula (A) to Formula (E) which will be described later.

(Repeating Unit Represented by Formula (A))

As an example of a specific unit for accomplishing (a) above, a method of introducing a repeating unit represented by Formula (A) into the specific acid-decomposable resin may be mentioned.

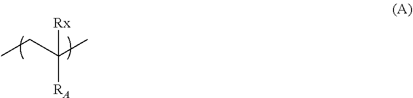

In Formula (A), R_{A} represents a group having a polycyclic structure. Rₓ represents a hydrogen atom, a methyl group, or an ethyl group. The group having a polycyclic structure is a group having a plurality of ring structures, and the plurality of ring structures may or may not be fused.

Specific examples of the repeating unit represented by Formula (A) include those described in paragraphs [0107] to [0119] of WO2018/193954A.

(Repeating Unit Represented by Formula (B))

As an example of a specific unit for accomplishing (b) above, a method of introducing a repeating unit represented by Formula (B) into the specific acid-decomposable resin may be mentioned.

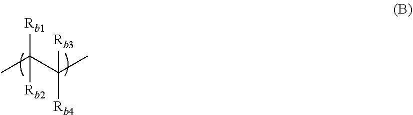

In Formula (B), R_{b1} to R_{b4} each independently represent a hydrogen atom or an organic group, and at least two or more of R_{b1}, . . . , or R_{b4} represent an organic group.

Furthermore, in a case where at least one of the organic groups is a group in which a ring structure is directly linked to the main chain in the repeating unit, the types of the other organic groups are not particularly limited.

In addition, in a case where none of the organic groups is a group in which a ring structure is directly linked to the main chain in the repeating unit, at least two or more of the organic groups are substituents having three or more constituent atoms excluding hydrogen atoms.

Specific examples of the repeating unit represented by Formula (B) include those described in paragraphs [0113] to [0115] of WO2018/193954A.

(Repeating Unit Represented by Formula (C))

As an example of a specific unit for accomplishing (c) above, a method of introducing a repeating unit represented by Formula (C) into the specific acid-decomposable resin may be mentioned.

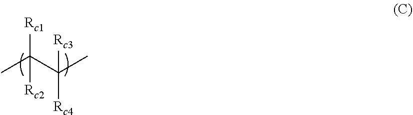

In Formula (C), R_{c1} to R_{c4} each independently represent a hydrogen atom or an organic group, and at least one of R_{c1}, . . . , or R_{c4} is a group having a hydrogen-bonding hydrogen atom with a number of atoms of 3 or less from the main chain carbon. Above all, it is preferable that the group has hydrogen-bonding hydrogen atoms with a number of atoms of 2 or less (on a side closer to the vicinity of the main chain) to induce an interaction between the main chains of the specific acid-decomposable resins.

Specific examples of the repeating unit represented by Formula (C) include those described in paragraphs [0119] to [0121] of WO2018/193954A.

(Repeating Unit Represented by Formula (D))

As an example of a specific unit for accomplishing (d) above, a method of introducing a repeating unit represented by Formula (D) into the specific acid-decomposable resin may be mentioned.

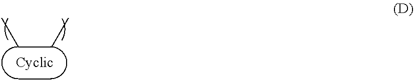

In Formula (D), “Cyclic” is a group that forms a main chain with a cyclic structure. The number of the ring-constituting atoms is not particularly limited.

Specific examples of the repeating unit represented by Formula (D) include those described in paragraphs [0126] and [0127] of WO2018/193954A.

(Repeating Unit Represented by Formula (E))

As an example of a specific unit for accomplishing (e) above, a method of introducing a repeating unit represented by Formula (E) into the specific acid-decomposable resin may be mentioned.

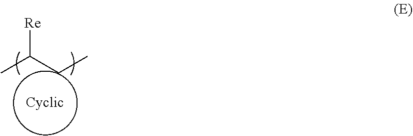

In Formula (E), Re's each independently represent a hydrogen atom or an organic group. Examples of the organic group include an alkyl group, a cycloalkyl group, an aryl group, an aralkyl group, and an alkenyl group, which may have a substituent.

“cylic” is a cyclic group including a carbon atom of the main chain. The number of atoms included in the cyclic group is not particularly limited.

Specific examples of the repeating unit represented by Formula (E) include those described in paragraphs [0131] to [0133] of WO2018/193954A.

<Repeating Unit Having at Least One Group Selected from Lactone Group, Sultone Group, Carbonate Group, Hydroxyl Group, Cyano Group, or Alkali-Soluble Group>

The specific acid-decomposable resin may have a repeating unit having at least one group selected from a lactone group, a sultone group, a carbonate group, a hydroxyl group, a cyano group, or an alkali-soluble group.

Examples of the repeating unit having a lactone group, a sultone group, or a carbonate group included in the specific acid-decomposable resin include the repeating units described in <Repeating Unit Having Lactone Group, Sultone Group, or Carbonate Group> mentioned above. A preferred content thereof is also the same as described in <Repeating Unit Having Lactone Group, Sultone Group, or Carbonate Group> mentioned above.

The specific acid-decomposable resin may have a repeating unit having a hydroxyl group or a cyano group. As a result of this, the adhesiveness to a substrate and the affinity for a developer are improved.

The repeating unit having a hydroxyl group or a cyano group is preferably a repeating unit having an alicyclic hydrocarbon structure substituted with a hydroxyl group or a cyano group.

The repeating unit having a hydroxyl group or a cyano group preferably has no acid-decomposable group. Examples of the repeating unit having a hydroxyl group or a cyano group include those described in paragraphs [0153] to [0158] of WO2020/004306A.

The specific acid-decomposable resin may have a repeating unit having an alkali-soluble group.

Examples of the alkali-soluble group include a carboxyl group, a sulfonamide group, a sulfonylimide group, a bissulfonylimide group, or an aliphatic alcohol group (for example, a hexafluoroisopropanol group) in which the α-position is substituted with an electron withdrawing group, and the carboxyl group is preferable. In a case where the specific acid-decomposable resin includes a repeating unit having an alkali-soluble group, the resolution for use in contact holes increases. Examples of the repeating unit having an alkali-soluble group include those described in paragraphs [0085] and [0086] of JP2014-098921A.

<Repeating Unit Having Alicyclic Hydrocarbon Structure and not Exhibiting Acid Decomposability>

The specific acid-decomposable resin may have a repeating unit having an alicyclic hydrocarbon structure and not exhibiting acid decomposability. This can reduce the elution of low-molecular-weight components from the resist film into an immersion liquid during liquid immersion exposure. Examples of such the repeating unit include repeating units derived from 1-adamantyl (meth)acrylate, diamantyl (meth)acrylate, tricyclodecanyl (meth)acrylate, and cyclohexyl (meth)acrylate. The alicyclic hydrocarbon structure may have, for example, a substituent such as a hydroxyl group.

<Repeating Unit Represented by Formula (III) Having Neither Hydroxyl Group Nor Cyano Group>

The specific acid-decomposable resin may have a repeating unit represented by Formula (III), which has neither a hydroxyl group nor a cyano group.

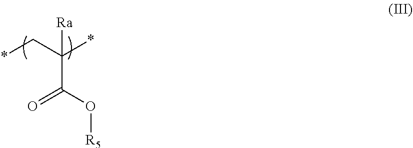

In Formula (III), R₅ represents a hydrocarbon group having at least one cyclic structure and having neither a hydroxyl group nor a cyano group.

Ra represents a hydrogen atom, an alkyl group, or a —CH₂—O—Ra₂ group. In the formula, Ra₂ represents a hydrogen atom, an alkyl group, or an acyl group.

The cyclic structure contained in R₅ includes a monocyclic hydrocarbon group and a polycyclic hydrocarbon group. Examples of the monocyclic hydrocarbon group include a cycloalkyl group having 3 to 12 carbon atoms (more preferably 3 to 7 carbon atoms) or a cycloalkenyl group having 3 to 12 carbon atoms.

Detailed definitions of each group in Formula (III) and specific examples of the repeating unit include those described in paragraphs [0169] to [0173] of WO2020/004306A.

<Other Repeating Units>

Furthermore, the specific acid-decomposable resin may have repeating units other than the above-mentioned repeating units.

For example, the specific acid-decomposable resin may have a repeating unit selected from the group consisting of a repeating unit having an oxathiane ring group, a repeating unit having an oxazolone ring group, a repeating unit having a dioxane ring group, and a repeating unit having a hydantoin ring group.

Such repeating units will be exemplified below.

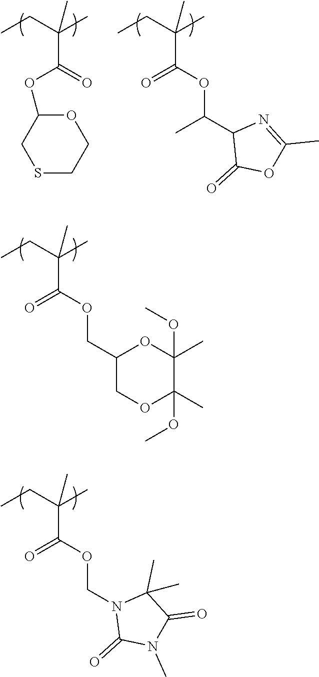

The specific acid-decomposable resin may have a variety of repeating structural units, in addition to the repeating structural units described above, for the purpose of adjusting dry etching resistance, suitability for a standard developer, adhesiveness to a substrate, a resist profile, resolving power, heat resistance, sensitivity, and the like.

As the specific acid-decomposable resin, all the repeating units is also preferably composed of (meth)acrylate-based repeating units (particularly in a case where the composition is used as a resist composition for ArF exposure). In this case, any of a resin in which all of the repeating units are methacrylate-based repeating units, a resin in which all of the repeating units are acrylate-based repeating units, and a resin in which all of the repeating units are methacrylate-based repeating units and acrylate-based repeating units can be used, and it is preferable that the amount of the acrylate-based repeating units is 50% by mass or less with respect to all the repeating units.

The specific acid-decomposable resin can be synthesized in accordance with an ordinary method (for example, radical polymerization).

The weight-average molecular weight of the specific acid-decomposable resin as a value expressed in terms of polystyrene by a GPC method is preferably 1,000 to 200,000, more preferably 3,000 to 20,000, and still more preferably 5,000 to 15,000. By setting the weight-average molecular weight of the specific acid-decomposable resin to 1,000 to 200,000, deterioration of heat resistance and dry etching resistance can be further suppressed. In addition, deterioration of developability and deterioration of film forming property due to high viscosity can also be further suppressed.

The dispersity (molecular weight distribution) of the specific acid-decomposable resin is usually 1 to 5, preferably 1 to 3, more preferably 1.2 or 3.0, and still more preferably 1.2 to 2.0. The smaller the dispersity, the more excellent the resolution and the resist shape, and the smoother the side wall of the resist pattern, the more excellent the roughness.

<<<Another Acid-Decomposable Resin Other than Specific Acid-Decomposable Resin>>>

The resist composition may include another acid-decomposable resin other than the specific acid-decomposable resin. Examples of such another acid-decomposable resin include an acid-decomposable resin that does not include a repeating unit having two or more acid-decomposable groups but includes a repeating unit having only one acid-decomposable group, and an acid-decomposable resin that does not include a repeating unit having a phenolic hydroxyl group.

[Photoacid Generator]

The resist composition may include a compound that generates an acid upon irradiation with actinic rays or radiation (photoacid generator).

The photoacid generator is not particularly limited, but preferably includes one or more (specific photoacid generators) selected from the group consisting of the compounds (I) and (II) from the viewpoint that the effects of the present invention are more excellent.

Furthermore, the resist composition may include a photoacid generator other than the specific photoacid generator (hereinafter also referred to as “another photoacid generator”).

Hereinbelow, the specific photoacid generators (the compounds (I) and (II)) will first be described.

<<<Specific Photoacid Generator>>>

<<Compound (I)>>

The compound (I) is a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation.

Structural site X: a structural site which consists of an anionic site A₁⁻ and a cationic site M₁⁺, and forms a first acidic site represented by HA₁ upon irradiation with actinic rays or radiation

Structural site Y: a structural site which consists of an anionic site A₂⁻ and a cationic site M₂⁺, and forms a second acidic site represented by HA₂ upon irradiation with actinic rays or radiation

It should be noted that the compound (I) satisfies the following condition I.

Condition I: A compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1.

Hereinafter, the condition I will be described more specifically.

In a case where the compound (I) is, for example, a compound that generates an acid having one site of the first acidic site derived from the structural site X and one site of the second acidic site derived from the structural site Y, the compound PI corresponds to a “compound having HA₁ and HA₂”.

More specifically, with regard to the acid dissociation constant a1 and the acid dissociation constant a2 of such a compound PI, in a case where the acid dissociation constant of the compound PI is determined, the pKa with which the compound PI serves as a “compound having A₁⁻ and HA₂” is the acid dissociation constant a1, and the pKa with which the “compound having A₁⁻ and HA₂” serves as a “compound having A₁⁻ and A₂⁻” is the acid dissociation constant a2.

In addition, in a case where the compound (I) is, for example, a compound that generates an acid having two sites of the first acidic site derived from the structural site X and one site of the second acidic site derived from the structural site Y, the compound PI corresponds to a “compound having two HA₁'s and one HA₂”.

In a case where the acid dissociation constant of such a compound PI is determined, an acid dissociation constant in a case where the compound PI serves as a “compound having one A₁⁻, one HA₁, and one HA₂” and an acid dissociation constant in a case where the “compound having one A₁⁻, one HA₁, and one HA₂” serves as a “compound having two A₁⁻'s and one HA₂” correspond to the acid dissociation constant a1. In addition, the acid dissociation constant in a case where the “compound having two A₁⁻ and one HA₂” serves as a “compound having two A₁⁻'s and A₂⁻” corresponds to the acid dissociation constant a2. That is, in a case of such a compound PI, a value of the acid dissociation constant a2 is larger than the largest value of the plurality of acid dissociation constants a1 in a case where the compound has a plurality of acid dissociation constants derived from the acidic site represented by HA₁, formed by substituting the cationic site M₁⁺ in the structural site X with H⁺. Furthermore, the acid dissociation constant in a case where the compound PI serves as a “compound having one A₁⁻, one HA₁ and one HA₂” is taken as aa and the acid dissociation constant in a case where the “compound having one A₁⁻, one HA₁, and one HA₂” serves as a “compound having two A₁⁻'s and one HA₂” is taken as ab, a relationship between aa and ab satisfies aa<ab.

The acid dissociation constant a1 and the acid dissociation constant a2 can be determined by the above-mentioned method for measuring an acid dissociation constant.

The compound PI corresponds to an acid generated upon irradiating the compound (I) with actinic rays or radiation.

In a case where the compound (I) has two or more structural sites X, the structural sites X may be the same as or different from each other. In addition, two or more A₁⁻'s and two or more M₁⁺'s may be the same as or different from each other.

Moreover, in the compound (I), A₁⁻'s and A₂⁻', and M₁⁺'s and M₂⁺'s may be the same as or different from each other, but it is preferable that A₁⁻'s and A₂⁻′, are each different from each other.

From the viewpoint that the LWR performance of a pattern thus formed is more excellent, in the compound PI, the difference between the acid dissociation constant a1 (the maximum value in a case where a plurality of acid dissociation constants a1 are present) and the acid dissociation constant a2 is preferably 0.1 or more, more preferably 0.5 or more, and still more preferably 1.0 or more. Furthermore, the upper limit value of the difference between the acid dissociation constant a1 (the maximum value in a case where a plurality of acid dissociation constants a1 are present) and the acid dissociation constant a2 is not particularly limited, but is, for example, 16 or less.

In addition, from the viewpoint that the LWR performance of a pattern thus formed is more excellent, in the compound PI, the acid dissociation constant a2 is, for example, 20 or less, and preferably 15 or less. Furthermore, a lower limit value of the acid dissociation constant a2 is preferably −4.0 or more.

In addition, from the viewpoint that the LWR performance of a pattern thus formed is more excellent, the acid dissociation constant a1 is preferably 2.0 or less, and more preferably 0 or less in the compound PI. Furthermore, a lower limit value of the acid dissociation constant a1 is preferably −20.0 or more.

The anionic site A₁⁻ and the anionic site A₂⁻ are structural sites including negatively charged atoms or atomic groups, and examples thereof include structural sites selected from the group consisting of Formulae (AA-1) to (AA-3) and Formulae (BB-1) to (BB-6) shown below. As the anionic site A₁⁻, those capable of forming an acidic site having a small acid dissociation constant are preferable, and among those, any one of Formula (AA-1), (AA-2), or (AA-3) is preferable. In addition, as the anionic site A₂⁻, those capable of forming an acidic site having a larger acid dissociation constant than the anionic site A₁⁻ are preferable, and those selected from any of Formulae (BB-1) to (BB-6) are more preferable. Furthermore, in Formulae (AA-1) to (AA-3) and Formulae (BB-1) to (BB-6), * represents a bonding position.

In Formula (AA-2), R^{A} represents a monovalent organic group. Examples of the monovalent organic group represented by R^{A} include a cyano group, a trifluoromethyl group, and a methanesulfonyl group.

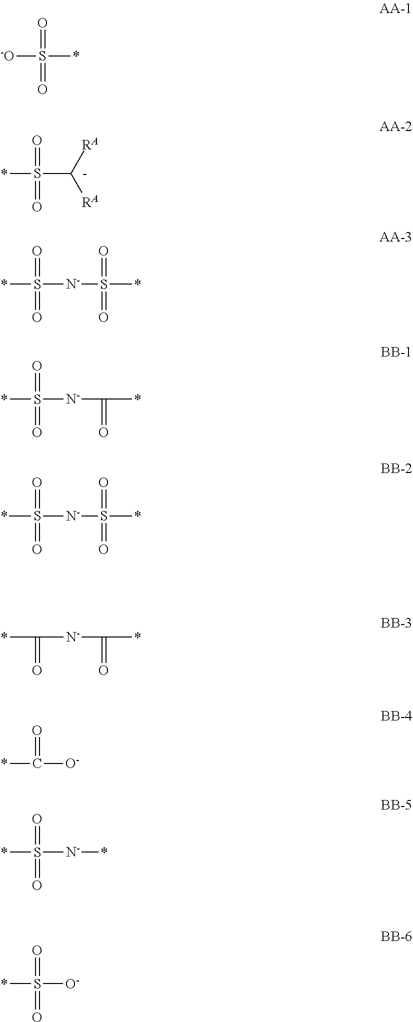

In addition, the cationic site M₁⁺ and the cationic site M₂⁺ are structural sites including positively charged atoms or atomic groups, and examples thereof include a monovalent organic cation. Furthermore, the organic cation is not particularly limited, but examples thereof include the same ones as the organic cations represented by M₁₁⁺ and M₁₂⁺ in Formula (Ia-1) which will be described later.

The specific structure of the compound (I) is not particularly limited, but examples thereof include compounds represented by Formulae (Ia-1) to (Ia-5) which will be described later.

Hereinbelow, first, the compound represented by Formula (Ia-1) will be described. The compound represented by Formula (Ia-1) is as follows.

M₁₁⁺A₁₁⁻-L₁-A₁₂⁻M₁₂⁺ (Ia-1)

The compound (Ia-1) generates an acid represented by HA₁₁-L₁-A₁₂H upon irradiation with actinic rays or radiation.

In Formula (Ia-1), M₁₁⁺ and M₁₂⁺ each independently represent an organic cation.

A₁₁⁻ and A₁₂⁻ each independently represent a monovalent anionic functional group.

L₁ represents a divalent linking group.

M₁₁⁺ and M₁₂⁺ may be the same as or different from each other.

A₁₁⁻ and A₁₂⁻ may be the same as or different from each other, but are preferably different from each other.

It should be noted that in the compound PIa (HA₁₁-L₁-A₁₂H) formed by substituting organic cations represented by M₁₁⁺ and M₁₂⁺ with H⁺ in Formula (Ia-1), the acid dissociation constant a2 derived from the acidic site represented by A₁₂H is larger than an acid dissociation constant a1 derived from an acidic site represented by HA₁₁. Furthermore, suitable values of the acid dissociation constant a1 and the acid dissociation constant a2 are as described above. In addition, the acids generated from the compound PIa and the compound represented by Formula (Ia-1) upon irradiation with actinic rays or radiation are the same.

In addition, at least one of M₁₁⁺, M₁₂⁺, A₁₁⁻, A₂⁻, or L₁ may have an acid-decomposable group as a substituent.

The organic cations represented by M₁₁⁺ and M₁₂⁺ in Formula (Ia-1) are as described later.

The monovalent anionic functional group represented by A₁₁⁻ is intended to be a monovalent group including the above-mentioned anionic site A₁⁻. In addition, the monovalent anionic functional group represented by A₁₂⁻ is intended to be a monovalent group including the above-mentioned anionic site A₂⁻.

The monovalent anionic functional group represented by each of A₁₁⁻ and A₁₂⁻ is preferably a monovalent anionic functional group including an anionic site of any one of Formula (AA-1), (AA-2), or (AA-3), and Formulae (BB-1) to (BB-6) mentioned above, and more preferably a monovalent anionic functional group selected from the group consisting of Formulae (AX-1) to (AX-3), and Formulae (BX-1) to (BX-7). The monovalent anionic functional group represented by A₁₁⁻ is preferably, among those, the monovalent anionic functional group represented by any one of Formula (AX-1), (AX-1), or (AX-3). In addition, the monovalent anionic functional group represented by A₁₂⁻ is preferably, among those, the monovalent anionic functional group represented by any one of Formula (BX-1), . . . , or (BX-7), and more preferably the monovalent anionic functional group represented by any one of Formula (BX-1), . . . , or to (BX-6).

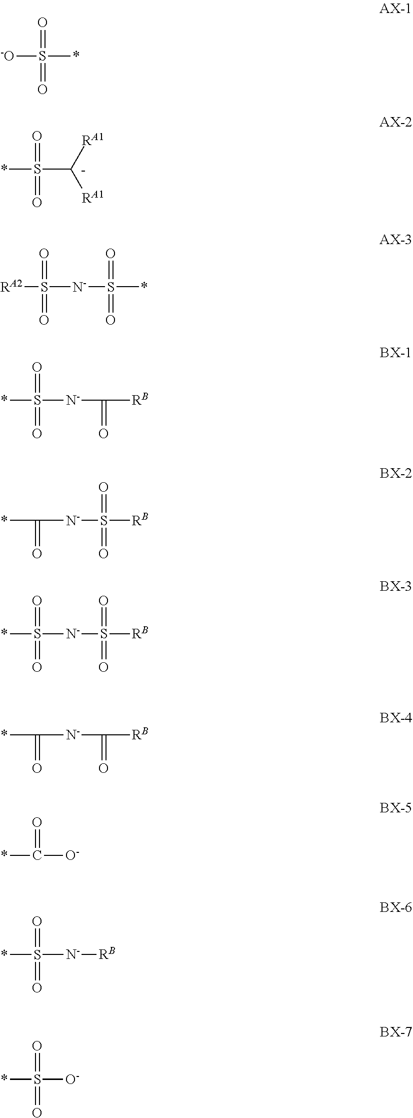

In Formulae (AX-1) to (AX-3), R^{A1} and R^{A2} each independently represent a monovalent organic group. * represents a bonding position.

Examples of the monovalent organic group represented by R^{A1} include a cyano group, a trifluoromethyl group, and a methanesulfonyl group.

As the monovalent organic group represented by R^{A2}, a linear, branched, or cyclic alkyl group, or an aryl group is preferable.

The alkyl group preferably has 1 to 15 carbon atoms, more preferably has 1 to 10 carbon atoms, and still more preferably has 1 to 6 carbon atoms.

The alkyl group may have a substituent. As the substituent, a fluorine atom or a cyano group is preferable, and the fluorine atom is more preferable. In a case where the alkyl group has a fluorine atom as the substituent, it may be a perfluoroalkyl group.

As the aryl group, a phenyl group or a naphthyl group is preferable, and the phenyl group is more preferable.

The aryl group may have a substituent. As the substituent, a fluorine atom, an iodine atom, a perfluoroalkyl group (for example, preferably a perfluoroalkyl group having 1 to 10 carbon atoms, and more preferably a perfluoroalkyl group having 1 to 6 carbon atoms), or a cyano group is preferable, and the fluorine atom, the iodine atom, or the perfluoroalkyl group is more preferable.

In Formulae (BX-1) to (BX-4) and Formula (BX-6), RB represents a monovalent organic group. * represents a bonding position.

As the monovalent organic group represented by RB, a linear, branched, or cyclic alkyl group, or an aryl group is preferable.

The alkyl group preferably has 1 to 15 carbon atoms, more preferably has 1 to 10 carbon atoms, and still more preferably has 1 to 6 carbon atoms.

The alkyl group may have a substituent. The substituent is not particularly limited, but as the substituent, a fluorine atom or a cyano group is preferable, and the fluorine atom is more preferable. In a case where the alkyl group has a fluorine atom as the substituent, it may be a perfluoroalkyl group.

Moreover, in a case where the carbon atom that serves as a bonding position in the alkyl group (for example, in a case of Formulae (BX-1) and (BX-4), the carbon atom corresponds to a carbon atom that directly bonds to —CO— specified in the formula in the alkyl group, and in a case of Formulae (BX-2) and (BX-3), the carbon atom corresponds to a carbon atom that directly bonded to —SO₂— specified in the formula in the alkyl group, and in a case of Formula (BX-6), the carbon atom corresponds to a carbon atom that directly bonded to N-specified in the formula in the alkyl group) has a substituent, it is also preferable that the carbon atom has a substituent other than a fluorine atom or a cyano group.

In addition, the alkyl group may have a carbon atom substituted with a carbonyl carbon.

As the aryl group, a phenyl group or a naphthyl group is preferable, and the phenyl group is more preferable.

The aryl group may have a substituent. As the substituent, a fluorine atom, an iodine atom, a perfluoroalkyl group (for example, preferably a perfluoroalkyl group having 1 to 10 carbon atoms, and more preferably a perfluoroalkyl group having 1 to 6 carbon atoms), a cyano group, an alkyl group (for example, preferably an alkyl group having 1 to 10 carbon atoms, and more preferably an alkyl group having 1 to 6 carbon atoms), an alkoxy group (for example, preferably an alkoxy group having 1 to 10 carbon atoms, and more preferably an alkoxy group having 1 to 6 carbon atoms), or an alkoxycarbonyl group (for example, preferably an alkoxycarbonyl group having 2 to 10 carbon atoms, and more preferably an alkoxycarbonyl group having 2 to 6 carbon atoms) is preferable, and the fluorine atom, the iodine atom, the perfluoroalkyl group, the alkyl group, the alkoxy group, or the alkoxycarbonyl group is more preferable.

In Formula (Ia-1), the divalent linking group represented by L₁ is not particularly limited, but examples thereof include —CO—, —NR—, —CO—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent linking group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include a halogen atom (preferably a fluorine atom).

Among those, the divalent linking group represented by Formula (L1) is preferable as the divalent linking group by L₁.

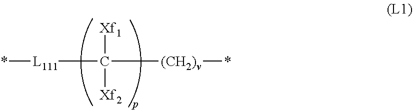

In Formula (L1), L₁₁₁ represents a single bond or a divalent linking group.

The divalent linking group represented by L₁₁₁ is not particularly limited, but examples thereof include —CO—, —NH—, —O—, —SO—, —SO₂—, an alkylene group (which preferably has 1 to 6 carbon atoms, and may be linear or branched) which may have a substituent, a cycloalkylene group (preferably having 3 to 15 carbon atoms) which may have a substituent, an aryl group (preferably having 6 to 10 carbon atoms) which may have a substituent, and a divalent linking group formed by combination of these groups. The substituent is not particularly limited, but examples thereof include a halogen atom.

p represents an integer of 0 to 3, and preferably represents an integer of 1 to 3.

v represents an integer of 0 or 1.

Xf₁'s each independently represent a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf₂'s each independently represent a hydrogen atom, an alkyl group which may have a fluorine atom as a substituent, or a fluorine atom. The alkyl group preferably has 1 to 10 carbon atoms, and more preferably has 1 to 4 carbon atoms. Among those, Xf₂ preferably represents the fluorine atom or the alkyl group substituted with at least one fluorine atom, and is more preferably the fluorine atom or a perfluoroalkyl group.

Among those, Xf₁ and Xf₂ are each independently preferably the fluorine atom or a perfluoroalkyl group having 1 to 4 carbon atoms, and more preferably the fluorine atom or CF₃. In particular, it is still more preferable that both Xf₁ and Xf₂ are fluorine atoms.

* represents a bonding position.

In a case where L₁ in Formula (Ia-1) represents a divalent linking group represented by Formula (L1), it is preferable that a bonding site (*) on the L₁₁₁ side in Formula (L1) is bonded to A₁₂⁻ in Formula (Ia-1).

In Formula (Ia-1), preferred forms of the organic cations represented by M₁₁⁺ and M₁₂⁺ will be described in detail.

The organic cations represented by M₁₁⁺ and M₁₂⁺ are each independently preferably an organic cation represented by Formula (ZaI) (cation (ZaI)) or an organic cation represented by Formula (ZaII) (cation (ZaII)).

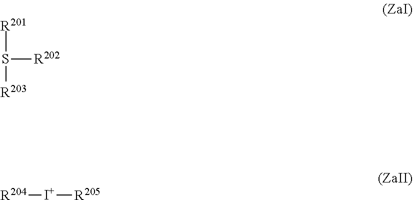

In Formula (ZaI),

R²⁰¹, R²⁰², and R²⁰³ each independently represent an organic group.

The organic group as each of R²⁰¹, R²⁰², and R²⁰³ usually has 1 to 30 carbon atoms, and preferably has 1 to 20 carbon atoms. In addition, two of R²⁰¹ to R²⁰³ may be bonded to each other to form a ring structure, and the ring may include an oxygen atom, a sulfur atom, an ester group, an amide group, or a carbonyl group. Examples of the group formed by the bonding of two of R²⁰¹ to R²⁰³ include an alkylene group (for example, a butylene group and a pentylene group), and —CH₂—CH₂—O—CH₂—CH₂—.

Suitable aspects of the organic cation as Formula (ZaI) include a cation (ZaI-1), a cation (ZaI-2), an organic cation represented by Formula (ZaI-3b) (cation (ZaI-3b)), and an organic cation represented by Formula (ZaI-4b) (cation (ZaI-4b)), each of which will be described later.

First, the cation (ZaI-1) will be described.

The cation (ZaI-1) is an arylsulfonium cation in which at least one of R²⁰¹, R²⁰², or R²⁰³ of Formula (ZaI) is an aryl group.

In the arylsulfonium cation, all of R²⁰¹ to R²⁰³ may be aryl groups, or some of R²⁰¹ to R²⁰³ may be an aryl group, and the rest may be an alkyl group or a cycloalkyl group.

In addition, one of R²⁰¹ to R²⁰³ is an aryl group, two of R²⁰¹ to R²⁰³ may be bonded to each other to form a ring structure, and an oxygen atom, a sulfur atom, an ester group, an amide group, or a carbonyl group may be included in the ring. Examples of the group formed by the bonding of two of R²⁰¹ to R²⁰³ include an alkylene group (for example, a butylene group, a pentylene group, or —CH₂—CH₂—O—CH₂—CH₂—) in which one or more methylene groups may be substituted with an oxygen atom, a sulfur atom, an ester group, an amide group, and/or a carbonyl group.

Examples of the arylsulfonium cation include a triarylsulfonium cation, a diarylalkylsulfonium cation, an aryldialkylsulfonium cation, a diarylcycloalkylsulfonium cation, and an aryldicycloalkylsulfonium cation.

As the aryl group included in the arylsulfonium cation, a phenyl group or a naphthyl group is preferable, and the phenyl group is more preferable. The aryl group may be an aryl group which has a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In a case where the arylsulfonium cation has two or more aryl groups, the two or more aryl groups may be the same as or different from each other.

The alkyl group or the cycloalkyl group contained in the arylsulfonium cation as necessary is preferably a linear alkyl group having 1 to 15 carbon atoms, a branched alkyl group having 3 to 15 carbon atoms, or a cycloalkyl group having 3 to 15 carbon atoms, and more preferably, for example, a methyl group, an ethyl group, a propyl group, an n-butyl group, a sec-butyl group, a t-butyl group, a cyclopropyl group, a cyclobutyl group, a cyclohexyl group, or the like.

The substituents which may be contained in each of the aryl group, the alkyl group, and the cycloalkyl group of each of R²⁰¹ to R²⁰³ are each independently preferably an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a cycloalkylalkoxy group (for example, having 1 to 15 carbon atoms), a halogen atom (for example, fluorine and iodine), a hydroxyl group, a carboxyl group, an ester group, a sulfinyl group, a sulfonyl group, an alkylthio group, a phenylthio group, or the like.

The substituent may further have a substituent as possible and is also preferably in the form of an alkyl halide group such as a trifluoromethyl group, for example, in which the alkyl group has a halogen atom as a substituent.

In addition, it is also preferable that the substituents form an acid-decomposable group by any combination.

Furthermore, the acid-decomposable group is intended to be a group that decomposes by the action of an acid to produce an acid group, and preferably has a structure in which an acid group is protected by a leaving group that leaves by the action of an acid. The acid group and the leaving group are as described above.

Next, the cation (ZaI-2) will be described.

The cation (ZaI-2) is a cation in which R²⁰¹ to R²⁰³ in Formula (ZaI) are each independently a cation representing an organic group having no aromatic ring. Here, the aromatic ring also includes an aromatic ring including a heteroatom.

The organic group having no aromatic ring as each of R²⁰¹ to R²⁰³ generally has 1 to 30 carbon atoms, and preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably the linear or branched 2-oxoalkyl group.

Examples of the alkyl group and the cycloalkyl group of each of R²⁰¹ to R²⁰³ include a linear alkyl group having 1 to 10 carbon atoms or branched alkyl group having 3 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group).

R²⁰¹ to R²⁰³ may further be substituted with a halogen atom, an alkoxy group (for example, having 1 to 5 carbon atoms), a hydroxyl group, a cyano group, or a nitro group.

In addition, it is also preferable that the substituents of R²⁰¹ to R²⁰³ each independently form an acid-decomposable group by any combination of the substituents.

Next, the cation (ZaI-3b) will be described.

The cation (ZaI-3b) is a cation represented by Formula (ZaI-3b).

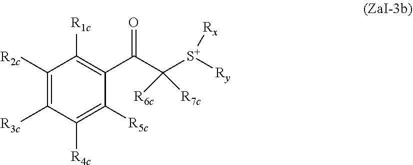

In Formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

R_{6c} and R_{7c} each independently represent a hydrogen atom, an alkyl group (a t-butyl group or the like), a cycloalkyl group, a halogen atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

In addition, it is also preferable that the substituents of R_{1c} to R_{7c}, Rₓ, and R_{y} each independently form an acid-decomposable group by any combination of substituents.

Any two or more of R_{1c}, . . . , or R_{5c}, R_{5c} and R^{6c}, R^{6c} and R_{7c}, R_{5c} and Rₓ, and Rₓ and R_{y} may each be bonded to each other to form a ring, and the ring may each independently include an oxygen atom, a sulfur atom, a ketone group, an ester bond, or an amide bond.

Examples of the ring include an aromatic or non-aromatic hydrocarbon ring, an aromatic or non-aromatic heterocyclic ring, and a polycyclic fused ring formed by combination of two or more kinds of these rings. Examples of the ring include a 3- to 10-membered ring, and the ring is preferably a 4- to 8-membered ring, and more preferably a 5- or 6-membered ring.

Examples of the group formed by the bonding of any two or more of R_{1c}, . . . , or R_{5c}, R_{6c} and R_{7c}, and Rₓ and R_{y} include an alkylene group such as a butylene group and a pentylene group. The methylene group in this alkylene group may be substituted with a heteroatom such as an oxygen atom.

As the group formed by the bonding of R_{5c} and R_{6c}, and R_{5c} and Rₓ, a single bond or an alkylene group is preferable. Examples of the alkylene group include a methylene group and an ethylene group.

A ring formed by the mutual bonding of any two or more of R_{1c} to R_{5c}, R_{6c}, R_{7c}, Rₓ, R_{y}, or R_{1c} to R_{5c}, and a ring formed by the mutual bonding of each pair of R^{5c} and R_{6c}, R_{6c} and R_{7c}, R^{5c} and Rₓ, and Rₓ and R_{y} may have a substituent.

Next, the cation (ZaI-4b) will be described.

The cation (ZaI-4b) is a cation represented by Formula (ZaI-4b).

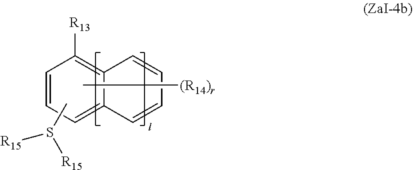

In Formula (ZaI-4b),

l represents an integer of 0 to 2.

r represents an integer of 0 to 8.

R₁₃ represents a hydrogen atom, a halogen atom (for example, a fluorine atom and an iodine atom), a hydroxyl group, an alkyl group, an alkyl halide group, an alkoxy group, a carboxyl group, an alkoxycarbonyl group, or a group having a cycloalkyl group (which may be the cycloalkyl group itself or a group including the cycloalkyl group in a part thereof). These groups may have a substituent.

R₁₄ represents a hydroxyl group, a halogen atom (for example, a fluorine atom and an iodine atom), an alkyl group, an alkyl halide group, an alkoxy group, an alkoxycarbonyl group, an alkylcarbonyl group, an alkylsulfonyl group, a cycloalkylsulfonyl group, or a group having a cycloalkyl group (which may be the cycloalkyl group itself or a group including the cycloalkyl group in a part thereof). These groups may have a substituent. In a case where R₁₄'s are present in plurality, they each independently represent the group such as a hydroxyl group.

R₁₅'s each independently represent an alkyl group, a cycloalkyl group, or a naphthyl group. Two R₁₅'s may be bonded to each other to form a ring. In a case where two R₁₅'s are bonded to each other to form a ring, the ring skeleton may include a heteroatom such as an oxygen atom and a nitrogen atom. In one aspect, it is preferable that two R₁₅'s are alkylene groups and are bonded to each other to form a ring structure. Furthermore, the alkyl group, the cycloalkyl group, the naphthyl group, and the ring formed by the mutual bonding two R₁₅'s may have a substituent.

In Formula (ZaI-4b), the alkyl group of each of R₁₃, R₁₄, and R₁₅ is linear or branched. The alkyl group preferably has 1 to 10 carbon atoms. The alkyl group is more preferably a methyl group, an ethyl group, an n-butyl group, a t-butyl group, or the like.

In addition, it is also preferable that the respective substituents of R¹³ to R¹⁵, Rₓ, and R_{y} each independently form an acid-decomposable group by any combination of substituents.

Next, Formula (ZaII) will be described.

In Formula (ZaII), R²⁰⁴ and R²⁰⁵ each independently represent an aryl group, an alkyl group, or a cycloalkyl group.

The aryl group of each of R²⁰⁴ and R²⁰⁵ is preferably a phenyl group or a naphthyl group, and more preferably the phenyl group. The aryl group of each of R²⁰⁴ and R²⁰⁵ may be an aryl group which has a heterocyclic ring having an oxygen atom, a nitrogen atom, a sulfur atom, or the like. Examples of the skeleton of the aryl group having a heterocyclic ring include pyrrole, furan, thiophene, indole, benzofuran, and benzothiophene.

The alkyl group and the cycloalkyl group of each of R²⁰⁴ and R²⁰⁵ is preferably a linear alkyl group having 1 to 10 carbon atoms or a branched alkyl group having 3 to 10 carbon atoms (for example, a methyl group, an ethyl group, a propyl group, a butyl group, and a pentyl group), or a cycloalkyl group having 3 to 10 carbon atoms (for example, a cyclopentyl group, a cyclohexyl group, or a norbornyl group).

The aryl group, the alkyl group, and the cycloalkyl group of each of R²⁰⁴ and R²⁰⁵ may each independently have a substituent. Examples of the substituent which may be contained in each of the aryl group, the alkyl group, and the cycloalkyl group of each of R²⁰⁴ and R²⁰⁵ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group. In addition, it is also preferable that the substituents of R²⁰⁴ and R²⁰⁵ each independently form an acid-decomposable group by any combination of the substituents.

Next, the compounds represented by Formulae (Ia-2) to (Ia-4) will be described.

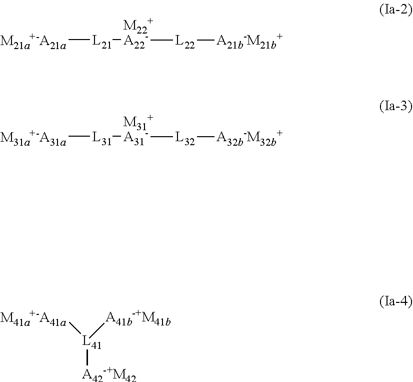

In Formula (Ia-2), A₂₁ₐ⁻ and A_{21b}⁻ each independently represent a monovalent anionic functional group. Here, the monovalent anionic functional group represented by each of A₂₁ₐ⁻ and A_{21b}⁻ is intended to be a monovalent group including the above-mentioned anionic site A₁⁻. The monovalent anionic functional group represented by each of A₂₁ₐ⁻ and A_{21b}⁻ is not particularly limited, but examples thereof include a monovalent anionic functional group selected from the group consisting of Formulae (AX-1) to (AX-3) mentioned above.

A₂₂⁻ represents a divalent anionic functional group. Here, the divalent anionic functional group represented by A₂₂⁻ is intended to be a divalent group including the above-mentioned anionic site A₂⁻. Examples of the divalent anionic functional group represented by A₂₂⁻ include divalent anionic functional groups represented by Formulae (BX-8) to (BX-11).

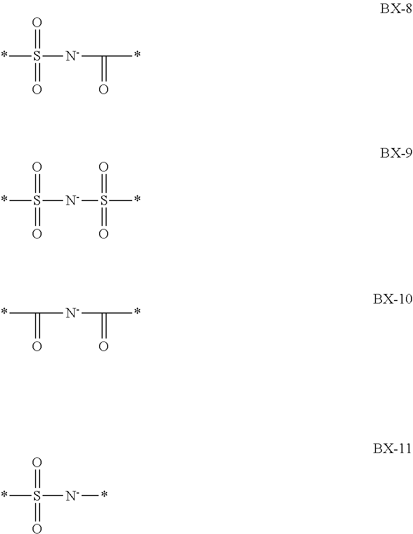 [SMILES: *C(=O)[N-]S(*)(=O)=O ; *S(=O)(=O)[N-]S(*)(=O)=O ; *C(=O)[N-]C(*)=O ; *[N-]S(*)(=O)=O]

M₂₁ₐ⁺, M_{21b}⁺, and M₂₂⁺ each independently represent an organic cation. The organic cations represented by M₂₁ₐ⁺, M_{21b}⁺, and M₂₂⁺ each have the same definition as the above-mentioned M₁⁺, and suitable aspects thereof are also the same.

L₂₁ and L₂₂ each independently represent a divalent organic group.

In addition, in the compound PIa-2 formed by substituting an organic cation represented by M₂₁ₐ⁺, M_{21b}⁺, and M₂₂⁺ with H⁺ in Formula (Ia-2), the acid dissociation constant a2 derived from the acidic site represented by A₂₂H is larger than the acid dissociation constant a1-1 derived from the acidic site represented by A₂₁ₐH and the acid dissociation constant a1-2 derived from the acidic site represented by A_{21b}H. Incidentally, the acid dissociation constant a1-1 and the acid dissociation constant a1-2 correspond to the above-mentioned acid dissociation constant a1.

Furthermore, A₂₁ₐ⁻ and A_{21b}⁻ may be the same as or different from each other. In addition, M₂₁ₐ⁺, M_{21b}⁺, and M₂₂⁺ may be the same as or different from each other.

Moreover, at least one of M₂₁ₐ⁺, M_{21b}⁺, M₂₂⁺, A₂₁ₐ⁻, A_{21b}⁻, L₂₁, or L₂₂ may have an acid-decomposable group as a substituent.

In Formula (Ia-3), A₃₁ₐ⁻ and A₃₂⁻ each independently represent a monovalent anionic functional group. Furthermore, the monovalent anionic functional group represented by A₃₁ₐ⁻ has the same definition as A₂₁ₐ⁻ and A_{21b}⁻ in Formula (Ia-2) mentioned above, and suitable aspects thereof are also the same.

The monovalent anionic functional group represented by A₃₂⁻ is intended to be a monovalent group including the above-mentioned anionic site A₂³¹. The monovalent anionic functional group represented by A₃₂⁻ is not particularly limited, but examples thereof include a monovalent anionic functional group selected from the group consisting of Formulae (BX-1) to (BX-7) mentioned above.

A_{31b}⁻ represents a divalent anionic functional group. Here, the divalent anionic functional group represented by A_{31b}⁻ is intended to be a divalent group including the above-mentioned anionic site A₁⁻. Examples of the divalent anionic functional group represented by A_{31b}⁻ include a divalent anionic functional group represented by Formula (AX-4).

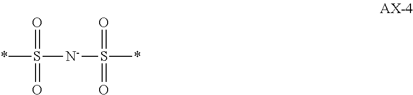 [SMILES: *S(=O)(=O)[N-]S(*)(=O)=O]

M₃₁ₐ⁺, M_{31b}⁺, and M₃₂⁺ each independently represent a monovalent organic cation. The organic cation represented by M₃₁ₐ⁺, M_{31b}⁺, and M₃₂⁺ have the same definitions as the above-mentioned M₁⁺, and suitable aspects thereof are also the same.

L₃₁ and L₃₂ each independently represent a divalent organic group.

In addition, in the compound PIa-3 formed by substituting an organic cation represented by M₃₁ₐ⁺, M_{31b}⁺, and M₃₂⁺ with H⁺ in Formula (Ia-3), the acid dissociation constant a2 derived from the acidic site represented by A₃₂H is larger than the acid dissociation constant a1-3 derived from the acidic site represented by A₃₁ₐH and the acid dissociation constant a1-4 derived from the acidic site represented by A_{31b}H. Incidentally, the acid dissociation constant a1-3 and the acid dissociation constant a1-4 correspond to the above-mentioned acid dissociation constant a1.

Furthermore, A₃₁ₐ⁻ and A₃₂⁻ may be the same as or different from each other. In addition, M₃₁ₐ⁺, M_{31b}⁺, and M₃₂⁺ may be the same as or different from each other.

Moreover, at least one of M₃₁ₐ⁺, M_{31b}⁺, M₃₂⁺, A₃₁ₐ⁻, A₃₂⁻, L₃₁, or L₃₂ may have an acid-decomposable group as a substituent.

In Formula (Ia-4), A₄₁ₐ⁻, A_{41b}⁻, and A₄₂⁻ each independently represent a monovalent anionic functional group. Furthermore, the monovalent anionic functional groups represented by A₄₁ₐ⁻ and A_{41b}⁻ have the same definitions as A₂₁ₐ⁻ and A_{21b}⁻ in Formula (Ia-2) mentioned above. In addition, the monovalent anionic functional group represented by A₄₂⁻ has the same definition as A₃₂⁻ in Formula (Ia-3) mentioned above, and suitable aspects thereof are also the same.

M₄₁ₐ⁺, M_{41b}⁺, and M₄₂⁺ each independently represent an organic cation.

L₄₁ represents a trivalent organic group.

In addition, in the compound PIa-4 formed by substituting an organic cation represented by M₄₁ₐ⁺, M_{41b}⁺, and M₄₂⁺ with H⁺ in Formula (Ia-4), the acid dissociation constant a2 derived from the acidic site represented by A₄₂H is larger than the acid dissociation constant a1-5 derived from the acidic site represented by A₄₁ₐH and the acid dissociation constant a1-6 derived from the acidic site represented by A_{41b}H. Incidentally, the acid dissociation constant a1-5 and the acid dissociation constant a1-6 correspond to the above-mentioned acid dissociation constant a1.

Furthermore, A₄₁ₐ⁻, A_{41b}⁻, and A₄₂⁻ may be the same as or different from each other. In addition, M₄₁ₐ⁺, M_{41b}⁺, and M₄₂⁺ may be the same as or different from each other.

Moreover, at least one of M₄₁ₐ⁺, M_{41b}⁺, M₄₂⁺, A₄₁ₐ⁻, A_{41b}⁻, A₄₂⁻, or L₄₁ may have an acid-decomposable group as a substituent.

The divalent organic group represented by each of L₂₁ and L₂₂ in Formula (Ia-2) and L₃₁ and L₃₂ in Formula (Ia-3) is not particularly limited, but examples thereof include —CO—, —NR—, —O—, —S—, —SO—, —SO₂—, an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent organic group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include a halogen atom (preferably a fluorine atom).

As the divalent organic group represented by each of L₂₁ and L₂₂ in Formula (Ia-2) and L₃₁ and L₃₂ in Formula (Ia-3), for example, a divalent organic group represented by Formula (L2) is preferable.

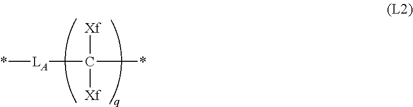

In Formula (L2), q represents an integer of 1 to 3. * represents a bonding position.

Xf's each independently represent a fluorine atom or an alkyl group substituted with at least one fluorine atom. The alkyl group preferably has 1 to 10 carbon atoms, and more preferably has 1 to 4 carbon atoms. In addition, a perfluoroalkyl group is preferable as the alkyl group substituted with at least one fluorine atom.

Xf is preferably the fluorine atom or a perfluoroalkyl group having 1 to 4 carbon atoms, and more preferably the fluorine atom or CF₃. In particular, it is still more preferable that both Xf's are fluorine atoms.

L_{A} represents a single bond or a divalent linking group.

The divalent linking group represented by L_{A} is not particularly limited, but examples thereof include —CO—, —O—, —SO—, —SO₂—, an alkylene group (which preferably has 1 to 6 carbon atoms and may be linear or branched), a cycloalkylene group (preferably having 3 to 15 carbon atoms), a divalent aromatic hydrocarbon ring group (preferably having a 6 to 10-membered ring, and more preferably having a 6-membered ring), and a divalent linking group formed by combination of a plurality of these groups.

In addition, the alkylene group, the cycloalkylene group, and the divalent aromatic hydrocarbon ring group may have a substituent. Examples of the substituent include a halogen atom (preferably a fluorine atom).

Examples of the divalent organic group represented by Formula (L2) include *—CF₂—*, *—CF₂*—CF₂—CF₂—CF₂—*, *-Ph-O— SO₂—CF₂—*, *-Ph-O— SO₂—CF₂—CF₂—*, *-Ph-O—SO₂—CF₂—CF₂—CF₂—*, and d*-Ph-OCO—CF₂—*. Furthermore, Ph is a phenylene group which may have a substituent, and is preferably a 1,4-phenylene group. The substituent is not particularly limited, but is preferably an alkyl group (for example, preferably an alkyl group having 1 to 10 carbon atoms, and more preferably an alkyl group having 1 to 6 carbon atoms), an alkoxy group (for example, preferably an alkoxy group having 1 to 10 carbon atoms, and more preferably an alkoxy group having 1 to 6 carbon atoms), or an alkoxycarbonyl group (for example, preferably an alkoxycarbonyl group having 2 to 10 carbon atoms, and more preferably an alkoxycarbonyl group having 2 to 6 carbon atoms).

In a case where L₂₁ and L₂₂ in Formula (Ia-2) represent a divalent organic group represented by Formula (L2), it is preferable that a bonding site (*) on the L_{A} side in Formula (L2) is bonded to A₂₁ₐ⁻ and A_{21b}⁻ in Formula (Ia-2).

In addition, in a case where L₃₁ and L₃₂ in Formula (Ia-3) represent a divalent organic group represented by Formula (L2), it is preferable that a bonding site (*) on the L_{A} side in Formula (L2) is combined with A₃₁ₐ⁻ and A₃₂⁻ in Formula (Ia-3).

The trivalent organic group represented by L₄₁ in Formula (Ia-4) is not particularly limited, but examples thereof include a trivalent organic group represented by Formula (L3).

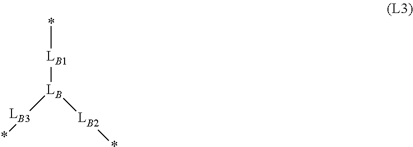

In Formula (L3), L_{B} represents a trivalent hydrocarbon ring group or a trivalent heterocyclic group. * represents a bonding position.

The hydrocarbon ring group may be an aromatic hydrocarbon ring group or an aliphatic hydrocarbon ring group. The number of carbon atoms included in the hydrocarbon ring group is preferably 6 to 18, and more preferably 6 to 14. The heterocyclic group may be either an aromatic heterocyclic group or an aliphatic heterocyclic group. The heterocyclic ring group is preferably a 5- to 10-membered ring, more preferably a 5- to 7-membered ring, and still more preferably a 5- or 6-membered ring, each of which has at least one N atom, O atom, S atom, or Se atom in the ring structure.

As L_{B}, above all, the trivalent hydrocarbon ring group is preferable, and a benzene ring group or an adamantane ring group is more preferable. The benzene ring group or the adamantane ring group may have a substituent. The substituent is not particularly limited, but examples thereof include a halogen atom (preferably a fluorine atom).

In addition, in Formula (L3), L_{B1} to L_{B3} each independently represent a single bond or a divalent linking group. The divalent linking group represented by L_{B1} to L_{B3} is not particularly limited, and for example, —CO—, —NR—, —O—, —S—, —SO—, —SO₂—, or an alkylene group (which preferably has 1 to 6 carbon atoms, and may be linear or branched), a cycloalkylene group (preferably having 3 to 15 carbon atoms), an alkenylene group (preferably having 2 to 6 carbon atoms), a divalent aliphatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic heterocyclic group (preferably having a 5- to 10-membered ring, more preferably having a 5- to 7-membered ring, and still more preferably having a 5- or 6-membered ring, each having at least one of an N atom, an O atom, an S atom, or an Se atom in the ring structure), a divalent aromatic hydrocarbon ring group (preferably having a 6- to 10-membered ring, and more preferably having a 6-membered ring), and a divalent linking group formed by combination of a plurality of these groups. Examples of R include a hydrogen atom or a monovalent organic group. The monovalent organic group is not particularly limited, but is preferably, for example, an alkyl group (preferably having 1 to 6 carbon atoms).

In addition, the alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include a halogen atom (preferably a fluorine atom).

As the divalent linking group represented by each of L_{B1} to L_{B3}, among those, —CO—, —NR—, —O—, —S—, —SO—, —SO₂—, the alkylene group which may have a substituent, and the divalent linking group formed by combination of these groups are preferable.

As the divalent linking group represented by each of L_{B1} to L_{B3}, the divalent linking group represented by Formula (L3-1) is more preferable.

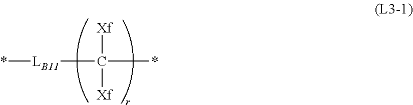

In Formula (L3-1), L_{B11} represents a single bond or a divalent linking group.

The divalent linking group represented by L_{B11} is not particularly limited, but examples thereof include —CO—, —O—, —SO—, —SO₂—, an alkylene group (which preferably has 1 to 6 carbon atoms, and may be linear or branched) which may have a substituent, and a divalent linking group formed by combination of a plurality of these groups. The substituent is not particularly limited, but examples thereof include a halogen atom.

r represents an integer of 1 to 3.

Xf has the same definition as Xf in Formula (L2) mentioned above, and suitable aspects thereof are also the same.

* represents a bonding position.

Examples of the divalent linking groups represented by each of L_{B1} to L_{B3} include *—O—*, *—O—SO₂—CF₂—*, *—O—SO₂—CF₂—CF₂—*, *—O—SO₂—CF₂—CF₂—CF₂—*, and *—COO—CH₂—CH₂—*.

In a case where L₄₁ in Formula (Ia-4) includes a divalent organic group represented by Formula (L3-1), and the divalent organic group represented by Formula (L3-1) and A₄₂⁻ are bonded to each other, it is preferable that the bonding site (*) on the carbon atom side specified in Formula (L3-1) is bonded to A₄₂⁻ in Formula (Ia-4).

Next, a compound represented by Formula (Ia-5) will be described.

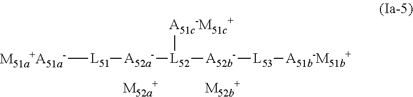

In Formula (Ia-5), A₅₁ₐ⁻, A_{51b}⁻, and A_{51c}⁻ each independently represent a monovalent anionic functional group. Here, the monovalent anionic functional group represented by each of A₅₁ₐ⁻, A_{51b}⁻, and A_{51c}⁻ is intended to be a monovalent group including the above-mentioned anionic site A₁⁻. The monovalent anionic functional group represented by each of A₅₁ₐ⁻, A_{51b}⁻, and A_{51c}⁻ is not particularly limited, but examples thereof include a monovalent anionic functional group selected from the group consisting of Formulae (AX-1) to (AX-3) mentioned above.

A₅₂ₐ⁻ and A_{52b}⁻ each represent a divalent anionic functional group. Here, the divalent anionic functional group represented by each of A₅₂ₐ⁻ and A_{52b}⁻ is intended to be a divalent group including the above-mentioned anionic site A₂⁻. Examples of the divalent anionic functional group represented by A₂₂⁻ include a divalent anionic functional group selected from the group consisting of Formulae (BX-8) to (BX-11) mentioned above.

M₅₁ₐ⁺, M_{51b}⁺, M_{51c}⁺, M₅₂ₐ⁺, and M_{52b}⁺ each independently represent an organic cation. The organic cation represented by each of M₅₁ₐ⁺, M_{51b}⁺, M_{51c}⁺, M₅₂ₐ⁺, and M_{52b}⁺ has the same definition as the above-mentioned M₁⁺, and suitable aspects thereof are also the same.

L₅₁ and L₅₃ each independently represent a divalent organic group. The divalent organic group represented by each of L₅₁ and L₅₃ has the same definition as L₂₁ and L₂₂ in Formula (Ia-2) mentioned above, and suitable aspects thereof are also the same.

L₅₂ represents a trivalent organic group. The trivalent organic group represented by L₅₂ has the same definition as L₄₁ in Formula (Ia-4) mentioned above, and suitable aspects thereof are also the same.

In addition, in the compound PIa-5 formed by substituting an organic cation represented by each of M₅₁ₐ⁺, M_{51b}⁺, M_{51c}⁺, M₅₂ₐ⁺, and M_{52b}⁺ with H⁺ in Formula (Ia-5), the acid dissociation constant a2-1 derived from the acidic site represented by A₅₂ₐH and the acid dissociation constant a2-2 derived from the acidic site represented by A_{52b}H are larger than the acid dissociation constant a1-1 derived from the acidic site represented by A₅₁ₐH, the acid dissociation constant a1-2 derived from the acidic site represented by A_{51b}H, and the acid dissociation constant a1-3 derived from the acidic site represented by A_{51c}H. Incidentally, the acid dissociation constants a1-1 to a1-3 correspond to the above-mentioned acid dissociation constant a1, and the acid dissociation constants a2-1 and a2-2 correspond to the above-mentioned acid dissociation constant a2.

Furthermore, A₅₁ₐ⁻, A_{51b}⁻, and A_{51c}⁻ may be the same as or different from each other. Moreover, A₅₂ₐ⁻ and A_{52b}⁻ may be the same as or different from each other. In addition, M₅₁ₐ⁺, M_{51b}⁺, M_{51c}⁺, M₅₂ₐ⁺, and M_{52b}⁺ may be the same as or different from each other.

Moreover, at least one of M_{51b}, M_{51c}⁺, M₅₂ₐ⁺, M_{52b}⁺, A₅₁ₐ⁻, A_{51b}⁻, A_{51c}⁻, L₅₁, L₅₂, or L₅₃ may have an acid-decomposable group as a substituent.

<<Compound (II)>>

The compound (II) is a compound having two or more sites of the structural site X and one or more sites of the following structural site Z, the compound generating an acid including two or more sites of the first acidic site derived from the structural site X and the structural site Z upon irradiation with actinic rays or radiation.

Structural site Z: a nonionic site capable of neutralizing an acid

In the compound (II), the definition of the structural site X and the definitions of A₁⁻ and M₁⁺ are the same as the definition of the structural site X in the compound (I), and the definitions of A₁⁻ and M₁⁺, each mentioned above, and suitable aspects thereof are also the same.

In the compound PII formed by substituting the cationic site M₁⁺ in the structural site X with H⁺ in the compound (II), a suitable range of the acid dissociation constant a1 derived from the acidic site represented by HA₁, formed by substituting the cationic site M₁⁺ in the structural site X with H⁺, is the same as the acid dissociation constant a1 in the compound PI.

Furthermore, in a case where the compound (II) is, for example, a compound that generates an acid having two sites of the first acidic site derived from the structural site X and the structural site Z, the compound PII corresponds to a “compound having two HA₁'s”. In a case where the acid dissociation constant of the compound PII was determined, the acid dissociation constant in a case where the compound PII serves as a “compound having one A₁⁻ and one HA₁” and the acid dissociation constant in a case where the “compound having one A₁⁻ and one HA₁” serves as a “compound having two A₁⁻'s” correspond to the acid dissociation constant a1.

The acid dissociation constant a1 is determined by the above-mentioned method for measuring an acid dissociation constant.

The compound PII corresponds to an acid generated upon irradiating the compound (II) with actinic rays or radiation.

Furthermore, two or more sites of the structural site X may be the same as or different from each other. In addition, two or more A₁⁻'s and two or more M₁⁺'s may be the same as or different from each other.

The nonionic site capable of neutralizing an acid in the structural site Z is not particularly limited, and is preferably, for example, a site including a functional group having a group or electron which is capable of electrostatically interacting with a proton.

Examples of the functional group having a group or electron capable of electrostatically interacting with a proton include a functional group with a macrocyclic structure, such as a cyclic polyether, or a functional group having a nitrogen atom having an unshared electron pair not contributing to n-conjugation. The nitrogen atom having an unshared electron pair not contributing to it-conjugation is, for example, a nitrogen atom having a partial structure represented by the following formula.

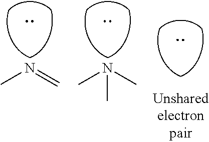

Examples of the partial structure of the functional group having a group or electron capable of electrostatically interacting with a proton include a crown ether structure, an azacrown ether structure, primary to tertiary amine structures, a pyridine structure, an imidazole structure, and a pyrazine structure, and among these, the primary to tertiary amine structures are preferable.

The compound (II) is not particularly limited, but examples thereof include compounds represented by Formula (IIa-1) and Formula (IIa-2).

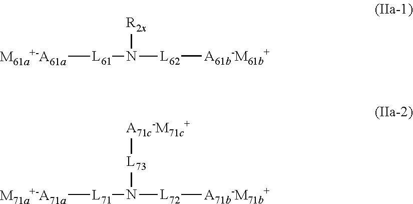

In Formula (IIa-1), A₆₁ₐ⁻ and A_{61b}⁻ each have the same definition as in Formula (Ia-1) mentioned above, and suitable aspects thereof are also the same. In addition, M₆₁ₐ⁺ and M_{61b}⁺ each have the same definition as M₁₁⁺ in Formula (Ia-1) mentioned above, and suitable aspects thereof are also the same.

In Formula (IIa-1), L₆₁ and L₆₂ each have the same definition as L₁ in Formula (Ia-1) mentioned above, and suitable aspects thereof are also the same.

In Formula (IIa-1), R_{2X} represents a monovalent organic group. The monovalent organic group represented by R_{2X} is not particularly limited, but examples thereof include an alkyl group (which preferably has 1 to 10 carbon atoms, and may be linear or branched), a cycloalkyl group (preferably having 3 to 15 carbon atoms), and an alkenyl group (preferably having 2 to 6 carbon atoms), in which —CH₂— may be substituted with one or a combination of two or more selected from the group consisting of —CO—, —NH—, —O—, —S—, —SO—, and —SO₂—.

In addition, the alkylene group, the cycloalkylene group, and the alkenylene group may have a substituent. The substituent is not particularly limited, but examples thereof include a halogen atom (preferably a fluorine atom).

In addition, in the compound PIIa-1 formed by substituting an organic cation represented by M₆₁ₐ⁺ and M_{61b}⁺ with H⁺ in Formula (IIa-1), the acid dissociation constant a1-7 derived from the acidic site represented by A₆₁ₐH and the acid dissociation constant a1-8 derived from the acidic site represented by A_{61b}H correspond to the above-mentioned acid dissociation constant a1.

Furthermore, the compound PIIa-1 formed by substituting the cationic sites M₆₁ₐ⁺ and M_{61b}⁺ in the structural site X with H⁺ in the compound (IIa-1) corresponds to HA₆₁ₐ-L₆₁-N(R_{2X})-L₆₂-A_{61b}H. In addition, the acids generated from the compound PIIa-1 and the compound represented by Formula (IIa-1) upon irradiation with actinic rays or radiation are the same.

Moreover, at least one of M₆₁ₐ⁺, M_{61b}⁺, A₆₁ₐ⁻, A_{61b}⁻, L₆₁, L₆₂, or R₂ₓ may have an acid-decomposable group as a substituent.

In Formula (IIa-2), A₇₁ₐ⁻, A_{71b}⁻, and A_{71c}⁻ each have the same definition as A₁₁⁻ in Formula (Ia-1) mentioned above, and suitable aspects thereof are also the same. In addition, M₇₁ₐ⁺, M_{71b}⁺, and M_{71c}⁺ each have the same definition as M₁₁⁺ in Formula (Ia-1) mentioned above, and suitable aspects thereof are also the same.

In Formula (IIa-2), L₇₁, L₇₂, and L₇₃ each have the same definition as L₁ in Formula (Ia-1) mentioned above, and suitable aspects thereof are also the same.

In addition, in the compound PIIa-2 formed by substituting an organic cation represented by M₇₁ₐ⁺, M_{71b}⁺, and M_{71c}⁺ with H⁺ in Formula (IIa-2), the acid dissociation constant a1-9 derived from the acidic site represented by A₇₁ₐH, the acid dissociation constant a1-10 derived from the acidic site represented by A_{71b}H, and the acid dissociation constant a1-11 derived from the acidic site represented by A_{71c}H correspond to the above-mentioned acid dissociation constant a1.

Furthermore, the compound PIIa-2 formed by substituting the cationic sites M₇₁ₐ⁺, M_{71b}⁺, and M_{71c}⁺ in the structural site X with H⁺ in the compound (IIa-1) corresponds to HA₇₁ₐ-L₇₁-N(L₇₃-A_{71c}H)-L₇₂-A_{71b}H. In addition, the acids generated from the compound PIIa-2 and the compound represented by Formula (IIa-2) upon irradiation with actinic rays or radiation are the same.

Moreover, at least one of M₇₁ₐ⁺, M_{71b}⁺, M_{71c}⁺, A₇₁ₐ⁻, A_{71b}⁻, A_{71c}⁻, L₇₁, L₇₂, or L₇₃ may have an acid-decomposable group as a substituent.

The organic cations and the other sites, which can be included in the specific photoacid generator, are exemplified below.

The organic cations can be used as, for example, M₁₁⁺, M₁₂⁺, M₂₁ₐ⁺, M_{21b}⁺, M₂₂⁺, M₃₁ₐ⁺, M_{31b}⁺, M₃₂⁺, M₄₁ₐ⁺, M_{41b}⁺, M₄₂⁺, M₅₁ₐ⁺, M_{51b}⁺, M_{51c}⁺, M₅₂ₐ⁺, or M_{52b}⁺ in the compounds represented by Formulae (Ia-1) to (Ia-5).

The other sites can be used as, for example, moieties other than M₁₁⁺, M₁₂⁺, M₂₁ₐ⁺, M_{21b}⁺, M₂₂⁺, M₃₁ₐ⁺, M_{31b}⁺, M₃₂⁺, M₄₁ₐ⁺, M_{41b}⁺, M₄₂⁺, M₅₁ₐ⁺, M_{51b}⁺, M_{51c}⁺, M₅₂ₐ⁺, or M_{52b}⁺ in the compounds represented by Formulae (Ia-1) to (Ia-5).

The organic cations and the other sites shown below can be appropriately combined and used as a specific photoacid generator.

First, an organic cation which can be contained in a specific photoacid generator will be exemplified.

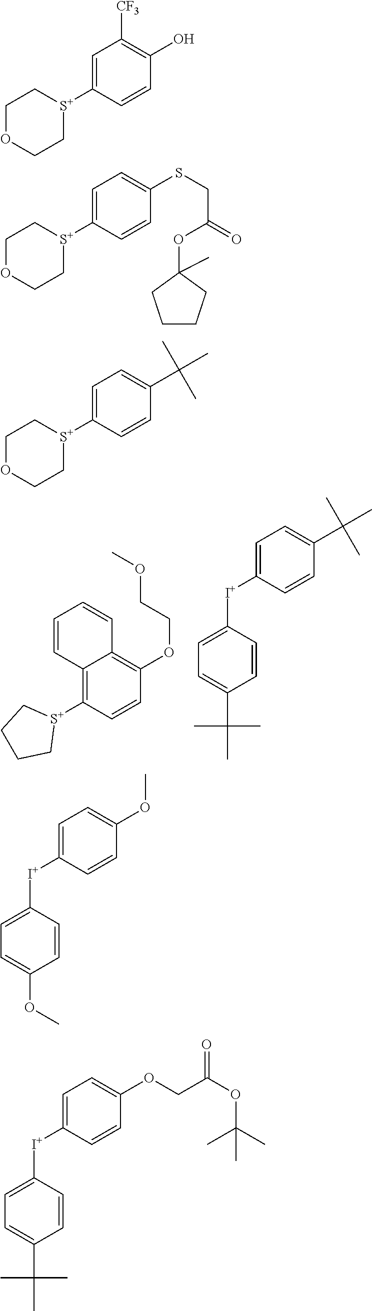

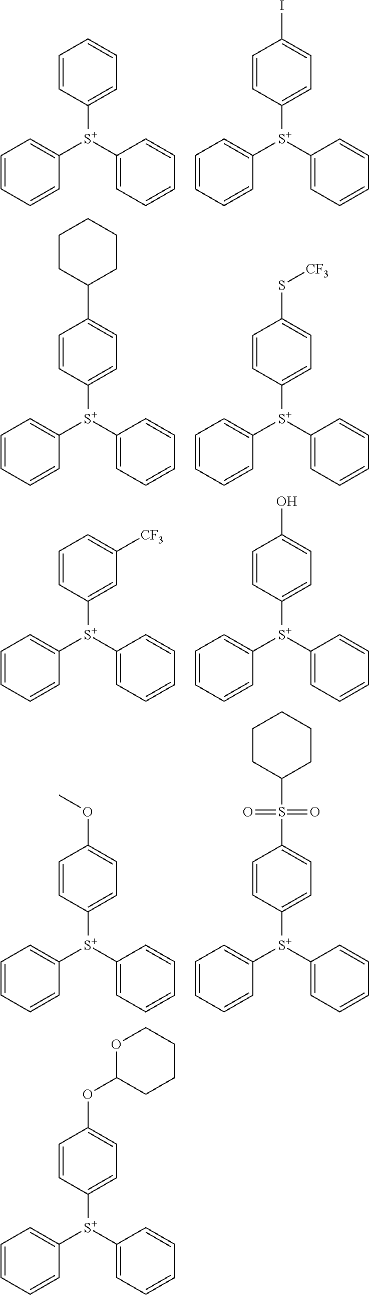

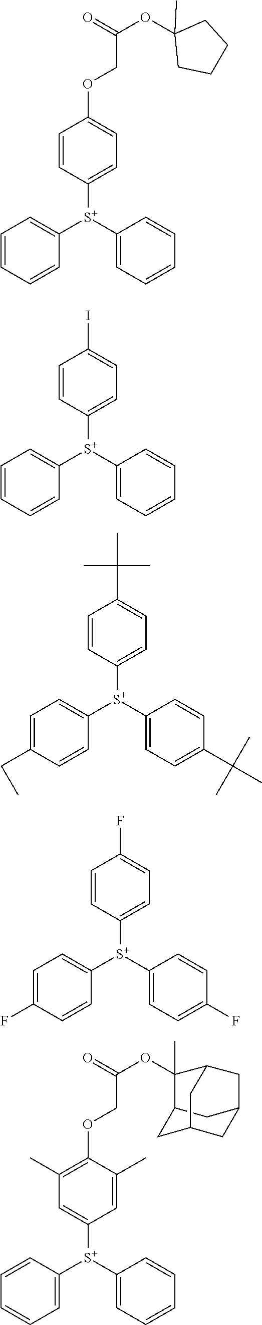 [SMILES: CC1(OC(=O)COc2ccc([S+](c3ccccc3)c3ccccc3)cc2)CCCC1 ; Ic1ccc([S+](c2ccccc2)c2ccccc2)cc1 ; CCc1ccc([S+](c2ccc(C(C)(C)C)cc2)c2ccc(C(C)(C)C)cc2)cc1 ; Fc1ccc([S+](c2ccc(F)cc2)c2ccc(F)cc2)cc1 ; Cc1cc([S+](c2ccccc2)c2ccccc2)cc(C)c1OCC(=O)OC1(C)C2CC3CC(C2)CC1C3]

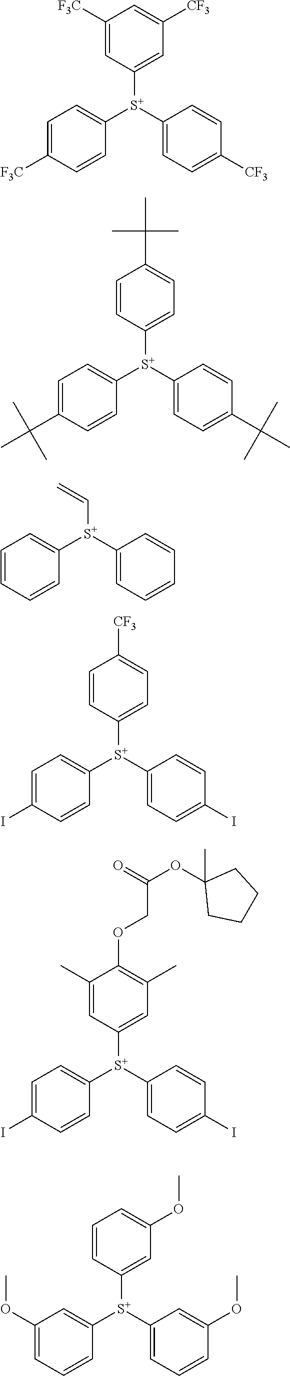 [SMILES: FC(F)(F)c1ccc([S+](c2ccc(C(F)(F)F)cc2)c2cc(C(F)(F)F)cc(C(F)(F)F)c2)cc1 ; CC(C)(C)c1ccc([S+](c2ccc(C(C)(C)C)cc2)c2ccc(C(C)(C)C)cc2)cc1 ; C=C[S+](c1ccccc1)c1ccccc1 ; FC(F)(F)c1ccc([S+](c2ccc(I)cc2)c2ccc(I)cc2)cc1 ; Cc1cc([S+](c2ccc(I)cc2)c2ccc(I)cc2)cc(C)c1OCC(=O)OC1(C)CCCC1 ; COc1cccc([S+](c2cccc(OC)c2)c2cccc(OC)c2)c1]

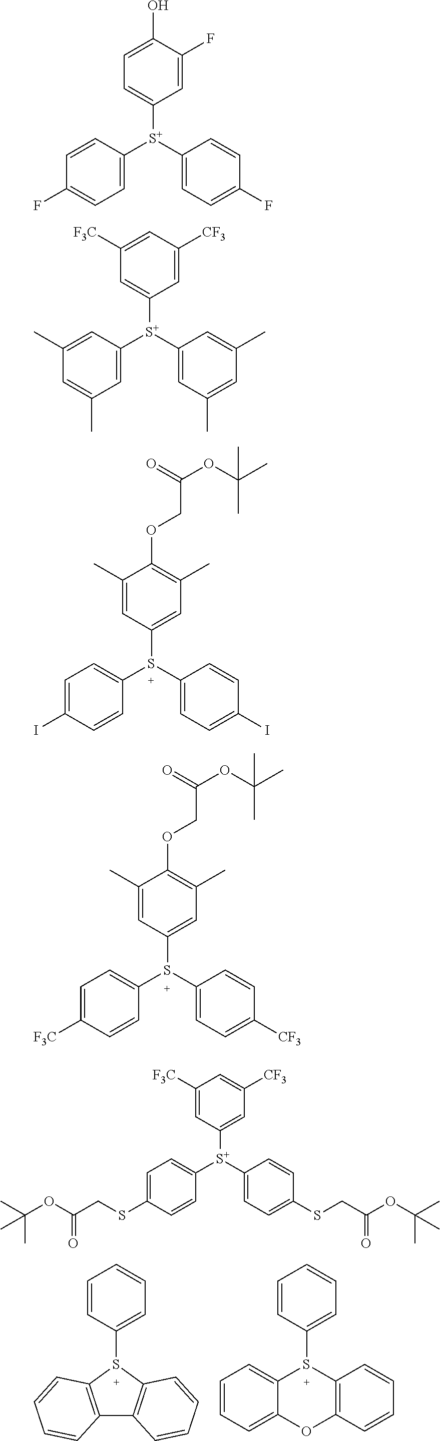

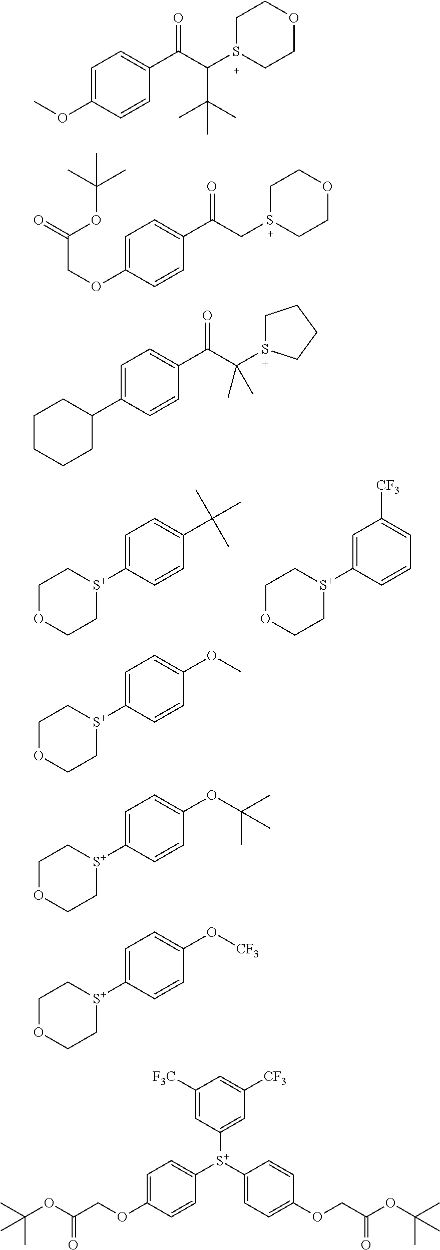

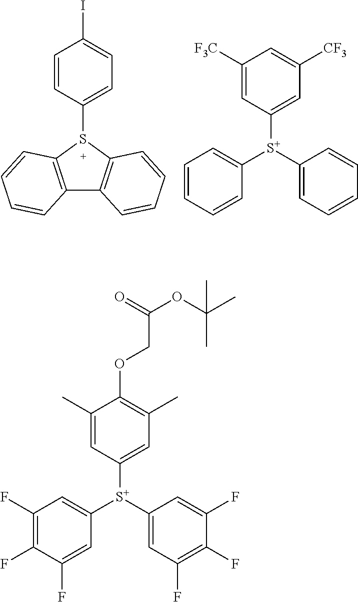

Next, a site other than the organic cation which can be included in the specific photoacid generator will be exemplified.

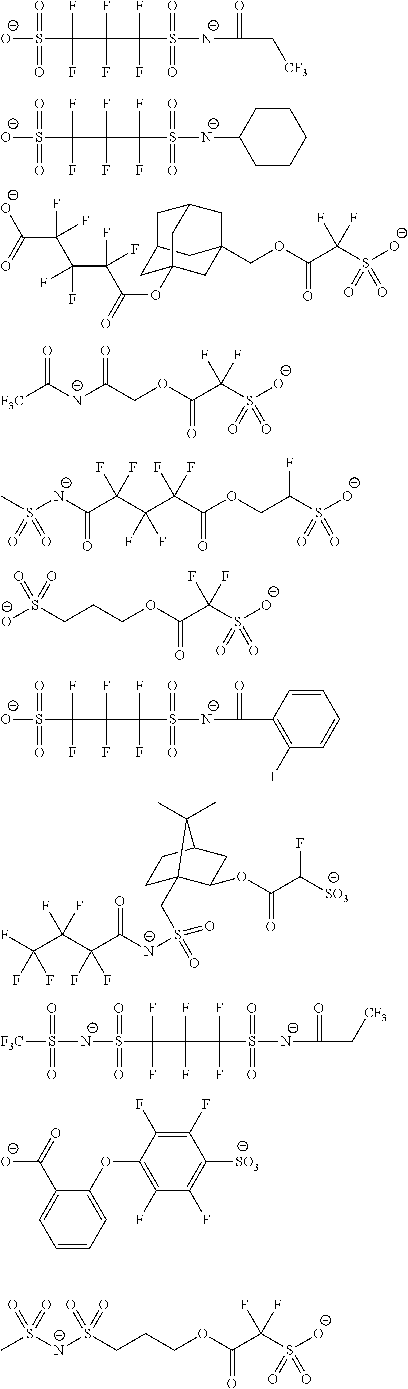

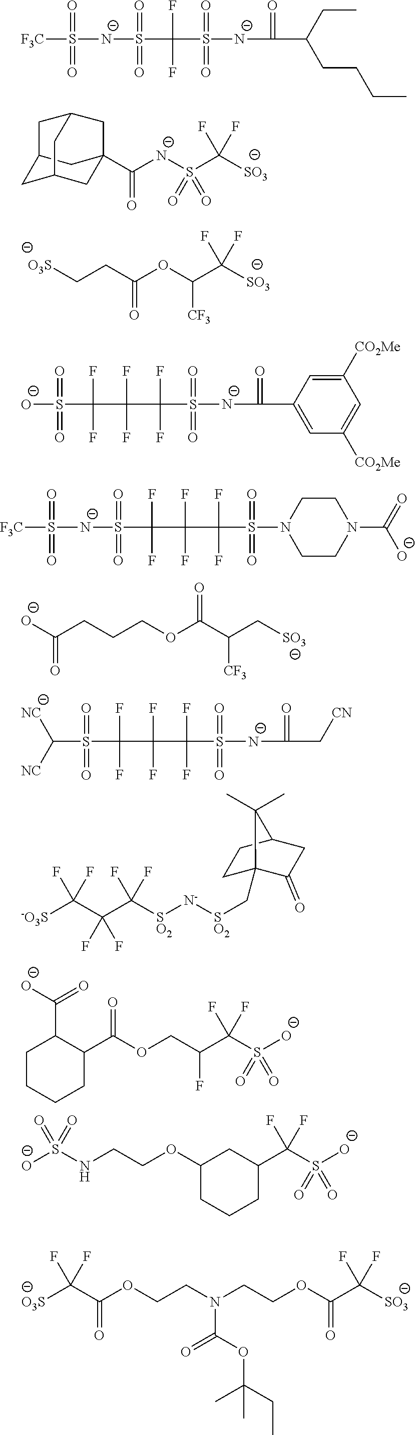

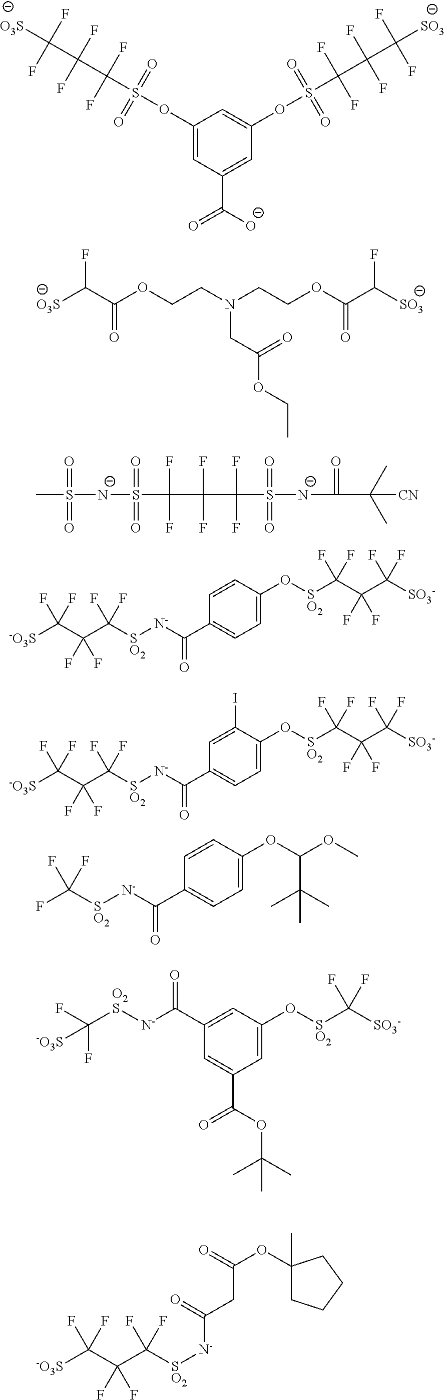

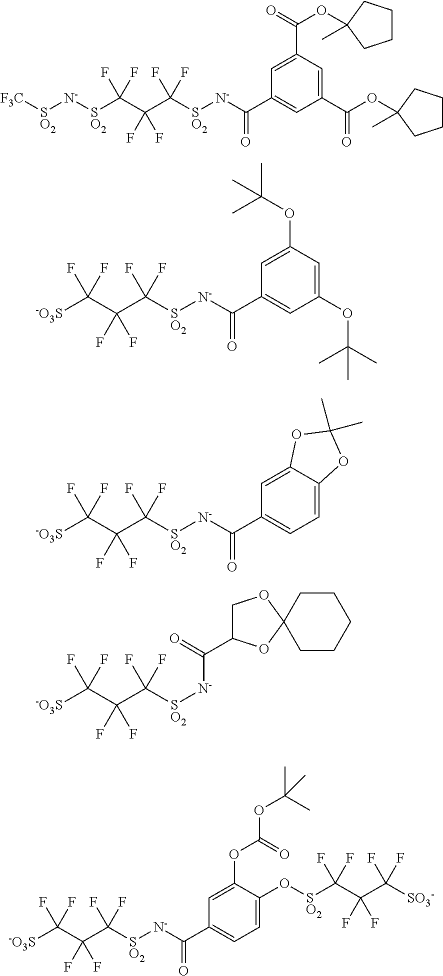

The molecular weight of the specific photoacid generator is preferably 100 to 10,000, more preferably 100 to 2,500, and still more preferably 100 to 1,500.

The specific photoacid generators may be used alone or in combination of two or more kinds thereof

<<Other Photoacid Generators>>

The resist composition may include a photoacid generator (hereinafter also referred to as “another photoacid generator”) other than the above-mentioned specific photoacid generator.

Such another photoacid generator may be in a form of a low-molecular-weight compound or a form incorporated into a part of a polymer. In addition, a combination of the form of a low-molecular-weight compound and the form incorporated into a part of a polymer may also be used.

In a case where such another photoacid generator is in the form of a low-molecular-weight compound, the molecular weight is preferably 3,000 or less, more preferably 2,000 or less, and still more preferably 1,000 or less.

In a case where such another photoacid generator is in the form incorporated into a part of a polymer, it may be incorporated into a part of the resin (A) or into a resin that is different from the resin (A).

In the present invention, such another photoacid generator is preferably in the form of the low-molecular-weight compound.

Examples of such another photoacid generator include a compound (onium salt) represented by “M⁺X⁻”, and a compound that generates an organic acid by exposure is preferable.

Examples of the organic acid include sulfonic acid (an aliphatic sulfonic acid such as a fluoroaliphatic sulfonic acid, an aromatic sulfonic acid, and a camphor sulfonic acid), a bis(alkylsulfonyl)imide acid, and a tris(alkylsulfonyl) methidoic acid.

In the compound represented by “M⁺X⁻”, M⁺ represents an organic cation.

The organic cation is preferably the above-mentioned cation represented by Formula (ZaI) (cation (ZaI)) or cation represented by Formula (ZaII) (cation (ZaII)).

In the compound represented by “M⁺X⁻” represents an organic anion.

The organic anion is not particularly limited, and is preferably a non-nucleophilic anion (anion having a significantly low ability to cause a nucleophilic reaction).

Examples of the non-nucleophilic anion include a sulfonate anion (an aliphatic sulfonate anion, an aromatic sulfonate anion, a camphor sulfonate anion, and the like), a sulfonylimide anion, a bis(alkylsulfonyl)imide anion, and a tris(alkylsulfonyl)methide anion.

The aliphatic site in the aliphatic sulfonate anion may be an alkyl group or a cycloalkyl group, and has a linear or branched alkyl group having 1 to 30 carbon atoms, or is preferably a cycloalkyl group having 3 to 30 carbon atoms.

The alkyl group may be, for example, a fluoroalkyl group (which may or may not have a substituent other than a fluorine atom, and may be a perfluoroalkyl group).

The aryl group in the aromatic sulfonate anion and the aromatic carboxylate anion is preferably an aryl group having 6 to 14 carbon atoms, and examples thereof include a phenyl group, a tolyl group, and a naphthyl group.

The alkyl group, the cycloalkyl group, and the aryl group exemplified above may have a substituent. The substituent is not particularly limited, but specific examples of the substituent include a nitro group, a halogen atom such as fluorine atom or a chlorine atom, a carboxyl group, a hydroxyl group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 12 carbon atoms), an acyl group (preferably having 2 to 12 carbon atoms), an alkoxycarbonyloxy group (preferably having 2 to 18 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an alkylaminosulfonyl group (preferably having 1 to 15 carbon atoms), and an aryloxysulfonyl group (preferably having 6 to 20 carbon atoms).

The alkyl group in the bis(alkylsulfonyl)imide anion and the tris(alkylsulfonyl)methide anion is preferably an alkyl group having 1 to 5 carbon atoms. Examples of the substituent of such an alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group, and a fluorine atom or an alkyl group substituted with the fluorine atom is preferable.

In addition, the alkyl groups in the bis(alkylsulfonyl)imide anion may be bonded to each other to form a ring structure. Thus, the acid strength increases.

As the non-nucleophilic anion, an aliphatic sulfonate anion in which at least α-position of sulfonic acid is substituted with a fluorine atom, an aromatic sulfonate anion substituted with a fluorine atom or a group having a fluorine atom, a bis(alkylsulfonyl)imide anion in which an alkyl group is substituted with a fluorine atom, or a tris(alkylsulfonyl)methide anion in which an alkyl group is substituted with a fluorine atom is preferable.

Such another photoacid generator may be a zwitterion. Such another photoacid generator which is a zwitterion ion preferably has a sulfonate anion (preferably an aromatic sulfonic acid), and more preferably has a sulfonium cation or an iodine cation.

As such another photoacid generator, the photoacid generators disclosed in paragraphs [0135] to [0171] of WO2018/193954A, paragraphs [0077] to [0116] of WO2020/066824A, and paragraphs [0018] to [0075] and [0334] to [0335] of WO2017/154345A, and the like are preferably used.

Such another photoacid generator may be used alone or in combination of two or more kinds thereof.

The content of the photoacid generator is preferably 2.0% by mass or more, more preferably 5.0% by mass or more, and still more preferably 10.0% by mass or more with respect to the total solid content of the composition. In addition, an upper limit value thereof is not particularly limited, but is preferably 40.0% by mass or less, more preferably 30.0% by mass or less, and still more preferably 25.0% by mass or less.

The photoacid generators may be used alone or in combination of two or more kinds thereof. In a case where two or more kinds of such other photoacid generators are used, a total content thereof is preferably within the suitable content range.

[Acid Diffusion Control Agent]

The resist composition may include an acid diffusion control agent as a component different from the above-mentioned components.

The acid diffusion control agent acts as a quencher that suppresses a reaction of an acid-decomposable resin in the unexposed portion by excessive generated acids by trapping the acids generated from a photoacid generator and the like upon exposure. For example, a basic compound (CA), a basic compound (CB) of which basicity is reduced or lost upon irradiation with actinic rays or radiation, a low-molecular-weight compound (CD) having a nitrogen atom and a group that leaves by the action of an acid, and an onium salt compound (CE) having a nitrogen atom in the cationic moiety, can be used as the acid diffusion control agent.

In addition, as the acid diffusion control agent, an onium salt which serves as a weak acid relative to the photoacid generating component can also be used.

In a case where the photoacid generator (the specific photoacid generator and other photoacid generators are collectively also referred to as a photoacid generating component) and the onium salt that generates an acid which is a weak acid relative to an acid generated from the photoacid generating component are used in combination, an acid generated from the photoacid generating component upon irradiation with actinic rays or radiation produces an onium salt having a strong acid anion by discharging the weak acid through salt exchange in a case where the acid collides with an onium salt having an unreacted weak acid anion. In this process, the strong acid is exchanged with a weak acid having a lower catalytic ability, and thus, the acid is apparently deactivated and the acid diffusion can be controlled.

As the onium salt which serves as a relatively weak acid with respect to the photoacid generating component, compounds represented by Formulae (d1-1) to (d1-3) are preferable.

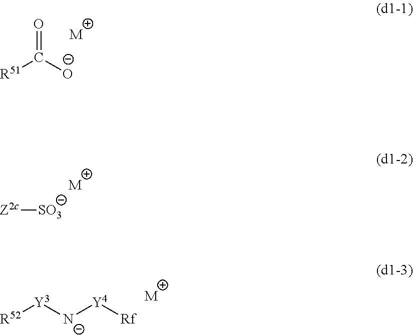

In the formula, R⁵¹ is an organic group. R⁵¹ preferably has 1 to 30 carbon atoms.

Z^{2c} is an organic group. The organic group preferably has 1 to 30 carbon atoms. It should be noted that in a case where the organic group represented by Z^{2c} has a carbon atom adjacent to SO₃⁻ specified in the formula, this carbon atom (α-carbon atom) does not have a fluorine atom and/or a perfluoroalkyl group as a substituent. The α-carbon atom is other than a ring member atom having a cyclic structure, and is preferably a methylene group. In addition, in Z^{2c}, in a case where the β-position atom with respect to SO₃⁻ is a carbon atom (β-carbon atom), the β-carbon atom also does not have a fluorine atom and/or a perfluoroalkyl group as a substituent.

R⁵² is an organic group (an alkyl group and the like), Y³ is —SO₂—, a linear, branched, or cyclic alkylene group, or an arylene group, Y⁴ is —CO— or —SO₂—, and Rf is a hydrocarbon group having a fluorine atom (a fluoroalkyl group and the like).

M⁺'s are each independently an ammonium cation, a sulfonium cation, or an iodonium cation. These cations may have an acid-decomposable group. As M⁺ in Formulae (d1-1) to (d1-3), the cations mentioned in the description of the specific photoacid generators and another photoacid generator may be used.

As the acid diffusion control agent, a zwitterion may be used. The acid diffusion control agent which is a zwitterion preferably has a carboxylate anion, and more preferably has a sulfonium cation or an iodonium cation.

In the resist composition of the embodiment of the present invention, a known acid diffusion control agent can be appropriately used. For example, the known compounds disclosed in paragraphs [0627] to [0664] of the specification of US2016/0070167A1, paragraphs [0095] to [0187] of the specification of US2015/0004544A1, paragraphs [0403] to [0423] of the specification of US2016/0237190A1, and paragraphs [0259] to [0328] of the specification of US2016/0274458A1 can be suitably used as the acid diffusion control agent.

In addition, for example, specific examples of the basic compound (CA) include those described in paragraphs [0132] to [0136] of WO2020/066824A, specific examples of the basic compound (CB) of which basicity is reduced or lost upon irradiation with actinic rays or radiation include those described in paragraphs [0137] to [0155] of WO2020/066824A, specific examples of the low-molecular-weight compound (CD) having a nitrogen atom and a group that leaves by the action of an acid include those described in paragraphs [0156] to [0163] of WO2020/066824A, and specific examples of the onium salt compound (CE) having a nitrogen atom in the cationic moiety include those described in paragraph [0164] of WO2020/066824A.

In a case where the resist composition includes an acid diffusion control agent, the content of the acid diffusion control agent is preferably 0.1% to 20.0% by mass, more preferably 0.1% to 10.0% by mass, and still more preferably 0.1% to 8.0% by mass with respect to the total solid content of the composition.

The acid diffusion control agents may be used alone or in combination of two or more kinds thereof. In a case where two or more kinds of such other photoacid generators are used, a total content thereof is preferably within the suitable content range.

[Hydrophobic Resin]

The resist composition may include a hydrophobic resin different from the resin (A), in addition to the resin (A).

Although it is preferable that the hydrophobic resin is designed to be unevenly distributed on a surface of the resist film, it does not necessarily need to have a hydrophilic group in the molecule as different from the surfactant, and does not need to contribute to uniform mixing of polar materials and non-polar materials.

Examples of the effect caused by the addition of the hydrophobic resin include a control of static and dynamic contact angles of a surface of the resist film with respect to water and suppression of out gas.

The hydrophobic resin preferably has any one or more of a “fluorine atom”, a “silicon atom”, and a “CH₃ partial structure which is contained in a side chain moiety of a resin” from the viewpoint of uneven distribution on the film surface layer, and more preferably has two or more kinds thereof. In addition, the hydrophobic resin preferably has a hydrocarbon group having 5 or more carbon atoms. These groups may be contained in the main chain of the resin or may be substituted in a side chain.

Examples of the hydrophobic resin include the compounds described in paragraphs [0318] to [0279] of WO2020/004306A.

In a case where the resist composition includes a hydrophobic resin, the content of the hydrophobic resin is preferably 0.01% to 20% by mass, more preferably 0.1% to 15% by mass, still more preferably 0.1% to 10% by mass, and particularly preferably 0.1% to 7.0% by mass with respect to the total solid content of the resist composition.

The hydrophobic resins may be used alone or in combination of two or more kinds thereof. In a case where two or more kinds of such other photoacid generators are used, a total content thereof is preferably within the suitable content range.

[Surfactant]

The resist composition may include a surfactant. In a case where the surfactant is included, it is possible to form a pattern having more excellent adhesiveness and fewer development defects.

The surfactant is preferably a fluorine-based and/or silicon-based surfactant.

As the fluorine-based and/or silicon-based surfactant, for example, the surfactants disclosed in paragraphs [0218] and [0219] of WO2018/19395A can be used.

In a case where the resist composition includes a surfactant, the content of the surfactant is preferably 0.0001% to 2% by mass, and more preferably 0.0005% to 1% by mass with respect to the total solid content of the composition.

The surfactants may be used alone or in combination of two or more kinds thereof. In a case where two or more kinds of such other photoacid generators are used, a total content thereof is preferably within the suitable content range.

[Solvent]

The resist composition may include a solvent.

The solvent preferably includes at least one solvent of (M1) propylene glycol monoalkyl ether carboxylate, or (M2) at least one selected from the group consisting of a propylene glycol monoalkyl ether, a lactic acid ester, an acetic acid ester, an alkoxypropionic acid ester, a chain ketone, a cyclic ketone, a lactone, and an alkylene carbonate as a solvent. Furthermore, this solvent may further include components other than the components (M1) and (M2).

The present inventors have found that by using such a solvent and the above-mentioned resin in combination, a pattern having a small number of development defects can be formed while improving the coating property of the composition. A reason thereof is not necessarily clear, but the present inventors have considered that since these solvents have a good balance among the solubility, the boiling point, and the viscosity of the resin, the unevenness of the film thickness of a composition film, the generation of precipitates during spin coating, and the like can be suppressed.

Details of the component (M1) and the component (M2) are described in paragraphs [0218] to [0226] of WO2020/004306A.

In a case where the solvent further includes a component other than the components (M1) and (M2), the content of the component other than the components (M1) and (M2) is preferably 5% to 30% by mass with respect to the total amount of the solvent.

The content of the solvent in the resist composition is preferably set such that the concentration of solid contents is 0.5% to 30% by mass, and more preferably set such that the concentration of solid contents is 1% to 20% by mass. With this content, the coating property of the resist composition can be further improved.

In other words, the content of the solvent in the resist composition is preferably 70% to 99.5% by mass, and more preferably 80% to 99% by mass with respect to the total mass of the composition.

The solvents may be used alone or in combination of two or more kinds thereof. In a case where two or more kinds of such other photoacid generators are used, a total content thereof is preferably within the suitable content range.

[Other Additives]

The resist composition may further include a dissolution inhibiting compound, a dye, a plasticizer, a photosensitizer, a light absorber, and/or a compound accelerating a solubility in a developer (for example, a phenol compound having a molecular weight of 1,000 or less or an alicyclic or aliphatic compound including a carboxylic acid group), or the like.

The resist composition may further include a dissolution inhibiting compound. Here, the “dissolution inhibiting compound” is intended to be a compound having a molecular weight of 3,000 or less, having a solubility in an organic developer decreases by decomposition by the action of an acid.

The resist composition of the embodiment of the present invention is also suitably used as a photosensitive composition for EUV exposure.

EUV light has a wavelength of 13.5 nm, which is a shorter wavelength than that of ArF (wavelength of 193 nm) light or the like, and therefore, the EUV light has a smaller number of incidence photons upon exposure with the same sensitivity. Thus, an effect of “photon shot noise” that the number of photons is statistically non-uniform is significant, and a deterioration in LER and a bridge defect are caused. In order to reduce the photon shot noise, a method in which an exposure amount increases to cause an increase in the number of incidence photons is available, but the method is a trade-off with a demand for a higher sensitivity.

In a case where the A value obtained by Formula (1) is high, the absorption efficiency of EUV light and electron beam of the resist film formed from the resist composition is higher, which is effective in reducing the photon shot noise. The A value represents the absorption efficiency of EUV light and electron beams of the resist film in terms of a mass proportion.

A=([H]×0.04+[C]×1.0⁺[N]×2.1+[O]×3.6+[F]×5.6+[S]×1.5+[I]×39.5)/([H]×1+[C]×12+[N]×14+[O]×16+[F]×19+[S]×32+[I]×127) Formula (1):

The A value is preferably 0.120 or more. The upper limit is not particularly limited, but in a case where the A value is extremely high, the transmittance of EUV light and electron beams of the resist film is lowered and the optical image profile in the resist film is deteriorated, which results in difficulty in obtaining a good pattern shape, and therefore, the upper limit is preferably 0.240 or less, and more preferably 0.220 or less.

Moreover, in Formula (1), [H] represents a molar ratio of hydrogen atoms derived from the total solid content with respect to all the atoms of the total solid content in the actinic ray-sensitive or radiation-sensitive resin composition, [C] represents a molar ratio of carbon atoms derived from the total solid content with respect to all the atoms of the total solid content in the actinic ray-sensitive or radiation-sensitive resin composition, [N] represents a molar ratio of nitrogen atoms derived from the total solid content with respect to all the atoms of the total solid content in the actinic ray-sensitive or radiation-sensitive resin composition, [O] represents a molar ratio of oxygen atoms derived from the total solid content with respect to all the atoms of the total solid content in the actinic ray-sensitive or radiation-sensitive resin composition, [F] represents a molar ratio of fluorine atoms derived from the total solid content with respect to all the atoms of the total solid content in the actinic ray-sensitive or radiation-sensitive resin composition, [S] represents a molar ratio of sulfur atoms derived from the total solid content with respect to all the atoms of the total solid content in the actinic ray-sensitive or radiation-sensitive resin composition, and [I] represents a molar ratio of iodine atoms derived from the total solid content with respect to all the atoms of the total solid content in the actinic ray-sensitive or radiation-sensitive resin composition.

For example, in a case where the resist composition includes a resin (acid-decomposable resin) of which polarity increases by the action of an acid, a photoacid generator, an acid diffusion control agent, and a solvent, the resin, the photoacid generator, and the acid diffusion control agent correspond to the solid content. That is, all the atoms of the total solid content correspond to a sum of all the atoms derived from the resin, all the atoms derived from the photoacid generator, and all the atoms derived from the acid diffusion control agent. For example, [H] represents a molar ratio of hydrogen atoms derived from the total solid content with respect to all the atoms in the total solid content, and by way of description based on the example above, [H] represents a molar ratio of a sum of the hydrogen atoms derived from the resin, the hydrogen atoms derived from the photoacid generator, and the hydrogen atoms derived from the acid diffusion control agent with respect to a sum of all the atoms derived from the resin, all the atoms derived from the photoacid generator, and all the atoms derived from the acid diffusion control agent.

The A value can be calculated by computation of the structure of constituent components of the total solid content in the resist composition, and the atomic number ratio contained in a case where the content is already known. In addition, even in a case where the constituent component is not known yet, it is possible to calculate a constituent atomic number ratio by subjecting a resist film obtained after evaporating the solvent components of the resist composition to computation according to an analytic approach such as elemental analysis.

[Resist Film and Pattern Forming Method]

The procedure of the pattern forming method using the resist composition is not particularly limited, but preferably has the following steps.

Step 1: A step of forming a resist film on a substrate, using a resist composition

Step 2: A step of exposing the resist film

Step 3: A step of developing the exposed resist film using a developer

Hereinafter, the procedure of each of the steps will be described in detail.

<Step 1: Resist Film Forming Step>

The step 1 is a step of forming a resist film on a substrate, using a resist composition.

The definition of the resist composition is as described above.

Examples of a method in which a resist film is formed on a substrate, using a resist composition include a method in which a resist composition is applied onto a substrate.

Incidentally, it is preferable that the resist composition before the application is filtered through a filter, as necessary. A pore size of the filter is preferably 0.1 μm or less, more preferably 0.05 μm or less, and still more preferably 0.03 μm or less. In addition, the filter is preferably a polytetrafluoroethylene-, polyethylene-, or nylon-made filter.

The resist composition can be applied onto a substrate (for example, silicon and silicon dioxide coating) as used in the manufacture of integrated circuit elements by a suitable application method such as ones using a spinner or a coater. The application method is preferably spin application using a spinner. A rotation speed upon the spin application using a spinner is preferably 1,000 to 3,000 rpm.

After the application of the resist composition, the substrate may be dried to form a resist film. In addition, various underlying films (an inorganic film, an organic film, or an antireflection film) may be formed on the underlayer of the resist film, as necessary.

Examples of the drying method include a method of heating and drying. The heating can be carried out using a unit included in an ordinary exposure machine and/or an ordinary development machine, and may also be carried out using a hot plate or the like. A heating temperature is preferably 80° C. to 150° C., more preferably 80° C. to 140° C., and still more preferably 80° C. to 130° C. A heating time is preferably 30 to 1,000 seconds, more preferably 60 to 800 seconds, and still more preferably 60 to 600 seconds.

A film thickness of the resist film is not particularly limited, but is preferably 10 to 120 nm from the viewpoint that a fine pattern having higher accuracy can be formed. Among those, in a case of performing EUV exposure or EB exposure, the film thickness of the resist film is more preferably 10 to 100 nm, and still more preferably 15 to 70 nm. In addition, in a case of performing ArF liquid immersion exposure, the film thickness of the resist film is more preferably 10 to 120 nm, and still more preferably 15 to 90 nm.

Moreover, a topcoat may be formed on the upper layer of the resist film, using the topcoat composition.

It is preferable that the topcoat composition is not mixed with the resist film and can be uniformly applied onto the upper layer of the resist film. The topcoat is not particularly limited, a topcoat known in the related art can be formed by the methods known in the related art, and the topcoat can be formed, based on the description in paragraphs [0072] to [0082] of JP2014-059543A, for example.

It is preferable that a topcoat including a basic compound as described in JP2013-061648A, for example, is formed on a resist film. Specific examples of the basic compound which can be included in the topcoat include a basic compound which may be included in the resist composition.

In addition, it is also preferable that the topcoat includes a compound which includes at least one group or bond selected from the group consisting of an ether bond, a thioether bond, a hydroxyl group, a thiol group, a carbonyl bond, and an ester bond.

<Step 2: Exposing Step>

The step 2 is a step of exposing the resist film.

Examples of the exposing method include a method of irradiating the resist film formed with actinic rays or radiation through a predetermined mask.

Examples of the actinic rays or radiation include infrared light, visible light, ultraviolet light, far ultraviolet light, extreme ultraviolet light, X-rays, and electron beams, preferably a far ultraviolet light having a wavelength of 250 nm or less, more preferably a far ultraviolet light having a wavelength of 220 nm or less, and particularly preferably a far ultraviolet light having a wavelength of 1 to 200 nm, specifically, KrF excimer laser (248 nm), ArF excimer laser (193 nm), F2 excimer laser (157 nm), EUV (13 nm), X-rays, and electron beams.

It is preferable to perform baking (heating) before performing development after the exposure. The baking accelerates a reaction in the exposed portion, and the sensitivity and the pattern shape are improved.

A heating temperature is preferably 60° C. to 150° C., more preferably 70° C. to 140° C., and still more preferably 80° C. to 130° C.

A heating time is preferably 10 to 1,000 seconds, more preferably 10 to 180 seconds, and still more preferably 30 to 120 seconds.

The heating can be carried out using a unit included in an ordinary exposure machine and/or an ordinary development machine, and may also be performed using a hot plate or the like.

This step is also referred to as a post-exposure baking.

<Step 3: Developing Step>

The step 3 is a step of developing the exposed resist film using a developer to form a pattern.

The developer may be either an alkali developer or a developer including an organic solvent (hereinafter also referred to as an organic developer).

Examples of the developing method include a method in which a substrate is immersed in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously jetted onto a substrate rotating at a constant rate while scanning a developer jetting nozzle at a constant rate (a dynamic dispense method).

In addition, after the step of performing development, a step of stopping the development may be carried out while substituting the solvent with another solvent.

A developing time is not particularly limited as long as it is a period of time where the unexposed portion of a resin is sufficiently dissolved, and is preferably 10 to 300 seconds, and more preferably 20 to 120 seconds.

The temperature of the developer is preferably 0° C. to 50° C., and more preferably 15° C. to 35° C.

As the alkali developer, it is preferable to use an aqueous alkali solution including an alkali. The type of the aqueous alkali solution is not particularly limited, but examples thereof include an aqueous alkali solution including a quaternary ammonium salt typified by tetramethylammonium hydroxide, an inorganic alkali, a primary amine, a secondary amine, a tertiary amine, an alcoholamine, a cyclic amine, or the like. Among those, the aqueous solutions of the quaternary ammonium salts typified by tetramethylammonium hydroxide (TMAH) are preferable as the alkali developer. An appropriate amount of an alcohol, a surfactant, or the like may be added to the alkali developer. The alkali concentration of the alkali developer is usually 0.1% to 20% by mass. Furthermore, the pH of the alkali developer is usually 10.0 to 15.0.

The organic developer is preferably a developer containing at least one organic solvent selected from the group consisting of a ketone-based solvent, an ester-based solvent, an alcohol-based solvent, an amide-based solvent, an ether-based solvent, and a hydrocarbon-based solvent.

A plurality of the solvents may be mixed or the solvent may be used in admixture with a solvent other than those described above or water. The moisture content in the entire developer is preferably less than 50% by mass, more preferably less than 20% by mass, and still more preferably less than 10% by mass, and particularly preferably moisture is not substantially contained.

The content of the organic solvent with respect to the organic developer is preferably from 50% by mass to 100% by mass, more preferably from 80% by mass to 100% by mass, still more preferably from 90% by mass to 100% by mass, and particularly preferably from 95% by mass to 100% by mass with respect to the total amount of the developer.

<Other Steps>

It is preferable that the pattern forming method includes a step of performing cleaning using a rinsing liquid after the step 3.

Examples of the rinsing liquid used in the rinsing step after the step of performing development using an alkali developer include pure water. Furthermore, an appropriate amount of a surfactant may be added to pure water.

An appropriate amount of a surfactant may be added to the rinsing liquid.

The rinsing liquid used in the rinsing step after the developing step with an organic developer is not particularly limited as long as the rinsing liquid does not dissolve the pattern, and a solution including a common organic solvent can be used. As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferably used.

A method for the rinsing step is not particularly limited, but examples thereof include a method in which a rinsing liquid is continuously jetted on a substrate rotated at a constant rate (a rotation application method), a method in which a substrate is dipped in a tank filled with a rinsing liquid for a certain period of time (a dip method), and a method in which a rinsing liquid is sprayed on a substrate surface (a spray method).

Furthermore, the pattern forming method of the embodiment of the present invention may include a heating step (post bake) after the rinsing step. By the present step, the developer and the rinsing liquid remaining between and inside the patterns are removed by baking. In addition, the present step also has an effect that a resist pattern is annealed and the surface roughness of the pattern is improved. The heating step after the rinsing step is usually performed at 40° C. to 250° C. (preferably 90° C. to 200° C.) for usually 10 seconds to 3 minutes (preferably 30 seconds to 120 seconds).

In addition, an etching treatment on the substrate may be carried out using a pattern thus formed as a mask. That is, the substrate (or the underlayer film and the substrate) may be processed using the pattern thus formed in the step 3 as a mask to form a pattern on the substrate.

A method for processing the substrate (or the underlayer film and the substrate) is not particularly limited, but a method in which a pattern is formed on a substrate by subjecting the substrate (or the underlayer film and the substrate) to dry etching using the pattern thus formed in the step 3 as a mask is preferable. Oxygen plasma etching is preferable as the dry etching.

It is preferable that various materials (for example, a solvent, a developer, a rinsing liquid, a composition for forming an antireflection film, and a composition for forming a topcoat) used in the resist composition and the pattern forming method of the embodiment of the present invention do not include impurities such as metals. The content of the impurities included in these materials is preferably 1 ppm by mass or less, more preferably 10 ppb by mass or less, still more preferably 100 ppt by mass or less, particularly preferably 10 ppt by mass or less, and most preferably 1 ppt by mass or less. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing impurities such as metals from the various materials include filtration using a filter. Details of filtration using a filter are described in paragraph [0321] of WO2020/004306A.

In addition, examples of a method for reducing impurities such as metals included in various materials include a method of selecting raw materials having a low content of metals as raw materials constituting various materials, a method of subjecting raw materials constituting various materials to filter filtration, and a method of performing distillation under the condition for suppressing the contamination as much as possible by, for example, lining the inside of a device with TEFLON (registered trademark).

In addition to the filter filtration, removal of impurities by an adsorbing material may be performed, or a combination of filter filtration and an adsorbing material may be used. As the adsorbing material, known adsorbing materials may be used, and for example, inorganic adsorbing materials such as silica gel and zeolite, and organic adsorbing materials such as activated carbon can be used. It is necessary to prevent the incorporation of impurities such as metals in the production process in order to reduce the metal impurities included in the various materials. Sufficient removal of metal impurities from a production device can be confirmed by measuring a content of metal components included in a cleaning liquid used to clean the production device. The content of the metal components included in the cleaning liquid after the use is preferably 100 parts per trillion (ppt) by mass or less, more preferably 10 ppt by mass or less, and still more preferably 1 ppt by mass or less.

A conductive compound may be added to an organic treatment liquid such as a rinsing liquid in order to prevent breakdown of chemical liquid pipes and various parts (a filter, an O-ring, a tube, and the like) due to electrostatic charging, and subsequently generated electrostatic discharging. The conductive compound is not particularly limited, but examples thereof include methanol. The addition amount is not particularly limited, but from the viewpoint that preferred development characteristics or rinsing characteristics are maintained, the addition amount is preferably 10% by mass or less, and more preferably 5% by mass or less.

For the chemical liquid pipe, for example, various pipes coated with stainless steel (SUS), or a polyethylene, polypropylene, or fluororesin (a polytetrafluoroethylene or perfluoroalkoxy resin, and the like) that has been subjected to an antistatic treatment can be used. In the same manner, for the filter or the O-ring, polyethylene, polypropylene, or a fluororesin (a polytetrafluoroethylene or perfluoroalkoxy resin, and the like) that has been subjected to an antistatic treatment can be used.

[Method for Manufacturing Electronic Device]

Moreover, the present invention further relates to a method for manufacturing an electronic device, including the pattern forming method, and an electronic device manufactured by the manufacturing method.

The electronic device of an embodiment of the present invention is suitably mounted on electric and electronic equipment (for example, home appliances, office automation (OA)-related equipment, media-related equipment, optical equipment, telecommunication equipment, and the like).

### EXAMPLES

Hereinafter, the present invention will be described in more detail with reference to Examples. The materials, the amounts of materials used, the proportions, the treatment details, the treatment procedure, and the like shown in Examples below may be appropriately modified as long as the modifications do not depart from the spirit of the present invention. Therefore, the scope of the present invention should not be construed as being limited to Examples shown below.

[Various Components of Actinic Ray-Sensitive or Radiation-Sensitive Resin Composition]

[Acid-Decomposable Resin]

The resins (A) shown in Table 2 (resins A-1 to A-55 and RA-1 to RA-4) are shown in Table 1.

Furthermore, as the resins A-1 to A-55 and RA-1 to RA-4, those synthesized in accordance with known methods were used. The compositional ratio (% by mass) of the respective repeating units shown below, the weight-average molecular weight (Mw), and the dispersity (Mw/Mn) are shown in Table 1.

Furthermore, the weight-average molecular weight (Mw) and the dispersity (Mw/Mn) of the resins A-1 to A-55 and RA-1 to RA-4 were measured by GPC (carrier: tetrahydrofuran (THF)) (an amount expressed in terms of polystyrene). In addition, the compositional ratio (% by mass) of the resin was measured by ¹³C-nuclear magnetic resonance (NMR).

TABLE 1

| | Repeating unit (A) | | Repeating unit (B) | | | | Repeating unit (C) | | Repeating unit (D) | | Weight- | |
|---|---|---|---|---|---|---|---|---|---|---|---|---|
| | | Content | | Content | | Content | | Content | | Content | average | |
| Table | | (% by | | (% by | | (% by | | (% by | | (% by | molecular | |
| 1-1 | Type | mass) | Type | mass) | Type | mass) | Type | mass) | Type | mass) | weight | Dispersity |
| A-1 | a1 | 50 | b7 | 30 | | | c1 | 20 | | | 9,000 | 1.8 |
| A-2 | a1 | 60 | b7 | 25 | | | c2 | 15 | | | 10,000 | 1.8 |
| A-3 | a1 | 50 | b1 | 20 | | | c2 | 30 | | | 11,000 | 1.8 |
| A-4 | a1 | 25 | b1 | 30 | | | c1 | 20 | d1 | 25 | 9,000 | 1.6 |
| A-5 | a1 | 30 | b5 | 10 | | | c4 | 30 | d5 | 30 | 10,000 | 1.7 |
| A-6 | a1 | 50 | b11 | 15 | b19 | 15 | c3 | 20 | | | 9,000 | 1.7 |
| A-7 | a11 | 60 | b7 | 20 | | | c1 | 20 | | | 10,000 | 1.7 |
| A-8 | a11 | 50 | b13 | 30 | | | c2 | 20 | | | 9,000 | 1.7 |
| A-9 | a21 | 50 | b11 | 30 | | | c2 | 20 | | | 9,000 | 1.7 |
| A-10 | a6 | 50 | b10 | 30 | | | c5 | 20 | | | 10,000 | 1.8 |
| A-11 | a5 | 50 | b4 | 15 | | | c2 | 35 | | | 9,000 | 1.6 |
| A-12 | a6 | 25 | | | b8 | 25 | c3 | 20 | d3 | 30 | 9,000 | 1.7 |
| A-13 | a4 | 60 | b7 | 10 | b18 | 10 | c1 | 20 | | | 11,000 | 1.9 |
| A-14 | a17 | 50 | b2 | 10 | b9 | 10 | c5 | 30 | | | 8,000 | 1.6 |
| A-15 | a30 | 20 | b3 | 30 | | | c1 | 20 | d9 | 30 | 9,000 | 1.7 |
| A-16 | a2 | 20 | b1 | 30 | | | c1 | 20 | d11 | 30 | 9,000 | 1.7 |
| A-17 | a14 | 25 | b5 | 25 | | | c5 | 20 | d12 | 30 | 10,000 | 1.7 |
| A-18 | a27 | 50 | b8 | 30 | | | c3 | 20 | | | 9,000 | 1.7 |
| A-19 | a29 | 60 | b12 | 20 | | | c4 | 20 | | | 11,000 | 1.7 |
| A-20 | a28 | 30 | b18 | 10 | | | c4 | 30 | d8 | 30 | 9,000 | 1.7 |
| A-21 | a23 | 25 | b19 | 15 | | | c2 | 30 | d2 | 30 | 9,000 | 1.7 |
| A-22 | a26 | 25 | b14 | 20 | | | c3 | 25 | d6 | 30 | 9,000 | 1.6 |
| A-23 | a13 | 25 | b9 | 15 | | | c5 | 30 | d7 | 30 | 9,000 | 1.7 |
| A-24 | a18 | 30 | b3 | 25 | | | c1 | 20 | d3 | 25 | 10,000 | 1.7 |
| A-25 | a7 | 20 | b11 | 35 | | | c1 | 15 | d5 | 30 | 9,000 | 1.7 |
| A-26 | a10 | 20 | b10 | 25 | | | c2 | 25 | d2 | 30 | 8,000 | 1.6 |
| A-27 | a10 | 30 | b16 | 15 | | | c4 | 35 | d8 | 20 | 9,000 | 1.8 |
| A-28 | a15 | 50 | b9 | 30 | | | c2 | 20 | | | 9,000 | 1.6 |
| A-29 | a18 | 60 | b7 | 20 | | | c1 | 20 | | | 9,000 | 1.7 |
| A-30 | a1 | 40 | b1 | 40 | | | c1 | 20 | | | 9,000 | 1.7 |
| A-31 | a1 | 65 | | | | | c1 | 35 | | | 9,000 | 1.7 |
| A-32 | a1 | 40 | b15 | 30 | | | c4 | 30 | | | 8,000 | 1.6 |
| A-33 | a1 | 40 | b4 | 30 | | | c1 | 30 | | | 7,000 | 1.6 |
| A-34 | a2 | 40 | b4 | 20 | b15 | 20 | c1 | 20 | | | 7,000 | 1.6 |
| A-35 | a15 | 30 | b2 | 30 | | | c2 | 30 | d11 | 10 | 8,000 | 1.6 |
| A-36 | a15 | 25 | b17 | 30 | | | c4 | 30 | d10 | 15 | 9,000 | 1.7 |
| A-37 | a16 | 30 | b16 | 40 | | | c5 | 30 | | | 9,000 | 1.7 |
| A-38 | a6 | 25 | b3 | 35 | | | c1 | 25 | d1 | 15 | 9,000 | 1.7 |
| A-39 | a3 | 20 | b5 | 35 | | | c3 | 20 | d3 | 25 | 8,000 | 1.6 |
| A-40 | a7 | 25 | b6 | 40 | | | c2 | 20 | d8 | 15 | 9,000 | 1.7 |
| A-41 | a9 | 20 | b11 | 35 | | | c5 | 25 | d9 | 20 | 10,000 | 1.7 |
| A-42 | a13 | 20 | b11 | 40 | | | c4 | 20 | d13 | 20 | 7,000 | 1.7 |
| A-43 | a17 | 20 | b13 | 35 | | | c1 | 20 | d4 | 25 | 7,000 | 1.6 |
| A-44 | a18 | 20 | b15 | 40 | | | c1 | 25 | d6 | 15 | 8,000 | 1.7 |
| A-45 | a20 | 25 | b16 | 30 | | | c5 | 30 | d2 | 15 | 9,000 | 1.8 |
| A-46 | a22 | 25 | b17 | 30 | | | c2 | 30 | d7 | 15 | 9,000 | 1.7 |

TABLE 2

| | Repeating unit (A) | | Repeating unit (B) | | | | Repeating unit (C) | | Repeating unit (D) | | Weight- | |
|---|---|---|---|---|---|---|---|---|---|---|---|---|
| | | Content | | Content | | Content | | Content | | Content | average | |
| Table | | (% by | | (% by | | (% by | | (% by | | (% by | molecular | |
| 1-2 | Type | mass) | Type | mass) | Type | mass) | Type | mass) | Type | mass) | weight | Dispersity |
| A-47 | a26 | 30 | b10 | 50 | | | c5 | 20 | | | 9,000 | 1.7 |
| A-48 | a28 | 30 | b9 | 50 | | | c4 | 20 | | | 9,000 | 1.7 |
| A-49 | a28 | 25 | b7 | 40 | | | c3 | 15 | d4 | 20 | 6,000 | 1.6 |
| A-50 | a30 | 25 | b4 | 35 | | | c1 | 20 | d2 | 20 | 8,000 | 1.7 |
| A-51 | a8 | 40 | b1 | 40 | | | c6 | 20 | | | 9,000 | 1.7 |
| A-52 | a12 | 35 | b2 | 45 | | | c6 | 20 | | | 9,000 | 1.7 |
| A-53 | a19 | 30 | b3 | 40 | | | c3 | 30 | | | 8,000 | 1.6 |
| A-54 | a24 | 45 | b9 | 25 | | | c2 | 30 | | | 7,000 | 1.6 |
| A-55 | a25 | 50 | b13 | 10 | | | c4 | 40 | | | 7,000 | 1.6 |
| RA-1 | ra1 | 50 | b3 | 25 | | | c1 | 25 | | | 9,000 | 1.7 |
| RA-2 | a5 | 50 | b12 | 50 | | | | | | | 9,000 | 1.7 |
| RA-3 | ra1 | 40 | b3 | 30 | | | c1 | 30 | | | 10,000 | 1.7 |
| RA-4 | a5 | 40 | b12 | 30 | b17 | 30 | | | | | 7,000 | 1.7 |

Various repeating units constituting the resins A-1 to A-55 and R^{A}-1 to R^{A}-4 shown in Table 1 are shown below.

Furthermore, in the resins A-1 to A-55, the repeating unit (A) corresponds to the above-mentioned repeating unit X1. In addition, the repeating unit (C) corresponds to the above-mentioned repeating unit X2.

Hereinafter, each repeating unit (repeating units al to a30 and repeating unit ra1) described in the repeating unit (A) column in Table 1 will be shown.

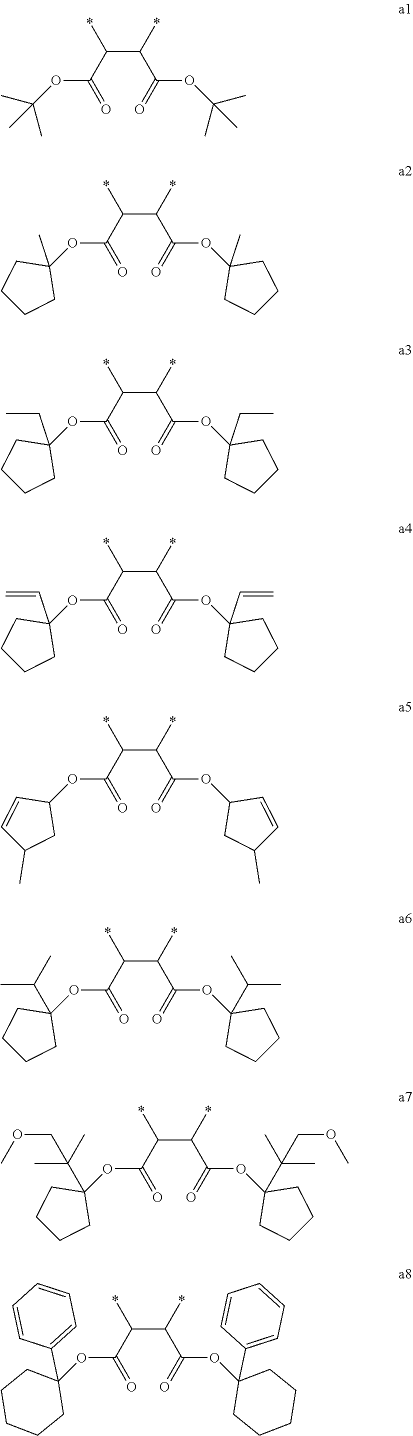

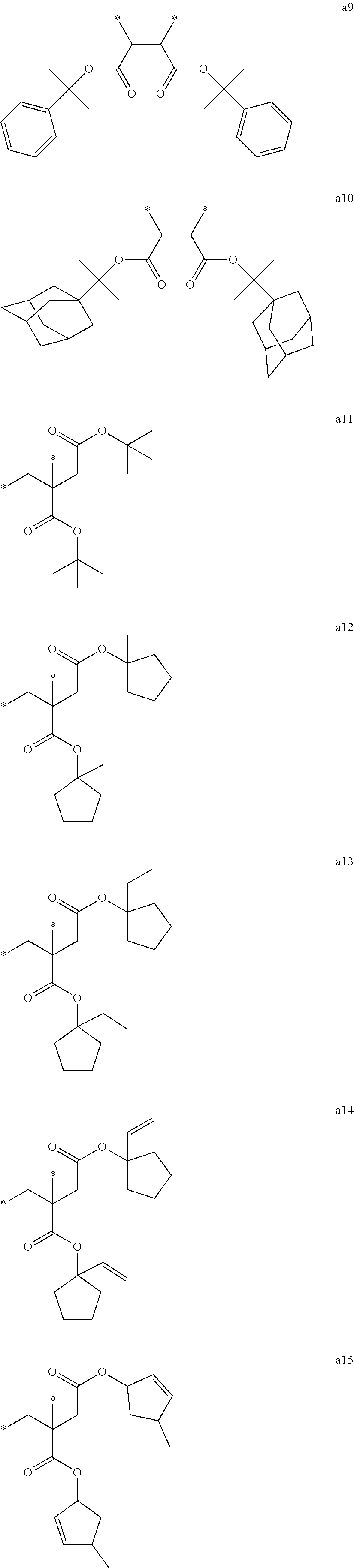

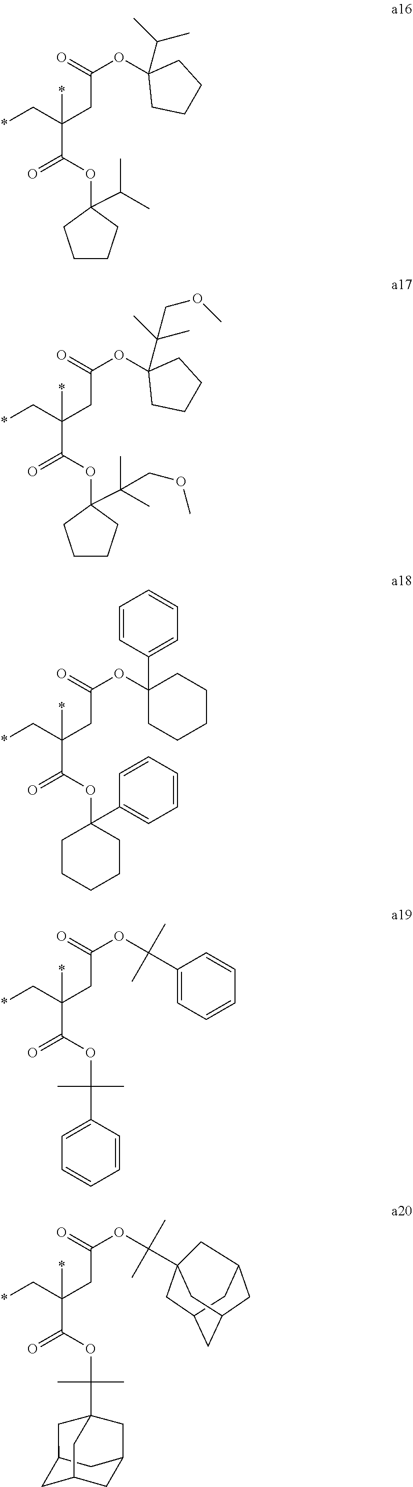

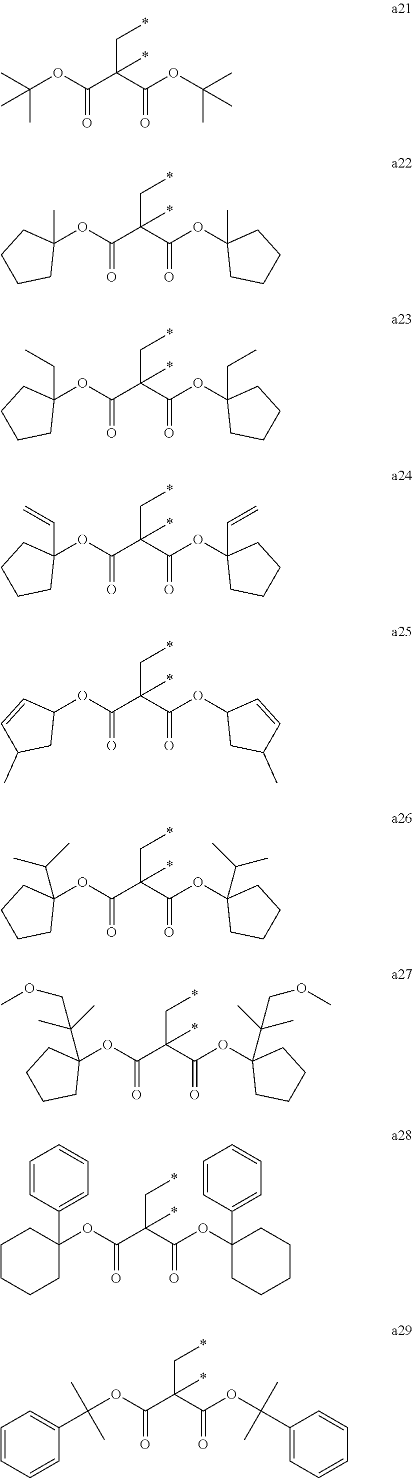

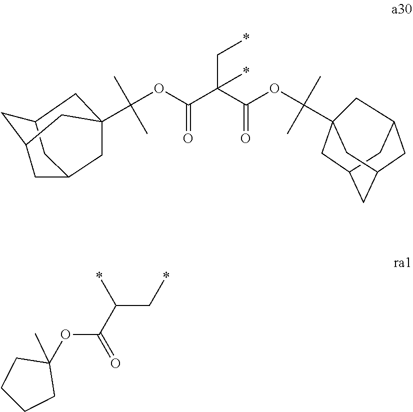

Hereinafter, each repeating unit (repeating units b1 to b19) described in the repeating unit (B) column in Table 1 will be shown.

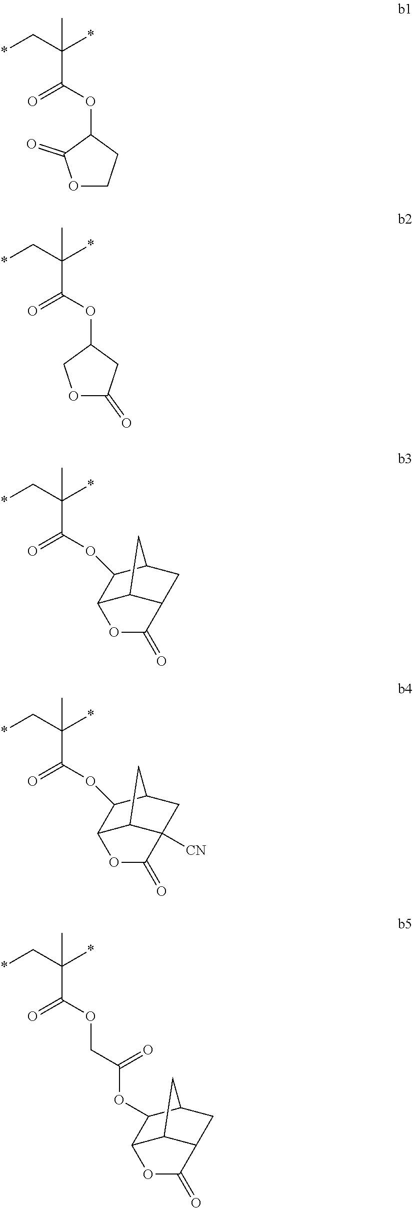

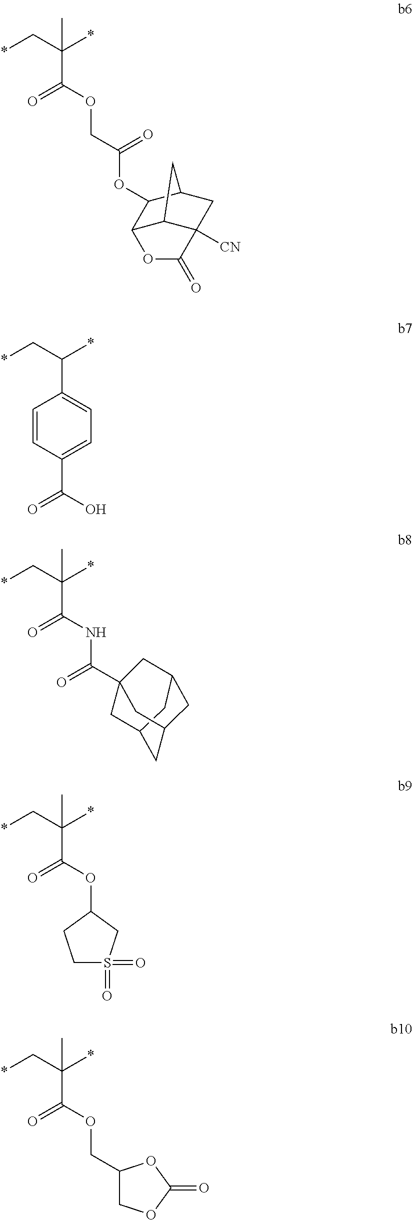

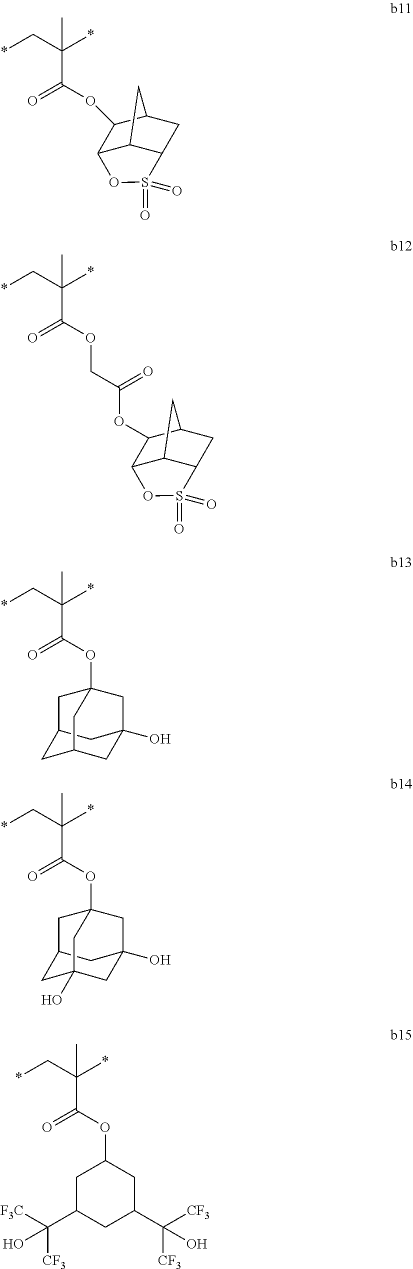

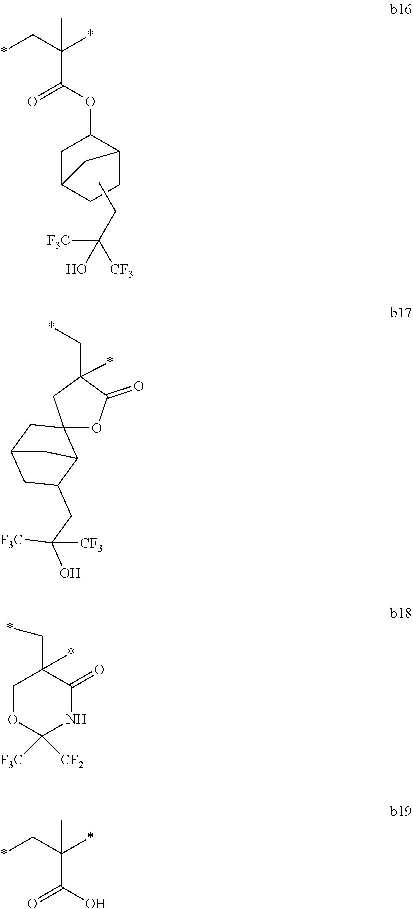

Hereinafter, each repeating unit (repeating units c1 to c6) described in the repeating unit (C) column in Table 1 is shown below.

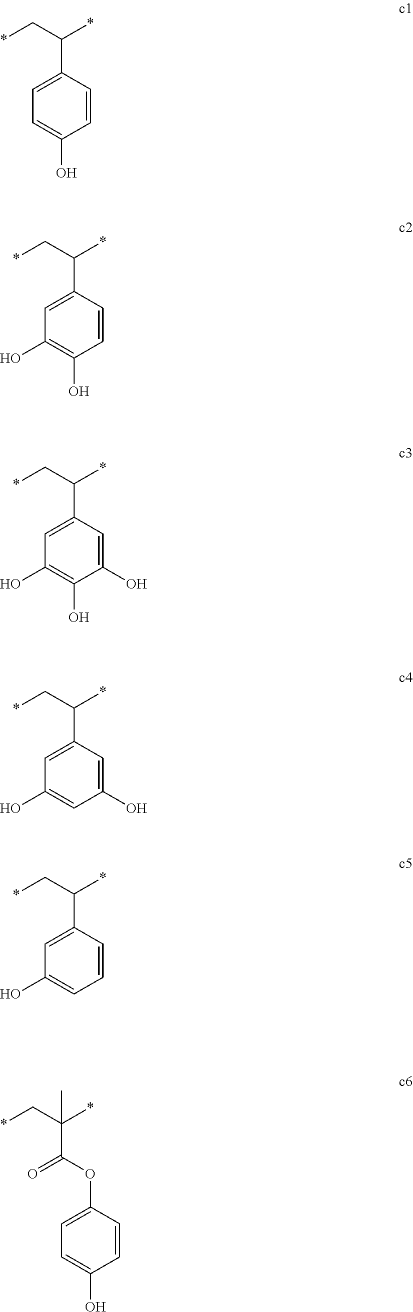

Hereinafter, each repeating unit (repeating units d1 to d13) described in the repeating unit (D) column in Table 1 is shown below.

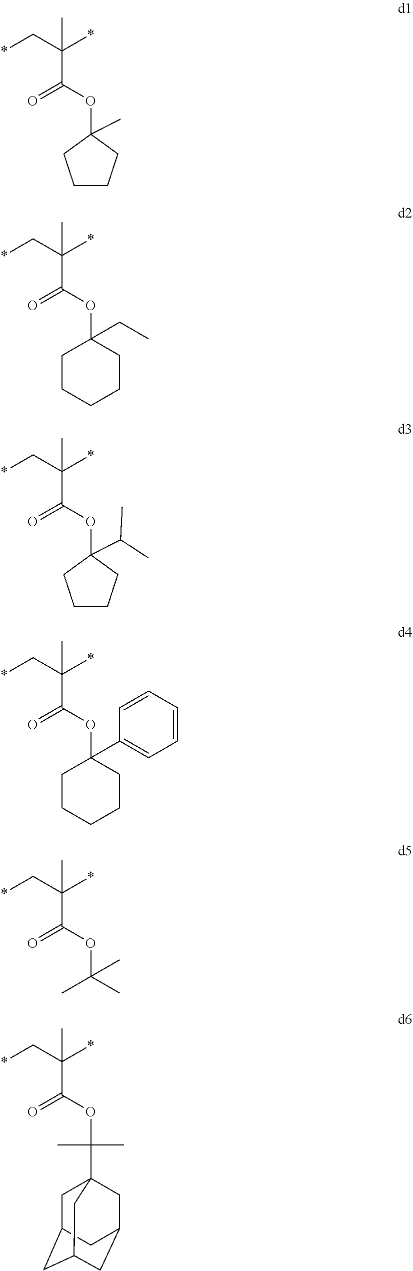

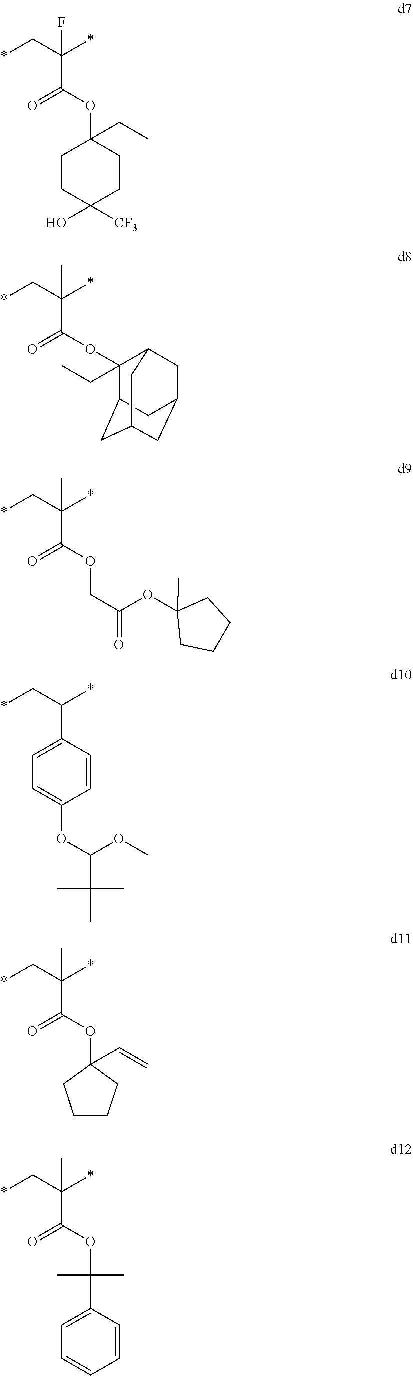

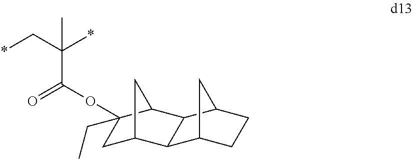

[Photoacid Generator]

The structures of photoacid generators (compounds B-1 to B-48) shown in Table 2 are shown below. Furthermore, among the following compounds, the compounds B-1 to B-29 correspond to any one of the compound (I) or the compound (II).

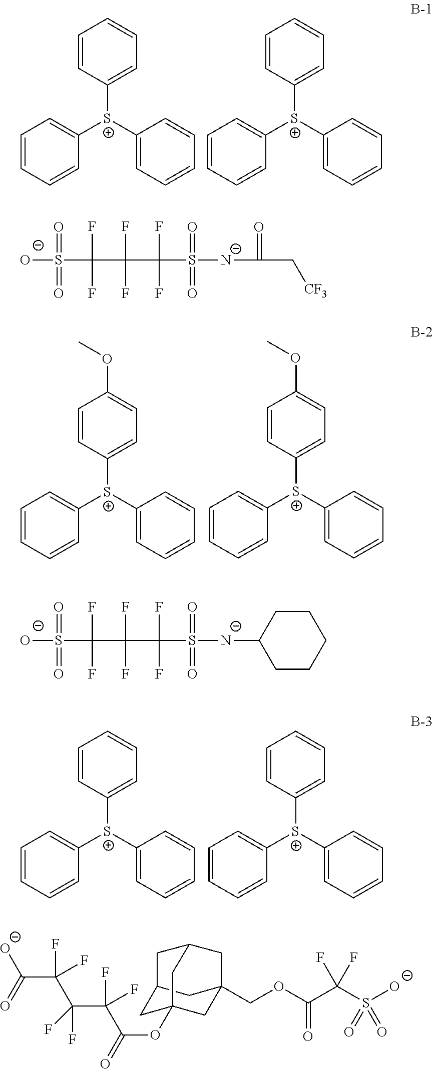

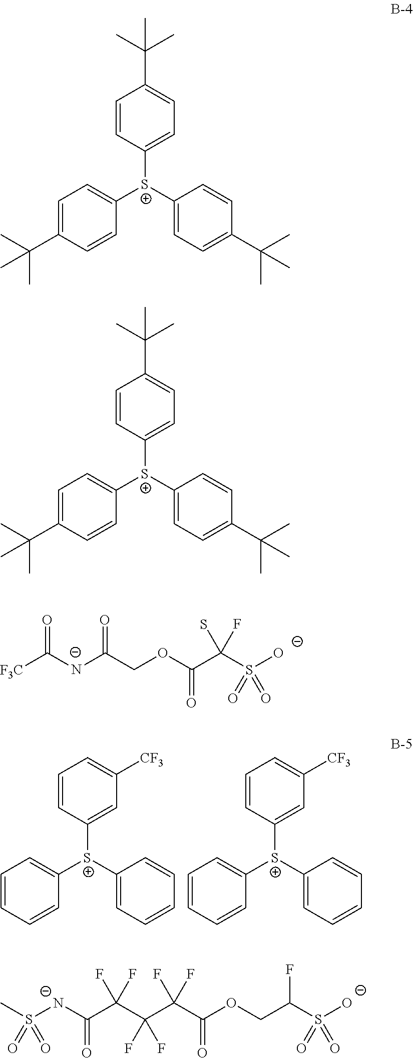

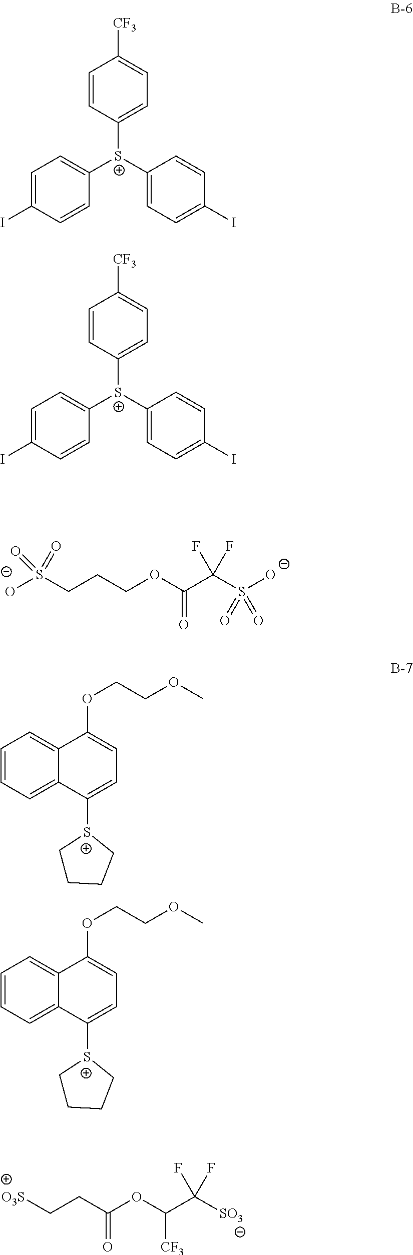

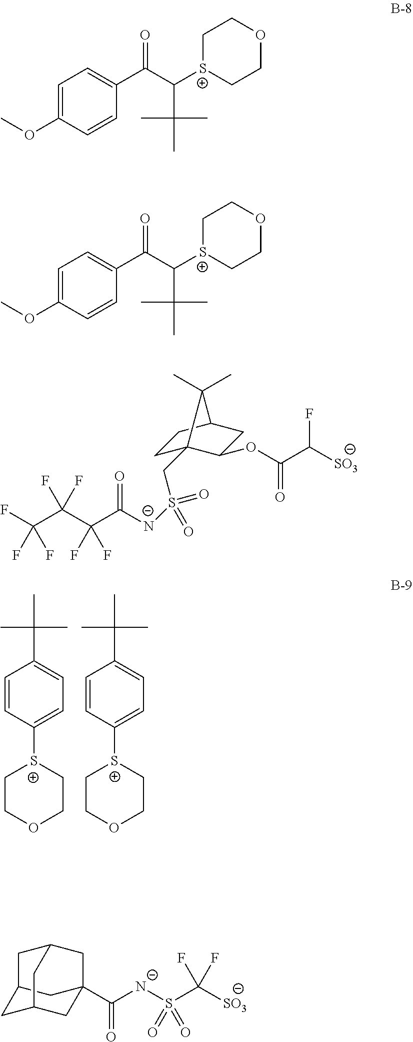

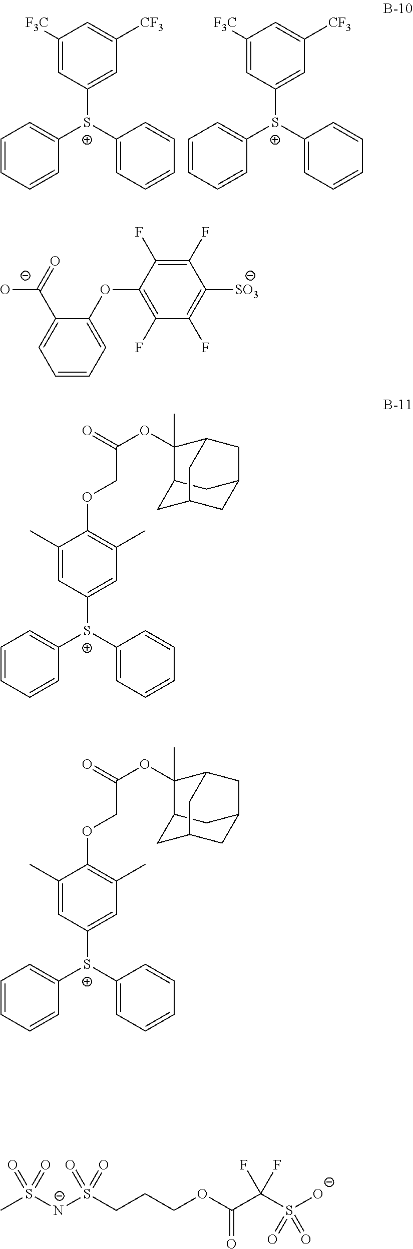

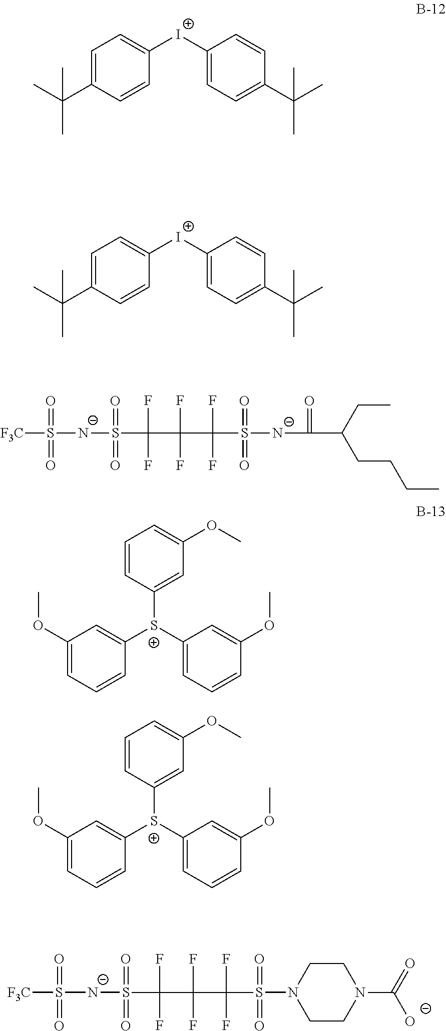

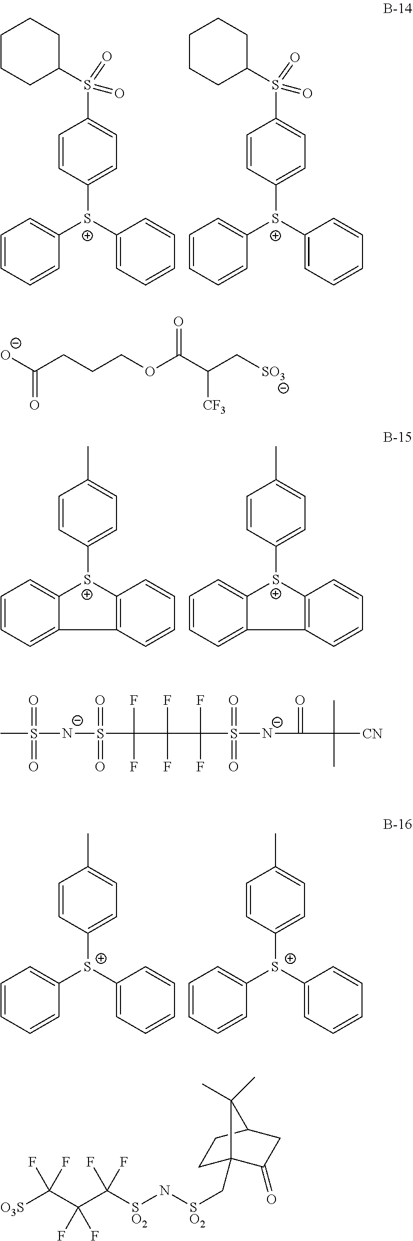

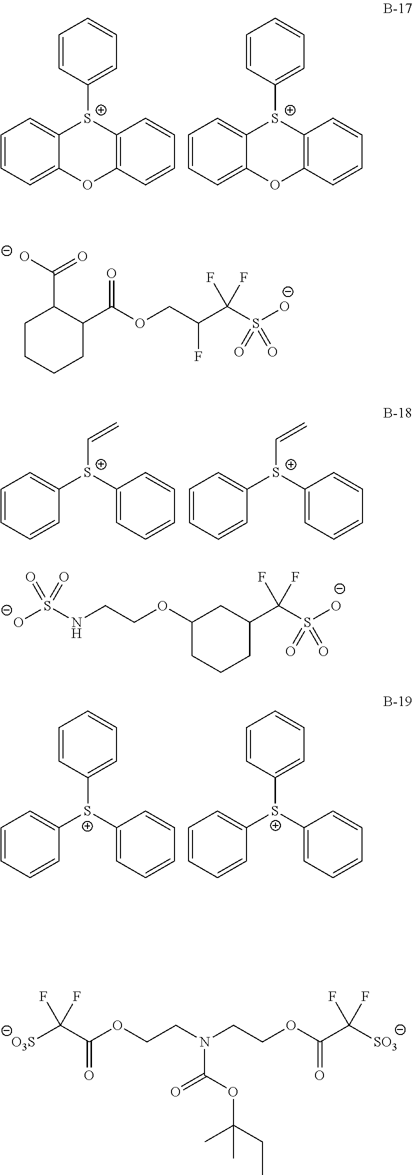

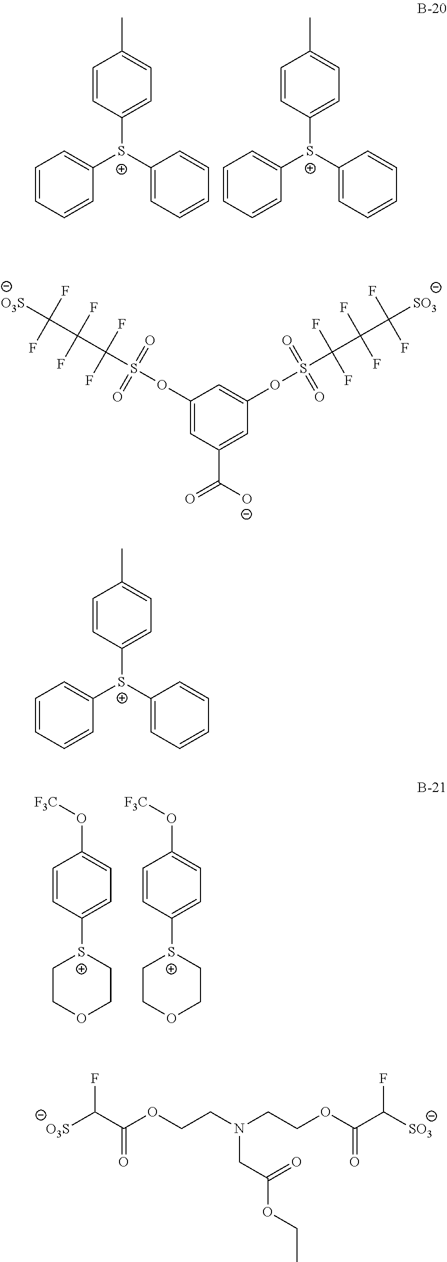

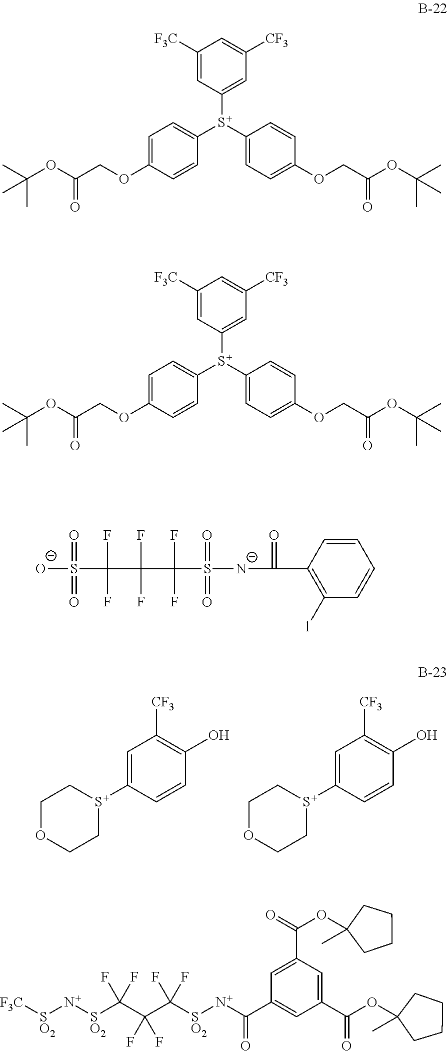

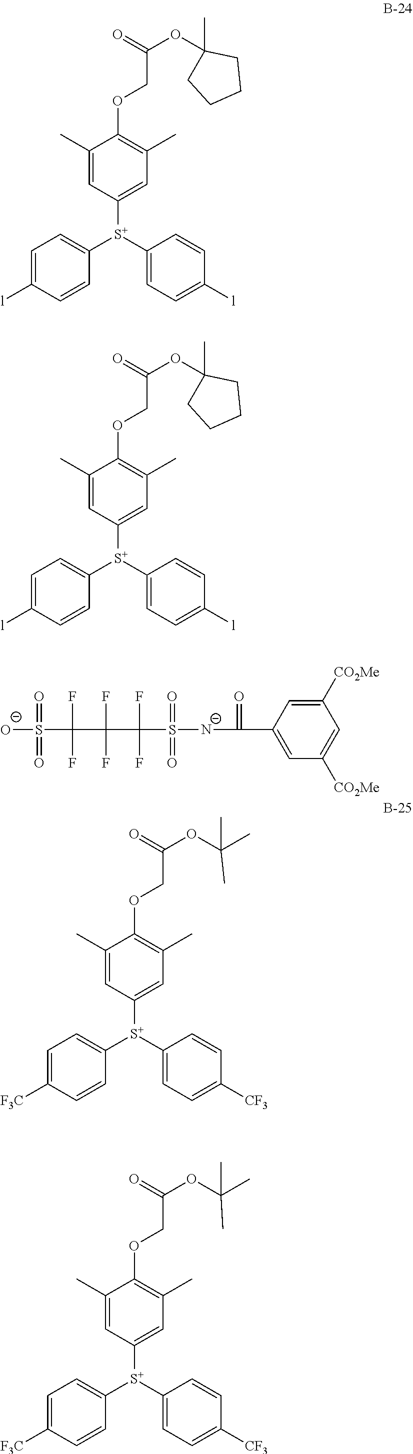

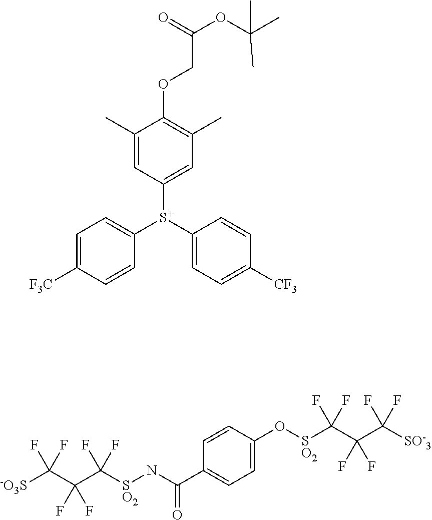

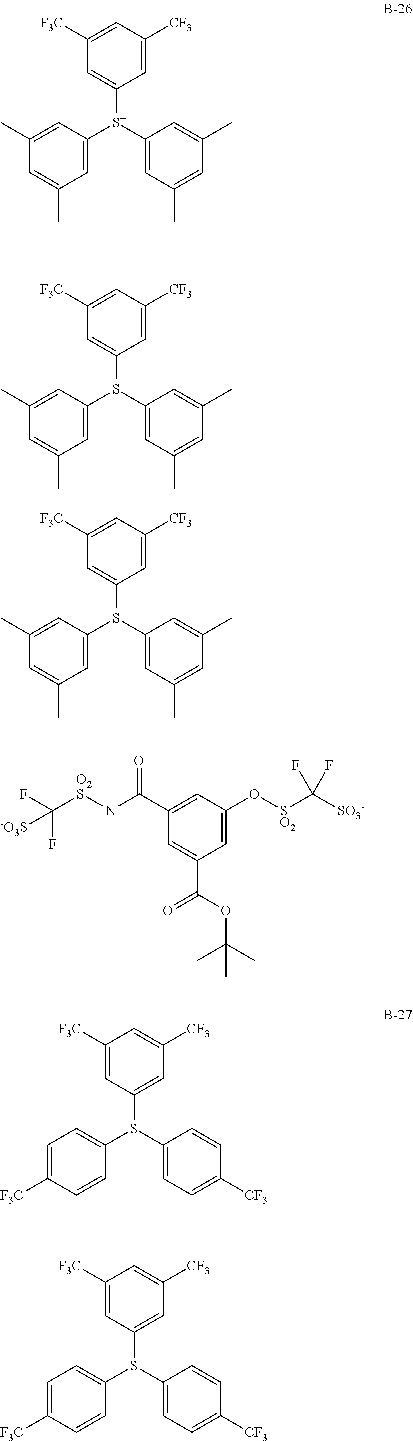

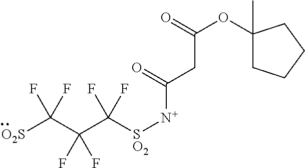

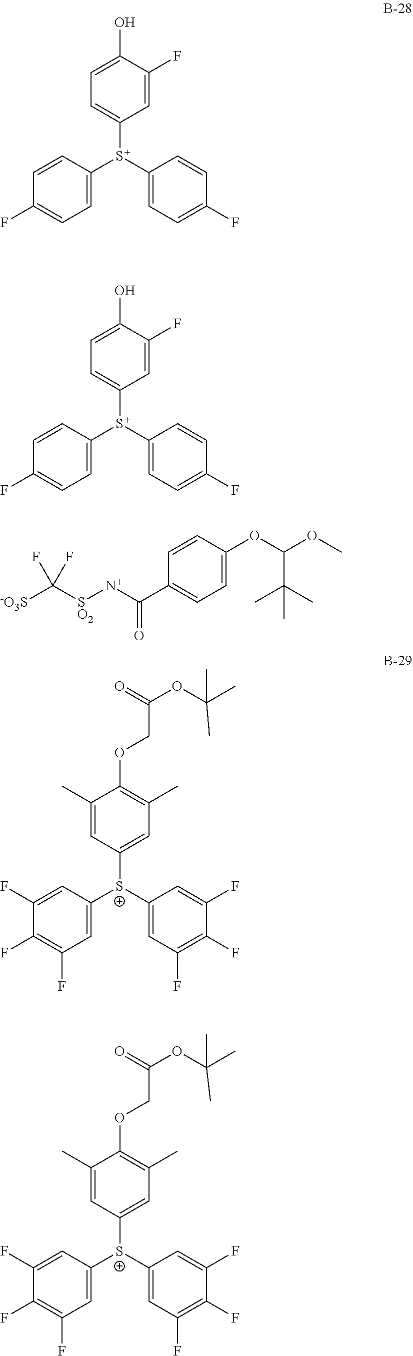

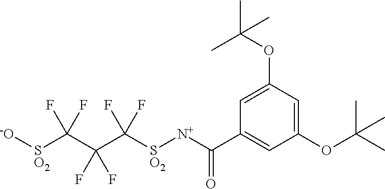

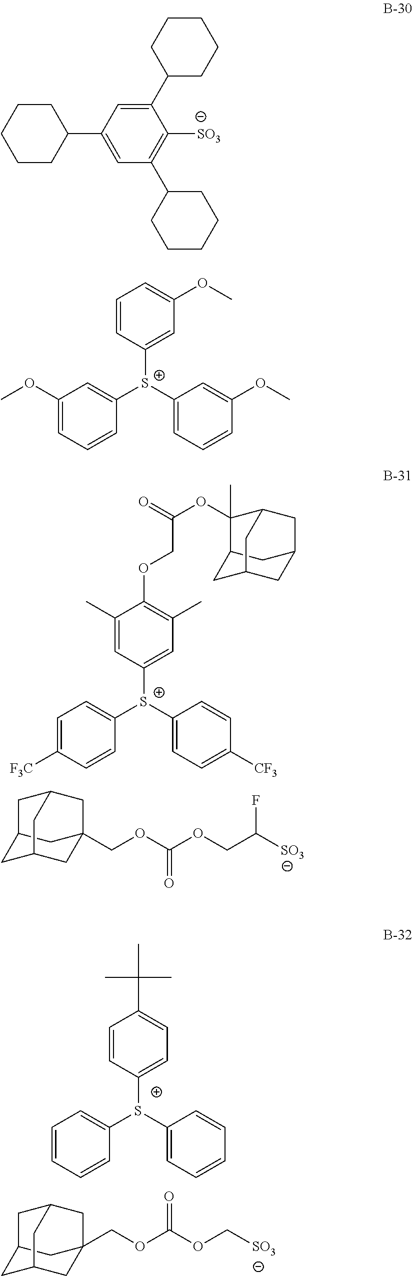

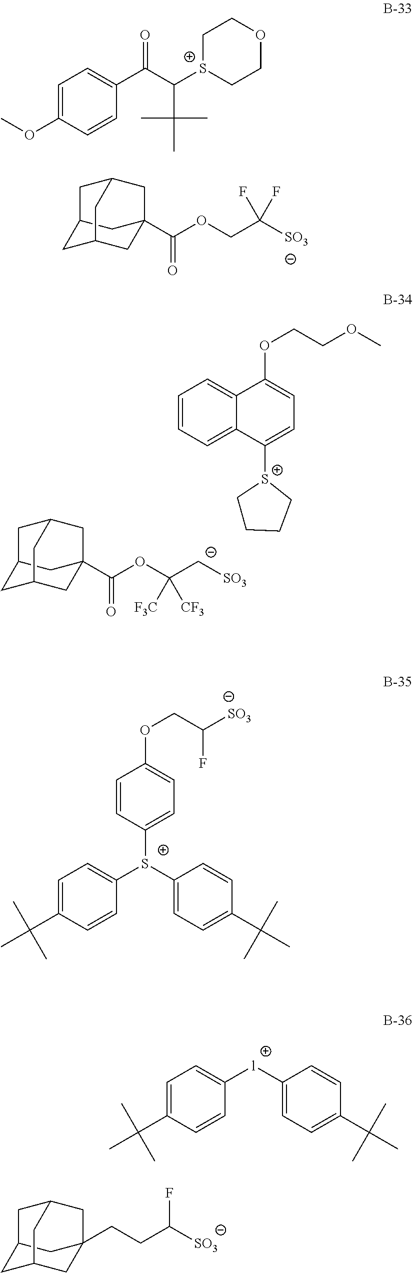

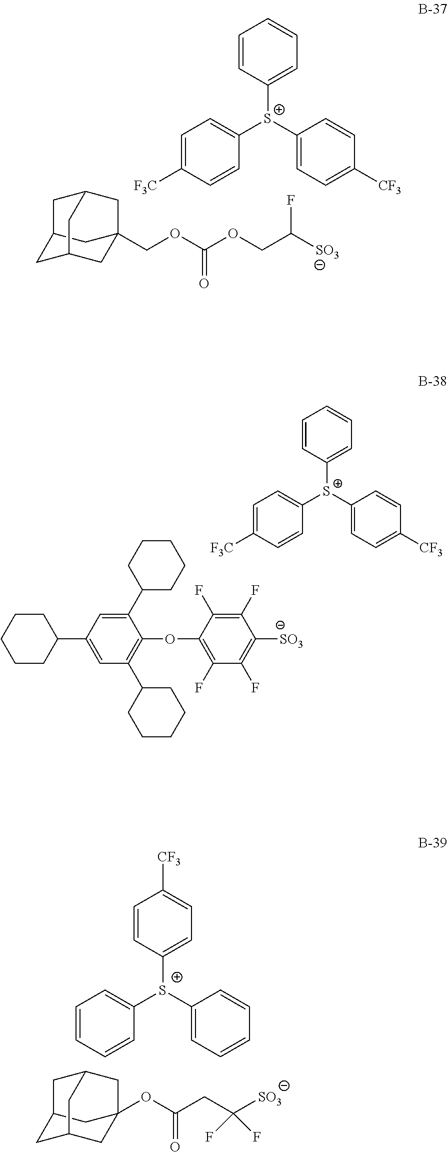

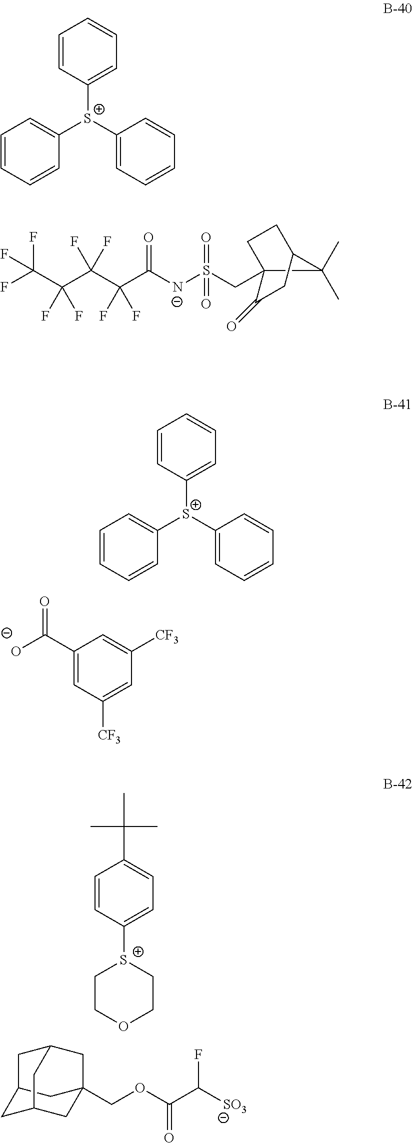

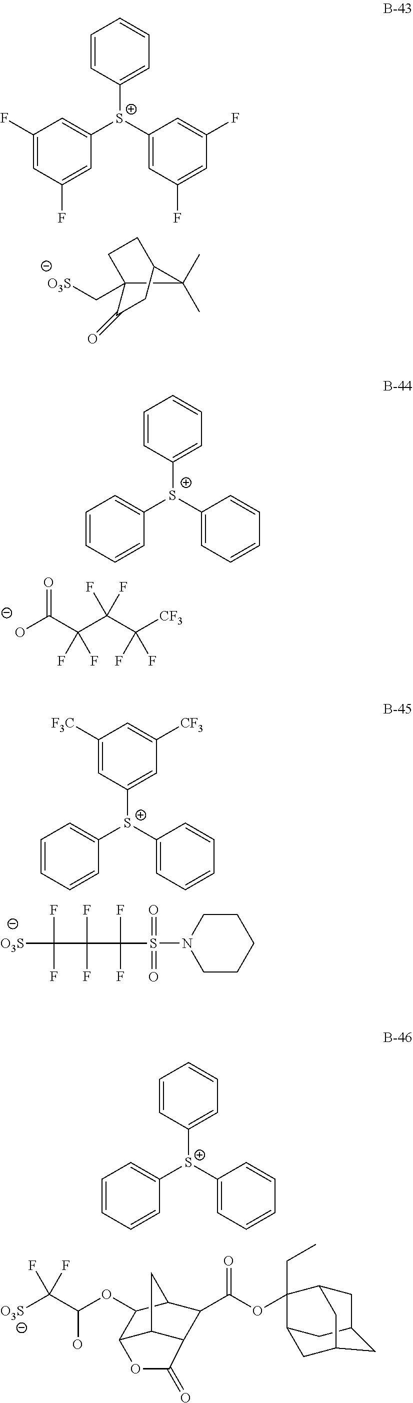

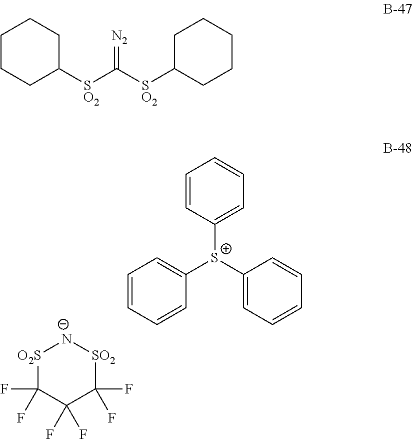

[Acid Diffusion Control Agent]

The structures of acid diffusion control agents (compounds D-1 to D-13) shown in Table 2 are shown below.

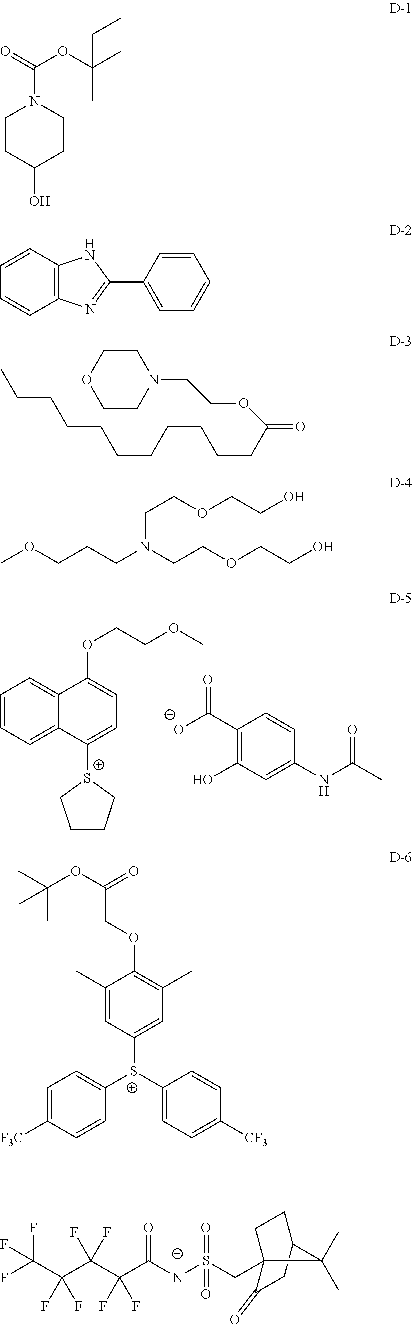

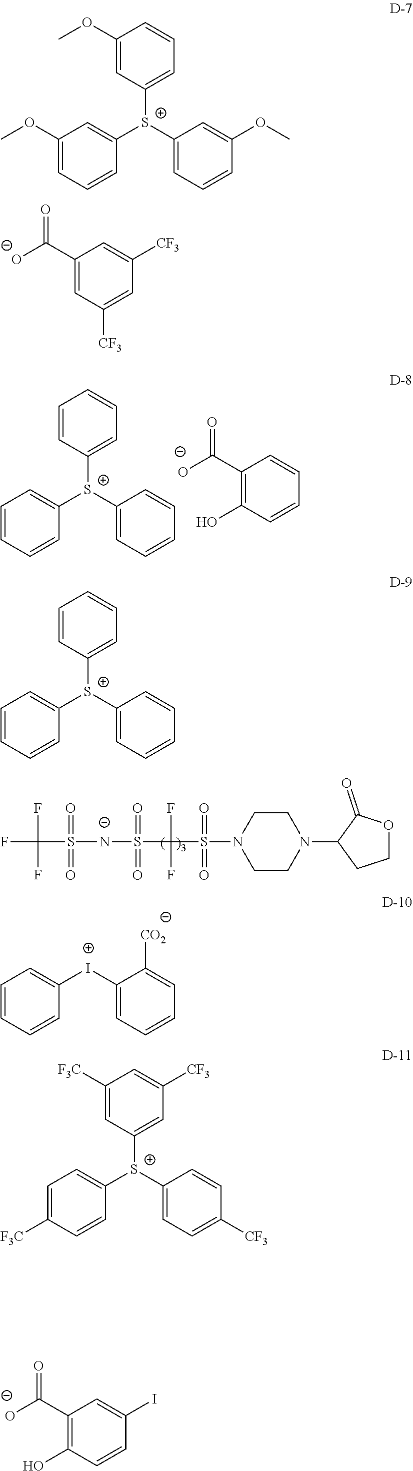

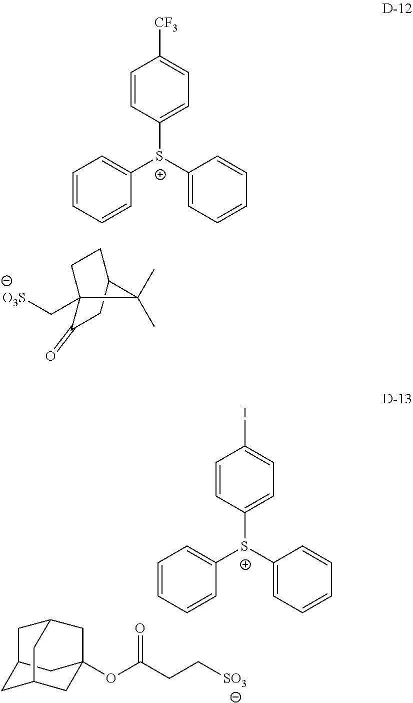

[Hydrophobic Resin]

Hydrophobic resins (resins E-1 to E-4) shown in Table 2 are shown below.

As the resins E-1 to E-4, those synthesized in accordance with known methods were used.

Furthermore, the weight-average molecular weight (Mw) and the dispersity (Mw/Mn) of the resins E-1 to E-4 were measured by GPC (carrier: THF) (an amount expressed in terms of polystyrene). In addition, the compositional ratio (% by mole) of the resin was measured by ¹³C-NMR.

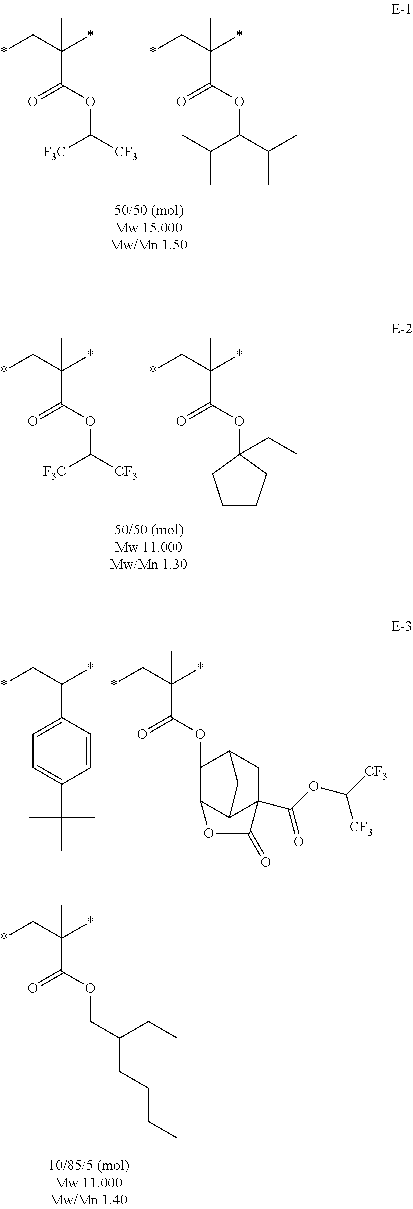

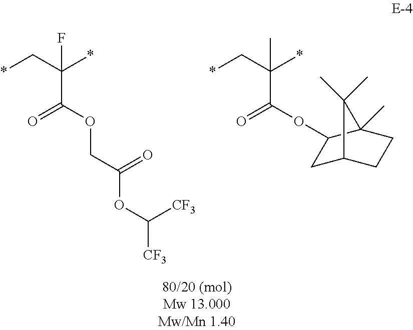 [SMILES: *CC(*)(F)C(=O)OCC(=O)OC(C(F)(F)F)C(F)(F)F ; *CC(*)(C)C(=O)OC1CC2CCC1(C)C2(C)C]

[Surfactant]

Surfactants shown in Table 2 are shown below.

H-1: MEGAFACE F176 (manufactured by DIC Corporation, fluorine-based surfactant)

H-2: MEGAFACE R08 (manufactured by DIC Corporation, fluorine- and silicon-based surfactant)

H-3: PF656 (manufactured by OMNOVA Solutions Inc., fluorine-based surfactant)

[Solvent]

Solvents shown in Table 2 are shown below.

F-1: Propylene glycol monomethyl ether acetate (PGMEA)

F-2: Propylene glycol monomethyl ether (PGME)

F-3: Propylene glycol monoethyl ether (PGEE)

F-4: Cyclohexanone

F-5: Cyclopentanone

F-6: 2-Heptanone

F-7: Ethyl lactate

F-8: γ-Butyrolactone

F-9: Propylene carbonate

[Preparation of Resist Composition]

The respective components shown in Table 2 were mixed so that the concentration of solid contents was 2% by mass. Next, the obtained mixed liquid was filtered initially through a polyethylene-made filter having a pore diameter of 50 nm, then through a nylon-made filter having a pore diameter of 10 nm, and lastly through a polyethylene-made filter having a pore diameter of 5 nm in this order to obtain resist compositions (R-1 to R-81 and CR-1 to CR-4). Furthermore, the solid content means all the components excluding the solvent. The resist compositions prepared above were used as the resist compositions of Examples and Comparative Examples.

TABLE 3

| | | | | | | | Acid diffusion | | Hydrophobic | | | | |
|---|---|---|---|---|---|---|---|---|---|---|---|---|---|
| | Resin | | Photoacid generator | | | | control agent | | resin | | Surfactant | | |
| | | Content | | Content | | Content | | Content | | Content | | Content | Solvent |
| Table | | (% by | | (% by | | (% by | | (% by | | (% by | | (% by | Type (mass |
| 2-1 | Type | mass) | Type | mass) | Type | mass) | Type | mass) | Type | mass) | Type | mass) | ratio) |
| R-1 | A-1 | 78.4 | B-7 | 15.6 | B-44 | 6.0 | — | — | — | — | — | — | F1/F7 = 50/50 |
| R-2 | A-1 | 79.3 | B-30 | 20.7 | — | — | — | — | — | — | — | — | F1/F2 = 70/30 |
| R-3 | A-1 | 86.5 | B-20 | 12.3 | — | — | D-4 | 1.2 | — | — | — | — | F7/F8 = 70/30 |
| R-4 | A-2 | 72.2 | B-28 | 15.2 | B-42 | 10.5 | — | — | E-2 | 2.1 | — | — | F1/F5 = 60/40 |
| R-5 | A-2 | 74.7 | B-32 | 19.5 | — | — | D-5 | 5.8 | — | — | — | — | F1/F8 = 80/20 |
| R-6 | A-3 | 81.4 | B-15 | 14.4 | — | — | D-6 | 4.2 | — | — | — | — | F1/F7 = 60/40 |
| R-7 | A-3 | 72.5 | B-38 | 16.2 | B-48 | 11.3 | — | — | — | — | — | — | F1/F8 = 70/30 |
| R-8 | A-4 | 74.2 | B-5 | 18.1 | B-31 | 7.7 | — | — | — | — | — | — | F7 = 100 |
| R-9 | A-4 | 73.6 | B-39 | 20.2 | B-35 | 3.2xx | — | — | E-1 | 3.0 | — | — | F1/F2/F4 = |
| | | | | | | | | | | | | | 70/20/10 |
| R-10 | A-5 | 79.4 | B-8 | 20.6 | — | — | — | — | — | — | — | — | F1/F7 = 80/20 |
| R-11 | A-5 | 78.0 | B-33 | 20.2 | — | — | D-2 | 1.8 | — | — | — | — | F1/F6 = 80/20 |
| R-12 | A-6 | 78.5 | B-22 | 15.7 | B-37 | 5.8 | — | — | — | — | — | — | F1/F4 = 70/30 |
| R-13 | A-6 | 78.9 | B-46 | 14.3 | — | — | D-13 | 6.8 | — | — | — | — | F1/F5 = 50/50 |
| R-14 | A-7 | 80.4 | B-25 | 12.5 | B-43 | 7.1 | — | — | — | — | — | — | F1/F8 = 80/20 |
| R-15 | A-7 | 77.9 | B-41 | 16.6 | — | — | D-10 | 5.5 | — | — | — | — | F2/F8 = 60/40 |
| R-16 | A-8 | 84.5 | B-17 | 15.5 | — | — | — | — | — | — | — | — | F1/F8 = 50/50 |
| R-17 | A-8 | 85.3 | B-40 | 8.6 | B-36 | 6.1 | — | — | — | — | — | — | F5/F7 = 30/70 |
| R-18 | A-9 | 88.2 | B-10 | 10.2 | — | — | D-1 | 1.6 | — | — | — | — | F1/F8 = 70/30 |
| R-19 | A-9 | 87.6 | B-32 | 12.3 | — | — | — | — | — | — | H-1 | 0.1 | F1/F2/F8 = |
| | | | | | | | | | | | | | 70/25/5 |
| R-20 | A-10 | 78.1 | B-12 | 16.4 | B-39 | 5.5 | — | — | — | — | — | — | F3/F7 = 40/60 |
| R-21 | A-10 | 76.1 | B-30 | 17.1 | B-41 | 6.8 | — | — | — | — | — | — | F1/F4 = 70/30 |
| R-22 | A-11 | 75.3 | B-6 | 16.6 | B-33 | 8.1 | — | — | — | — | — | — | F1/F4/F8 = |
| | | | | | | | | | | | | | 70/20/10 |
| R-23 | A-11 | 78.4 | B-31 | 21.6 | — | — | — | — | — | — | — | — | F1/F6 = 80/20 |
| R-24 | A-12 | 78.7 | B-37 | 18.9 | — | — | D-2 | 2.4 | — | — | — | — | F1/F5 = 60/40 |
| R-25 | A-13 | 80.4 | B-46 | 19.6 | — | — | — | — | — | — | — | — | F2/F8 = 95/5 |
| R-26 | A-14 | 77.6 | B-36 | 15.8 | B-33 | 6.6 | — | — | — | — | — | — | F1/F5 = 60/40 |
| R-27 | A-15 | 78.7 | B-30 | 16.2 | — | — | D-7 | 5.1 | — | — | — | — | F1/F2 = 80/20 |
| R-28 | A-16 | 82.2 | B-10 | 17.8 | — | — | — | — | — | — | — | — | F7/F9 = 60/40 |
| R-29 | A-17 | 84.5 | B-44 | 8.4 | B-37 | 5.3 | — | — | E-1 | 1.8 | — | — | F2/F8 = 50/50 |
| R-30 | A-18 | 72.5 | B-42 | 16.2 | B-36 | 11.3 | — | — | — | — | — | — | F1/F6 = 70/30 |
| R-31 | A-19 | 78.0 | B-25 | 16.2 | — | — | D-3 | 5.8 | — | — | — | — | F1/F7 = 80/20 |
| R-32 | A-20 | 81.2 | B-36 | 10.7 | B-46 | 8.1 | — | — | — | — | — | — | F1/F2 = 70/30 |
| R-33 | A-21 | 78.5 | B-47 | 21.5 | — | — | — | — | — | — | — | — | F1/F8 = 80/20 |
| R-34 | A-22 | 83.4 | B-20 | 14.5 | — | — | D-1 | 2.1 | — | — | — | — | F1/F8 = 70/30 |
| R-35 | A-23 | 77.2 | B-8 | 22.8 | | — | — | — | — | — | — | — | F1/F2/F4 = |
| | | | | | | | | | | | | | 70/25/5 |
| R-36 | A-24 | 80.4 | B-31 | 19.6 | | — | — | — | — | — | — | — | F1/F7 = 50/50 |
| R-37 | A-25 | 76.8 | B-39 | 16.8 | B-44 | 6.4 | — | — | — | — | — | — | F1/F6 = 80/20 |
| R-38 | A-26 | 88.3 | B-22 | 9.7 | — | — | D-2 | 2.0 | — | — | — | — | F1/F2 = 75/25 |
| R-39 | A-27 | 78.3 | B-33 | 16.5 | — | — | D-6 | 5.2 | — | — | — | — | F1/F7 = 60/40 |
| R-40 | A-28 | 76.6 | B-27 | 18.8 | B-33 | 4.6 | — | — | — | — | — | — | F1/F4 = 70/30 |
| R-41 | A-29 | 77.8 | B-39 | 13.4 | B-38 | 8.8 | — | — | — | — | — | — | F1/F8 = 70/30 |
| R-42 | A-30 | 78.5 | B-22 | 21.5 | — | — | — | — | — | — | — | — | F2/F8 = 90/10 |
| R-43 | A-30 | 77.2 | B-30 | 15.6 | B-37 | 6.0 | — | — | E-4 | 1.2 | — | — | F1/F2/F4 = |
| | | | | | | | | | | | | | 70/20/10 |
| R-44 | A-31 | 78.6 | B-29 | 19.8 | — | — | — | — | E-3 | 1.6 | — | — | F1/F8 = 70/30 |
| R-45 | A-31 | 80.6 | B-39 | 16.1 | — | — | D-11 | 3.3 | — | — | — | — | F1/F8 = 50/50 |
| R-46 | A-32 | 73.7 | B-17 | 18.2 | B-37 | 8.1 | — | — | — | — | — | — | F1/F7 = 50/50 |
| R-47 | A-32 | 77.5 | B-31 | 21.6 | — | — | — | — | E-4 | 0.9 | — | — | F1/F6 = 85/15 |
| R-48 | A-33 | 77.6 | B-16 | 15.8 | B-38 | 6.6 | — | — | — | — | — | — | F3/F7 = 50/50 |
| R-49 | A-33 | 74.0 | B-33 | 19.2 | B-32 | 6.8 | — | — | — | — | — | — | F7/F9 = 50/50 |
| R-50 | A-34 | 79.4 | B-11 | 20.6 | — | — | — | — | — | — | — | — | F1/F2 = 70/30 |

TABLE 4

| | | | | | | | Acid diffusion | | Hydrophobic | | | | |
|---|---|---|---|---|---|---|---|---|---|---|---|---|---|
| | Resin | | Photoacid generator | | | | control agent | | resin | | Surfactant | | |
| | | Content | | Content | | Content | | Content | | Content | | Content | Solvent |
| Table | | (% by | | (% by | | (% by | | (% by | | (% by | | (% by | Type (mass |
| 2-2 | Type | mass) | Type | mass) | Type | mass) | Type | mass) | Type | mass) | Type | mass) | ratio) |
| R-51 | A-34 | 81.2 | B-48 | 10.7 | B-40 | 8.1 | — | — | — | — | — | — | F2/F8 = 90/10 |
| R-52 | A-35 | 85.6 | B-14 | 8.6 | — | — | D-9 | 5.8 | — | — | — | — | F1/F5 = 60/40 |
| R-53 | A-35 | 86.6 | B-35 | 9.4 | — | — | D-8 | 1.7 | E-2 | 2.2 | H-2 | 0.1 | F1/F7 = 60/40 |
| R-54 | A-36 | 76.3 | B-7 | 15.4 | B-36 | 8.3 | — | — | — | — | — | — | F1/F4 = 80/20 |
| R-55 | A-36 | 78.8 | B-40 | 16.6 | — | — | D-6 | 4.6 | — | — | — | — | F1/F8 = 70/30 |
| R-56 | A-37 | 87.7 | B-4 | 6.8 | B-47 | 3.1 | — | — | E-3 | 2.4 | — | — | F2/F8 = 60/40 |
| R-57 | A-37 | 80.2 | B-44 | 19.8 | — | — | — | — | — | — | — | — | F1/F7 = 50/50 |
| R-58 | A-38 | 79.0 | B-38 | 18.9 | — | — | D-1 | 2.1 | — | — | — | — | F1/F6 = 70/30 |
| R-59 | A-39 | 81.3 | B-46 | 16.9 | — | — | — | — | E-3 | 1.8 | — | — | F1/F8 = 70/30 |
| R-60 | A-40 | 80.5 | B-29 | 11.8 | B-39 | 7.7 | — | — | — | — | — | — | F1/F2 = 80/20 |
| R-61 | A-41 | 76.1 | B-15 | 17.1 | B-43 | 6.8 | — | — | — | — | — | — | F1/F2 = 75/25 |
| R-62 | A-42 | 74.8 | B-12 | 17.6 | B-46 | 5.8 | — | — | E-4 | 1.8 | — | — | F2/F8 = 90/10 |
| R-63 | A-43 | 81.1 | B-11 | 12.0 | B-34 | 6.9 | — | — | — | — | — | — | F1/F5 = 60/40 |
| R-64 | A-44 | 74.1 | B-30 | 15.7 | B-42 | 10.2 | — | — | — | — | — | — | F3/F7 = 50/50 |
| R-65 | A-45 | 85.0 | B-36 | 8.2 | — | — | D-12 | 6.8 | — | — | — | — | F1/F7 = 50/50 |
| R-66 | A-46 | 80.4 | B-29 | 12.5 | B-40 | 7.1 | — | — | — | — | — | — | F1/F8 = 70/30 |
| R-67 | A-47 | 79.3 | B-22 | 13.5 | B-48 | 7.2 | — | — | — | — | — | — | F5/F7 = 30/70 |
| R-68 | A-48 | 79.8 | B-44 | 17.8 | — | — | — | — | E-2 | 2.4 | — | — | F1/F8 = 80/20 |
| R-69 | A-49 | 77.6 | B-27 | 22.4 | — | — | — | — | — | — | — | — | F1/F2 = 75/25 |
| R-70 | A-50 | 80.1 | B-45 | 19.9 | — | — | — | — | — | — | — | — | F1/F8 = 70/30 |
| R-71 | A-51 | 80.5 | B-1 | 11.8 | B-39 | 7.6 | — | — | — | — | H-3 | 0.1 | F1/F2 = 75/25 |
| R-72 | A-51 | 76.1 | B-2 | 17.1 | B-43 | 6.8 | — | — | — | — | — | — | F1/F7 = 60/40 |
| R-73 | A-52 | 74.8 | B-3 | 17.6 | B-46 | 5.8 | — | — | E-4 | 1.8 | — | — | F1/F4 = 70/30 |
| R-74 | A-52 | 81.1 | B-9 | 12.0 | B-34 | 6.9 | — | — | — | — | — | — | F1/F8 = 70/30 |
| R-75 | A-53 | 74.1 | B-13 | 15.7 | B-42 | 10.2 | — | — | — | — | — | — | F2/F8 = 90/10 |
| R-76 | A-53 | 85.0 | B-18 | 8.2 | — | — | D-12 | 6.8 | — | — | — | — | F1/F2/F4 = |
| | | | | | | | | | | | | | 70/20/10 |
| R-77 | A-54 | 80.4 | B-19 | 12.5 | B-40 | 7.1 | — | — | — | — | — | — | F1/F8 = 70/30 |
| R-78 | A-54 | 79.3 | B-21 | 13.5 | B-48 | 7.2 | — | — | — | — | — | — | F1/F8 = 50/50 |
| R-79 | A-55 | 79.8 | B-23 | 17.8 | — | — | — | — | E-2 | 2.4 | — | — | F1/F7 = 50/50 |
| R-80 | A-55 | 77.6 | B-24 | 22.4 | — | — | — | — | — | — | — | — | F1/F6 = 85/15 |
| R-81 | A-55 | 80.1 | B-26 | 19.9 | — | — | — | — | — | — | — | — | F3/F7 = 50/50 |
| CR-1 | RA-1 | 83.8 | B-40 | 14.0 | — | — | D-3 | 2.2 | — | — | — | — | F1/F4/F8 = |
| | | | | | | | | | | | | | 70/20/10 |
| CR-2 | RA-2 | 83.8 | B-40 | 14.0 | — | — | D-3 | 2.2 | — | — | — | — | F1/F4/F8 = |
| | | | | | | | | | | | | | 70/20/10 |
| CR-3 | RA-3 | 83.8 | B-40 | 14.0 | — | — | D-3 | 2.2 | — | — | — | — | F1/F4/F8 = |
| | | | | | | | | | | | | | 70/20/10 |
| CR-4 | RA-4 | 83.8 | B-40 | 14.0 | — | — | D-3 | 2.2 | — | — | — | — | F1/F4/F8 = |
| | | | | | | | | | | | | | 70/20/10 |

[Pattern Formation]

[EUV Exposure and Organic Solvent Development]

A composition for forming an underlayer film, AL412 (manufactured by Brewer Science, Inc.) was applied onto a silicon wafer having a diameter of 12 inches and baked at 205° C. for 60 seconds to form an underlying film having a film thickness of 20 nm. A resist composition shown in Table 3 was applied thereon and baked at 100° C. for 60 seconds to form a resist film having a film thickness of 30 nm.

The silicon wafer having the obtained resist film was subjected to patternwise irradiation using an EUV exposure device (manufactured by Exitech Ltd., Micro Exposure Tool, NA 0.3, Quadrupol, outer sigma 0.68, inner sigma 0.36), and pattern irradiation was performed such that the average line width of the obtained pattern was 20 nm. Furthermore, as a reticle, a mask having a line size=20 nm and a line:space=1:1 was used.

The resist film after the exposure was baked at 90° C. for 60 seconds, developed with n-butyl acetate for 30 seconds, and spin-dried to obtain a negative tone pattern.

<Evaluation of Resolution (Limit Resolution, nm)>

Using the above-mentioned resist pattern forming method, an optimum exposure amount Eop (μC/cm²) in which the L/S pattern of a target size is formed was determined. A limit resolution in this Eop, specifically, a minimum dimension of a pattern that resolves without collapsing in a case where the exposure amount is gradually increased from the optimum exposure amount Eop to form an L/S pattern was determined using a scanning electron microscope (SEM (Hitachi, Ltd., S-9380II)). This was defined as a “limit resolution (nm)”. The smaller the limit resolution value, the better the resolution.

In addition, the limit resolution (nm) is preferably 23 nm or less, more preferably 22 nm or less, still more preferably 21 nm or less, particularly preferably 20 nm or less, and most preferably 19 nm or less.

Table 3 is shown below.

Incidentally, in Tables 3 to 5, the “Type of resin (A)” in the “Resin (A)” column in “Note” is intended to be a type of the resin (A) included in the resist composition.

Moreover, in Tables 3 to 5, the “Type” in the “Repeating unit (A)” column is intended to be a type of the repeating unit (A) included in the resin (A).

In addition, in Tables 3 to 5, the “Number of carbon atoms of leaving group in acid-decomposable group” in the “Repeating unit (A)” column is intended to be the number of carbon atoms of the leaving group in the acid-decomposable group in the repeating unit (A).

In addition, in Tables 3 to 5, the “Content” in the “Repeating unit (A)” column is intended to be the content (% by mass) of the repeating unit (A) with respect to all the repeating units in the resin (A). A case where the content of the repeating unit (A) with respect to all the repeating units in the resin (A) is 30% by mass or more is denoted as “P”, and a case where the content of the repeating unit (A) with respect to all the repeating units in the resin (A) is less than 30% by mass is denoted as “N”.

Furthermore, in Tables 3 to 5, the “Presence or absence of specific photoacid generator” column in the “Note” shows whether the resist composition includes one or more photoacid generators selected from the group consisting of the above-mentioned compounds (I) and (II) (specific photoacid generators). A case where the resist composition includes the specific photoacid generator is denoted as “P”, and a case where the resist composition does not include the specific photoacid generator is denoted as “N”.

TABLE 5

| | | Note | | | | | |
|---|---|---|---|---|---|---|---|
| | | Resin (A) | | | | | |
| | | | Repeating unit (A) | | | | |
| | | | | Number of carbon | | Presence or | |
| Table 3 (EUV | | | | atoms of leaving | | absence of | |
| exposure/ | | | | group in acid- | | specific | Limit |
| negative | Composition | Type of | | decomposable | | photoacid | resolution |
| development) | No. | resin (A) | Type | group | Content | generator | (nm) |
| Example 1 | R-1 | A-1 | a1 | 4 | P | P | 19 |
| Example 2 | R-2 | A-1 | a1 | 4 | P | N | 20 |
| Example 3 | R-3 | A-1 | a1 | 4 | P | P | 19 |
| Example 4 | R-4 | A-2 | a1 | 4 | P | P | 19 |
| Example 5 | R-5 | A-2 | a1 | 4 | P | N | 20 |
| Example 6 | R-6 | A-3 | a1 | 4 | P | P | 19 |
| Example 7 | R-7 | A-3 | a1 | 4 | P | N | 20 |
| Example 8 | R-8 | A-4 | a1 | 4 | N | P | 20 |
| Example 9 | R-9 | A-4 | a1 | 4 | N | N | 21 |
| Example 10 | R-10 | A-5 | a1 | 4 | P | P | 19 |
| Example 11 | R-11 | A-5 | a1 | 4 | P | N | 20 |
| Example 12 | R-12 | A-6 | a1 | 4 | P | P | 19 |
| Example 13 | R-13 | A-6 | a1 | 4 | P | N | 20 |
| Example 14 | R-14 | A-7 | a11 | 4 | P | P | 19 |
| Example 15 | R-15 | A-7 | a11 | 4 | P | N | 20 |
| Example 16 | R-16 | A-8 | a11 | 4 | P | P | 19 |
| Example 17 | R-17 | A-8 | a11 | 4 | P | N | 20 |
| Example 18 | R-18 | A-9 | a21 | 4 | P | P | 19 |
| Example 19 | R-19 | A-9 | a21 | 4 | P | N | 20 |
| Example 20 | R-20 | A-10 | a6 | 8 | P | P | 20 |
| Example 21 | R-21 | A-10 | a6 | 8 | P | N | 21 |
| Example 22 | R-22 | A-11 | a5 | 6 | P | P | 19 |
| Example 23 | R-23 | A-11 | a5 | 6 | P | N | 20 |
| Example 24 | R-24 | A-12 | a6 | 8 | N | N | 22 |
| Example 25 | R-25 | A-13 | a4 | 7 | P | N | 20 |
| Example 26 | R-26 | A-14 | a17 | 10 | P | N | 21 |
| Example 27 | R-27 | A-15 | a30 | 13 | N | N | 22 |
| Example 28 | R-28 | A-16 | a2 | 6 | N | P | 20 |
| Example 29 | R-29 | A-17 | a14 | 7 | N | N | 21 |
| Example 30 | R-30 | A-18 | a27 | 10 | P | N | 21 |
| Example 31 | R-31 | A-19 | a29 | 9 | P | P | 20 |
| Example 32 | R-32 | A-20 | a28 | 12 | P | N | 21 |
| Example 33 | R-33 | A-21 | a23 | 7 | N | N | 21 |
| Example 34 | R-34 | A-22 | a26 | 8 | N | P | 21 |
| Example 35 | R-35 | A-23 | a13 | 7 | N | P | 20 |
| Example 36 | R-36 | A-24 | a18 | 12 | P | N | 21 |
| Example 37 | R-37 | A-25 | a7 | 10 | N | N | 22 |
| Example 38 | R-38 | A-26 | a10 | 13 | N | P | 21 |
| Example 39 | R-39 | A-27 | a10 | 13 | P | N | 21 |
| Example 40 | R-40 | A-28 | a15 | 6 | P | P | 19 |
| Example 41 | R-41 | A-29 | a18 | 12 | P | N | 21 |
| Comparative | CR-1 | — | — | — | — | — | 26 |
| Example 1 | | | | | | | |
| Comparative | CR-2 | — | — | — | — | — | 27 |
| Example 2 | | | | | | | |

As shown in Table 3 above, it was confirmed that the resist composition of the embodiment of the present invention has an excellent resolution.

In particular, it was confirmed that in a case where the resist composition satisfies at least one of the following condition A, B, or C (preferably a case where the resist composition satisfies at least two conditions, and more preferably a case where the resist composition satisfies all the conditions), the resolution is more excellent.

Condition A: The acid-decomposable group in the repeating unit X1 in the resin (A) has a structure in which a polar group is protected by a leaving group having 7 or less carbon atoms, which leaves by the action of an acid (preferably, the resin (A) includes the above-mentioned repeating unit represented by Formula (A) as the repeating unit X1, and any two or more of X1, . . . , or X4 in the repeating unit represented by Formula (A) represent a group represented by Formula (AP′), having a leaving group (M¹¹) having 7 or less carbon atoms).

Condition B: The content of the repeating unit X1 in the resin (A) is 30% by mass or more with respect to all the repeating units of the resin (A).

Condition C: The resist composition includes a specific photoacid generator.

On the other hand, the resist compositions of Comparative Examples did not satisfy the desired requirements.

[EUV Exposure and Aqueous Alkali Solution Development]

A composition for forming an underlayer film, AL412 (manufactured by Brewer Science, Inc.) was applied onto a silicon wafer having a diameter of 12 inches and baked at 205° C. for 60 seconds to form an underlying film having a film thickness of 20 nm. A resist composition shown in Table 4 was applied thereon and baked at 100° C. for 60 seconds to form a resist film having a film thickness of 30 nm.

The silicon wafer having the obtained resist film was subjected to patternwise irradiation using an EUV exposure device (manufactured by Exitech Ltd., Micro Exposure Tool, NA 0.3, Quadrupol, outer sigma 0.68, inner sigma 0.36), and pattern irradiation was performed such that the average line width of the obtained pattern was 20 nm. Furthermore, as a reticle, a mask having a line size=20 nm and a line:space=1:1 was used.

The resist film after the exposure was baked at 90° C. for 60 seconds, developed with an aqueous tetramethylammonium hydroxide solution (2.38% by mass) for 30 seconds, and then rinsed with pure water for 30 seconds. Thereafter, the resist film was spin-dried to obtain a positive tone pattern.

Using the obtained positive tone pattern, the resolution was evaluated in the same manner as described above.

Furthermore, the limit resolution (nm) is preferably 23 nm or less, more preferably 22 nm or less, still more preferably 21 nm or less, particularly preferably 20 nm or less, and most preferably 19 nm or less.

TABLE 6

| | | Note | | | | | |
|---|---|---|---|---|---|---|---|
| | | Resin (A) | | | | | |
| | | | Repeating unit (A) | | | | |
| | | | | Number of carbon | | Presence or | |
| Table 4 (EUV | | | | atoms of leaving | | absence of | |
| exposure/ | | | | group in acid- | | specific | Limit |
| positive | Composition | Type of | | decomposable | | photoacid | resolution |
| development) | No. | resin (A) | Type | group | Content | generator | (nm) |
| Example 42 | R-42 | A-30 | a1 | 4 | P | P | 20 |
| Example 43 | R-43 | A-30 | a1 | 4 | P | N | 21 |
| Example 44 | R-44 | A-31 | a1 | 4 | P | P | 20 |
| Example 45 | R-45 | A-31 | a1 | 4 | P | N | 21 |
| Example 46 | R-46 | A-32 | a1 | 4 | P | P | 20 |
| Example 47 | R-47 | A-32 | a1 | 4 | P | N | 21 |
| Example 48 | R-48 | A-33 | a1 | 4 | P | P | 20 |
| Example 49 | R-49 | A-33 | a1 | 4 | P | N | 21 |
| Example 50 | R-50 | A-34 | a2 | 6 | P | P | 20 |
| Example 51 | R-51 | A-34 | a2 | 6 | P | N | 21 |
| Example 52 | R-52 | A-35 | a15 | 6 | P | P | 20 |
| Example 53 | R-53 | A-35 | a15 | 6 | P | N | 21 |
| Example 54 | R-54 | A-36 | a15 | 6 | N | P | 21 |
| Example 55 | R-55 | A-36 | a15 | 6 | N | N | 22 |
| Example 56 | R-56 | A-37 | a16 | 8 | P | P | 21 |
| Example 57 | R-57 | A-37 | a16 | 8 | P | N | 22 |
| Example 58 | R-58 | A-38 | a6 | 8 | N | N | 23 |
| Example 59 | R-59 | A-39 | a3 | 7 | N | N | 22 |
| Example 60 | R-60 | A-40 | a7 | 10 | N | P | 22 |
| Example 61 | R-61 | A-41 | a9 | 9 | N | P | 22 |
| Example 62 | R-62 | A-42 | a13 | 7 | N | P | 21 |
| Example 63 | R-63 | A-43 | a17 | 10 | N | P | 22 |
| Example 64 | R-64 | A-44 | a18 | 12 | N | N | 23 |
| Example 65 | R-65 | A-45 | a20 | 13 | N | N | 23 |
| Example 66 | R-66 | A-46 | a22 | 6 | N | P | 21 |
| Example 67 | R-67 | A-47 | a26 | 8 | P | P | 21 |
| Example 68 | R-68 | A-48 | a28 | 12 | P | N | 22 |
| Example 69 | R-69 | A-49 | a28 | 12 | N | P | 22 |
| Example 70 | R-70 | A-50 | a30 | 13 | N | N | 23 |
| Example 71 | R-71 | A-51 | a8 | 12 | P | P | 21 |
| Example 72 | R-72 | A-51 | a8 | 12 | P | P | 21 |
| Example 73 | R-73 | A-52 | a12 | 6 | P | P | 20 |
| Example 74 | R-74 | A-52 | a12 | 6 | P | P | 20 |
| Example 75 | R-75 | A-53 | a19 | 9 | P | P | 21 |
| Example 76 | R-76 | A-53 | a19 | 9 | P | P | 21 |
| Example 77 | R-77 | A-54 | a24 | 7 | P | P | 20 |
| Example 78 | R-78 | A-54 | a24 | 7 | P | P | 20 |
| Example 79 | R-79 | A-55 | a25 | 6 | P | P | 20 |
| Example 80 | R-80 | A-55 | a25 | 6 | P | P | 20 |
| Example 81 | R-81 | A-55 | a25 | 6 | P | P | 20 |
| Comparative | CR-3 | — | — | — | — | — | 26 |
| Example 3 | | | | | | | |
| Comparative | CR-4 | — | — | — | — | — | 27 |
| Example 4 | | | | | | | |

As shown in Table 4 above, it was confirmed that the resist composition of the embodiment of the present invention has an excellent resolution.

In particular, it was confirmed that in a case where the resist composition satisfies at least one of the following condition A, B, or C (preferably a case where the resist composition satisfies at least two conditions, and more preferably a case where the resist composition satisfies all the conditions), the resolution is more excellent.

Condition A: The acid-decomposable group in the repeating unit X1 in the resin (A) has a structure in which a polar group is protected by a leaving group having 7 or less carbon atoms, which leaves by the action of an acid (preferably, the resin (A) includes the above-mentioned repeating unit represented by Formula (A) as the repeating unit X1, and any two or more of X¹, . . . , or X⁴ in the repeating unit represented by Formula (A) represent a group represented by Formula (AP′), having a leaving group (M¹¹) having 7 or less carbon atoms).

Condition B: The content of the repeating unit X1 in the resin (A) is 30% by mass or more with respect to all the repeating units of the resin (A).

Condition C: The resist composition includes a specific photoacid generator.

On the other hand, the resist compositions of Comparative Examples did not satisfy the desired requirements.

[EB Exposure and Alkali Solvent Development]

A composition for forming an antireflection film, DUV44 (manufactured by Brewer Science, Inc.), was applied onto a silicon wafer and baked at 205° C. for 60 seconds to form an antireflection film having a film thickness of 60 nm. A resist composition shown in Table 5 was applied thereon and baked at 100° C. for 60 seconds to form a resist film having a film thickness of 50 nm. As a result, a silicon wafer having the resist film was formed.

The silicon wafer having the resist film obtained by the above-mentioned procedure was subjected to pattern irradiation using an electron beam drawing device (manufactured by Hitachi, Ltd., HL750, acceleration voltage: 50 keV). At that time, lithography was performed so that a 1:1 line-and-space was formed.

The resist film after the exposure was baked at 90° C. for 60 seconds, developed with an aqueous tetramethylammonium hydroxide solution (2.38% by mass) for 30 seconds, and then rinsed with pure water for 30 seconds. Thereafter, the resist film was spin-dried to obtain a positive tone pattern.

Using the obtained positive tone pattern, the resolution was evaluated in the same manner as described above.

Furthermore, the limit resolution (nm) is preferably 24 nm or less, more preferably 23 nm or less, still more preferably 22 nm or less, even still more preferably 21 nm or less, particularly preferably 20 nm or less, and most preferably 19 nm or less.

TABLE 7

| | | Note | | | | | |
|---|---|---|---|---|---|---|---|
| | | Resin (A) | | | | | |
| | | | Repeating unit (A) | | | | |
| | | | | Number of carbon | | Presence or | |
| Table 5 (EB | | | | atoms of leaving | | absence of | |
| exposure/ | | | | group in acid- | | specific | Limit |
| positive | Composition | Type of | | decomposable | | photoacid | resolution |
| development) | No. | resin (A) | Type | group | Content | generator | (nm) |
| Example 82 | R-42 | A-30 | a1 | 4 | P | P | 21 |
| Example 83 | R-43 | A-30 | a1 | 4 | P | N | 22 |
| Example 84 | R-44 | A-31 | a1 | 4 | P | P | 21 |
| Example 85 | R-45 | A-31 | a1 | 4 | P | N | 22 |
| Example 86 | R-46 | A-32 | a1 | 4 | P | P | 21 |
| Example 87 | R-47 | A-32 | a1 | 4 | P | N | 22 |
| Example 88 | R-48 | A-33 | a1 | 4 | P | P | 21 |
| Example 89 | R-49 | A-33 | a1 | 4 | P | N | 22 |
| Example 90 | R-50 | A-34 | a2 | 6 | P | P | 21 |
| Example 91 | R-51 | A-34 | a2 | 6 | P | N | 22 |
| Example 92 | R-52 | A-35 | a15 | 6 | P | P | 21 |
| Example 93 | R-53 | A-35 | a15 | 6 | P | N | 22 |
| Example 94 | R-54 | A-36 | a15 | 6 | N | P | 22 |
| Example 95 | R-55 | A-36 | a15 | 6 | N | N | 23 |
| Example 96 | R-56 | A-37 | a16 | 8 | P | P | 22 |
| Example 97 | R-57 | A-37 | a16 | 8 | P | N | 23 |
| Example 98 | R-58 | A-38 | a6 | 8 | N | N | 24 |
| Example 99 | R-59 | A-39 | a3 | 7 | N | N | 23 |
| Example 100 | R-60 | A-40 | a7 | 10 | N | P | 23 |
| Example 101 | R-61 | A-41 | a9 | 9 | N | P | 23 |
| Example 102 | R-62 | A-42 | a13 | 7 | N | P | 22 |
| Example 103 | R-63 | A-43 | a17 | 10 | N | P | 23 |
| Example 104 | R-64 | A-44 | a18 | 12 | N | N | 24 |
| Example 105 | R-65 | A-45 | a20 | 13 | N | N | 24 |
| Example 106 | R-66 | A-46 | a22 | 6 | N | P | 22 |
| Example 107 | R-67 | A-47 | a26 | 8 | P | P | 22 |
| Example 108 | R-68 | A-48 | a28 | 12 | P | N | 23 |
| Example 109 | R-69 | A-49 | a28 | 12 | N | P | 23 |
| Example 110 | R-70 | A-50 | a30 | 13 | N | N | 24 |
| Example 111 | R-71 | A-51 | a8 | 12 | P | P | 22 |
| Example 112 | R-72 | A-51 | a8 | 12 | P | P | 22 |
| Example 113 | R-73 | A-52 | a12 | 6 | P | P | 21 |
| Example 114 | R-74 | A-52 | a12 | 6 | P | P | 21 |
| Example 115 | R-75 | A-53 | a19 | 9 | P | P | 22 |
| Example 116 | R-76 | A-53 | a19 | 9 | P | P | 22 |
| Example 117 | R-77 | A-54 | a24 | 7 | P | P | 21 |
| Example 118 | R-78 | A-54 | a24 | 7 | P | P | 21 |
| Example 119 | R-79 | A-55 | a25 | 6 | P | P | 21 |
| Example 120 | R-80 | A-55 | a25 | 6 | P | P | 21 |
| Example 121 | R-81 | A-55 | a25 | 6 | P | P | 21 |
| Comparative | CR-3 | — | — | — | — | — | 27 |
| Example 5 | | | | | | | |
| Comparative | CR-4 | — | — | — | — | — | 28 |
| Example 6 | | | | | | | |

As shown in Table 5 above, it was confirmed that the resist composition of the embodiment of the present invention has an excellent resolution.

In particular, it was confirmed that in a case where the resist composition satisfies at least one of the following condition A, B, or C (preferably a case where the resist composition satisfies at least two conditions, and more preferably a case where the resist composition satisfies all the conditions), the resolution is more excellent.

Condition A: The acid-decomposable group in the repeating unit X1 in the resin (A) has a structure in which a polar group is protected by a leaving group having 7 or less carbon atoms, which leaves by the action of an acid (preferably, the resin (A) includes the above-mentioned repeating unit represented by Formula (A) as the repeating unit X1, and any two or more of X¹, . . . , or X⁴ in the repeating unit represented by Formula (A) represent a group represented by Formula (AP′), having a leaving group (M¹¹) having 7 or less carbon atoms).

Condition B: The content of the repeating unit X1 in the resin (A) is 30% by mass or more with respect to all the repeating units of the resin (A).

Condition C: The resist composition includes a specific photoacid generator.

On the other hand, the resist compositions of Comparative Examples did not satisfy the desired requirements.

What is claimed is:

1. An actinic ray-sensitive or radiation-sensitive resin composition comprising:
a resin of which polarity increases through decomposition by an action of an acid; and
a compound that generates an acid upon irradiation with actinic rays or radiation,
wherein the resin includes a resin containing a repeating unit X1 having two or more groups of which polarity increases through decomposition by an action of an acid and a repeating unit X2 having a phenolic hydroxyl group.

2. The actinic ray-sensitive or radiation-sensitive resin composition according to claim 1,
wherein the repeating unit X1 is a repeating unit represented by Formula (A), 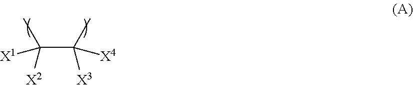
in the formula, X¹ to X⁴ each independently represent a hydrogen atom, an alkyl group, or a group represented by Formula (AP′), provided that two or more of X¹ to X⁴ represent a group represented by Formula (AP),
*-L¹-COOM¹¹ Expression (AP′):
in the formula, L¹ represents a single bond or a divalent organic group, M¹¹ represents a leaving group that leaves by an action of an acid, and * represents a bonding position.

3. The actinic ray-sensitive or radiation-sensitive resin composition according to claim 2,
wherein M¹¹ has 7 or less carbon atoms.

4. The actinic ray-sensitive or radiation-sensitive resin composition according to claim 1,
wherein a content of the repeating unit X1 is 30% by mass or more with respect to all repeating units in the resin.

5. The actinic ray-sensitive or radiation-sensitive resin composition according to claim 1,
wherein the repeating unit X2 is a repeating unit represented by Formula (I), 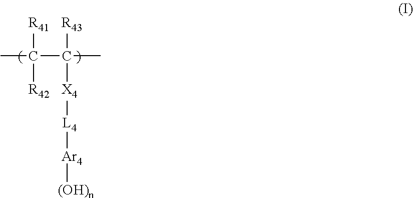
in the formula, R₄₁, R₄₂, and R₄₃ each independently represent a hydrogen atom or a substituent, provided that R⁴² may be bonded to Ar₄ to form a ring, where in such a case R₄₂ represents a single bond or an alkylene group,
X₄ represents a single bond, —COO—, or —CONR₆₄—, where R₆₄ represents a hydrogen atom or an alkyl group,
L₄ represents a single bond or an alkylene group,
Ar₄ represents an (n+1)-valent aromatic ring group, and in a case where Ar₄ is bonded to R₄₂ to form a ring, Ar₄ represents an (n+2)-valent aromatic ring group, and
n represents an integer of 1 to 5.

6. The actinic ray-sensitive or radiation-sensitive resin composition according to claim 1,
wherein the compound that generates an acid upon irradiation with actinic rays or radiation includes any one or more of the following compound (I) or compound (II),
compound (I):
a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation,
structural site X: a structural site which consists of an anionic site A₁⁻ and a cationic site M₁⁺, and forms a first acidic site represented by HA₁ upon irradiation with actinic rays or radiation,
structural site Y: a structural site which consists of an anionic site A₂⁻ and a cationic site M₂⁺, and forms a second acidic site represented by HA₂ upon irradiation with actinic rays or radiation,
provided that the compound (I) satisfies the following condition I,
condition I: a compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1,
compound (II):
a compound having two or more sites of the structural site X and one or more sites of the following structural site Z, the compound that generates an acid including two or more sites of the first acidic site derived from the structural site X and the structural site Z upon irradiation with actinic rays or radiation,
structural site Z: a nonionic site capable of neutralizing an acid.

7. A resist film formed of the actinic ray-sensitive or radiation-sensitive resin composition according to claim 1.

8. A pattern forming method comprising:
a step of forming a resist film on a substrate, using the actinic ray-sensitive or radiation-sensitive resin composition according to claim 1;
a step of exposing the resist film; and
a step of developing the exposed resist film using a developer to form a pattern.

9. The pattern forming method according to claim 8,
wherein the developer includes an organic solvent.

10. A method for manufacturing an electronic device, comprising the pattern forming method according to claim 8.

11. The actinic ray-sensitive or radiation-sensitive resin composition according to claim 2,
wherein a content of the repeating unit X1 is 30% by mass or more with respect to all repeating units in the resin.

12. The actinic ray-sensitive or radiation-sensitive resin composition according to claim 2,
wherein the repeating unit X2 is a repeating unit represented by Formula (I), 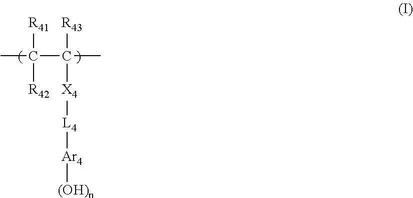
in the formula, R₄₁, R₄₂, and R₄₃ each independently represent a hydrogen atom or a substituent, provided that R₄₂ may be bonded to Ar₄ to form a ring, where in such a case R₄₂ represents a single bond or an alkylene group,
X₄ represents a single bond, —COO—, or —CONR₆₄—, where R₆₄ represents a hydrogen atom or an alkyl group,
L₄ represents a single bond or an alkylene group,
Ar₄ represents an (n+1)-valent aromatic ring group, and in a case where Ar₄ is bonded to R⁴² to form a ring, Ar₄ represents an (n+2)-valent aromatic ring group, and
n represents an integer of 1 to 5.

13. The actinic ray-sensitive or radiation-sensitive resin composition according to claim 2,
wherein the compound that generates an acid upon irradiation with actinic rays or radiation includes any one or more of the following compound (I) or compound (II),
compound (I):
a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation,
structural site X: a structural site which consists of an anionic site A₁⁻ and a cationic site M₁⁺, and forms a first acidic site represented by HA₁ upon irradiation with actinic rays or radiation,
structural site Y: a structural site which consists of an anionic site A₂⁻ and a cationic site M₂⁺, and forms a second acidic site represented by HA₂ upon irradiation with actinic rays or radiation,
provided that the compound (I) satisfies the following condition I,
condition I: a compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1,
compound (II):
a compound having two or more sites of the structural site X and one or more sites of the following structural site Z, the compound that generates an acid including two or more sites of the first acidic site derived from the structural site X and the structural site Z upon irradiation with actinic rays or radiation,
structural site Z: a nonionic site capable of neutralizing an acid.

14. A resist film formed of the actinic ray-sensitive or radiation-sensitive resin composition according to claim 2.

15. A pattern forming method comprising:
a step of forming a resist film on a substrate, using the actinic ray-sensitive or radiation-sensitive resin composition according to claim 2;
a step of exposing the resist film; and
a step of developing the exposed resist film using a developer to form a pattern.

16. The pattern forming method according to claim 15,
wherein the developer includes an organic solvent.

17. A method for manufacturing an electronic device, comprising the pattern forming method according to claim 9.

18. The actinic ray-sensitive or radiation-sensitive resin composition according to claim 3,
wherein a content of the repeating unit X1 is 30% by mass or more with respect to all repeating units in the resin.

19. The actinic ray-sensitive or radiation-sensitive resin composition according to claim 3,
wherein the repeating unit X2 is a repeating unit represented by Formula (I), 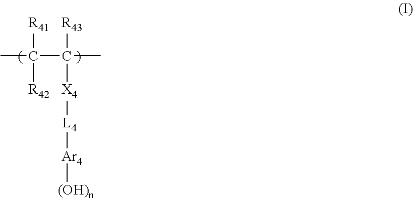
in the formula, R₄₁, R₄₂, and R₄₃ each independently represent a hydrogen atom or a substituent, provided that R₄₂ may be bonded to Ar₄ to form a ring, where in such a case R₄₂ represents a single bond or an alkylene group,
X₄ represents a single bond, —COO—, or —CONR₆₄—, where R₆₄ represents a hydrogen atom or an alkyl group,
L₄ represents a single bond or an alkylene group,
Ar₄ represents an (n+1)-valent aromatic ring group, and in a case where Ar₄ is bonded to R₄₂ to form a ring, Ar₄ represents an (n+2)-valent aromatic ring group, and
n represents an integer of 1 to 5.

20. The actinic ray-sensitive or radiation-sensitive resin composition according to claim 3,
wherein the compound that generates an acid upon irradiation with actinic rays or radiation includes any one or more of the following compound (I) or compound (II),
compound (I):
a compound having one or more sites of the following structural site X and one or more sites of the following structural site Y, the compound generating an acid including the following first acidic site derived from the following structural site X and the following second acidic site derived from the following structural site Y upon irradiation with actinic rays or radiation,
structural site X: a structural site which consists of an anionic site A₁⁻ and a cationic site M₁⁺, and forms a first acidic site represented by HA₁ upon irradiation with actinic rays or radiation,
structural site Y: a structural site which consists of an anionic site A₂⁻ and a cationic site M₂⁺, and forms a second acidic site represented by HA₂ upon irradiation with actinic rays or radiation,
provided that the compound (I) satisfies the following condition I,
condition I: a compound PI formed by substituting the cationic site M₁⁺ in the structural site X and the cationic site M₂⁺ in the structural site Y with H⁺ in the compound (I) has an acid dissociation constant a1 derived from an acidic site represented by HA₁, formed by substituting the cationic site M₁⁺ in the structural site X with H⁺, and an acid dissociation constant a2 derived from an acidic site represented by HA₂, formed by substituting the cationic site M₂⁺ in the structural site Y with H⁺, and the acid dissociation constant a2 is larger than the acid dissociation constant a1,
compound (II):
a compound having two or more sites of the structural site X and one or more sites of the following structural site Z, the compound that generates an acid including two or more sites of the first acidic site derived from the structural site X and the structural site Z upon irradiation with actinic rays or radiation,
structural site Z: a nonionic site capable of neutralizing an acid.
